(19) United States
(12) Patent Application Publication
(10) Pub. No.: US 2025/0079354 A1
(43) Pub. Date: Mar. 6, 2025

(54) LEADING POINT OF DISCHARGE STRUCTURES FOR ELECTROSTATIC DISCHARGE PROTECTION AND METHODS OF FORMING THE SAME

(71) Applicant: Taiwan Semiconductor Manufacturing Company Limited, Hsinchu (TW)

(72) Inventors: Steven Sze Hang Poon, Hsinchu City (TW); Jun He, Zhubei City (TW); Wen-Hsiung Lu, Tainan City (TW); Ming-Da Cheng, Taoyuan (TW); Chang-Jung Hsueh, Taipei (TW)

(21) Appl. No.: 18/402,775

(22) Filed: Jan. 3, 2024

Related U.S. Application Data
(60) Provisional application No. 63/579,997, filed on Sep. 1, 2023.

(51) Int. Cl. H01L 23/00; H01L 23/60

(52) U.S. Cl. CPC H01L 24/02; H01L 23/60; H01L 24/05; H01L 24/06; H01L 24/08; H01L 24/24; H01L 24/03; H01L 24/14; H01L 24/16; H01L 24/82; H01L 2224/02313; H01L 2224/0235; H01L 2224/02373; H01L 2224/02375; H01L 2224/02381; H01L 2224/0239; H01L 2224/0345; H01L 2224/03462; H01L 2224/03466; H01L 2224/03614; H01L 2224/05024; H01L 2224/05082; H01L 2224/05147; H01L 2224/05166; H01L 2224/05572; H01L 2224/05573; H01L 2224/05601; H01L 2224/05611; H01L 2224/05613; H01L 2224/05616; H01L 2224/05618; H01L 2224/05624; H01L 2224/05647; H01L 2224/0603; H01L 2224/06131; H01L 2224/0801; H01L 2224/08145; H01L 2224/1403; H01L 2224/14131; H01L 2224/16148; H01L 2224/16227; H01L 2224/2405; H01L 2224/24101; H01L 2224/24137; H01L 2224/82106; H01L 2924/01022; H01L 2924/01029; H01L 2924/01048

(57) ABSTRACT

Protection from electrostatic discharge (ESD) events is provided by forming leading points of discharge (LPoD) structures on a semiconductor die or on a composite die. The LPoD structures may comprise an upper protrusion portion on an ESD path metal structure, intermediate metallic material portions, solder material portions having a greater height than normal solder material portions that are not provided with ESD protection, or a elongated metal bar structure. The LPoD structures may be used for anisotropic etch process for forming via cavities, bonding processes using solder material portions, bonding processes using metal-to-metal bonding, and/or solder ball attachment processes.

### RELATED APPLICATIONS

This application claims the benefit of priority from U.S. Provisional Application Ser. No. 63/579,997 entitled “Leading Point of Discharge (LPoD) structure for ESD protection” and filed on Sep. 1, 2023, the entire contents of which are incorporated herein by reference for all purposes.

### BACKGROUND

Electrostatic discharge (ESD) events may damage semiconductor dies and semiconductor packages during, and after, manufacture. The ESD events may cause immediate device failure, yield loss, shortened device lifespans, and hidden reliability risks, and may have deleterious effects on device reliability and manufacturing yield.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first embodiment structure including a semiconductor die according to a first embodiment of the present disclosure.

FIG. 2A-2F are sequential vertical cross-sectional views of region M of the first embodiment structure of FIG. 1 during formation of a leading point of discharge structure according to the first embodiment of the present disclosure.

FIG. 3 is a top-down view of a region of the first embodiment structure after formation of leading point of discharge structures and passivation-level metal structures according to the first embodiment of the present disclosure.

FIGS. 4A-4F are sequential vertical cross-sectional views of region M of the first embodiment structure of FIG. 1 during formation of bonding pads and attachment of solder material portions according to the first embodiment of the present disclosure.

FIG. 5 is a vertical cross-sectional view of the semiconductor die of the first embodiment structure after dicing according to the first embodiment of the present disclosure.

FIGS. 6A-61 are sequential vertical cross-sectional views of a region of an alternative configuration of the first embodiment structure during formation of a leading point of discharge structure and bonding pads and attachment of solder material portions according to the first embodiment of the present disclosure.

FIGS. 7A-7D are sequential vertical cross-sectional views of a second embodiment structure during formation of leading point of discharge structures according to a second embodiment of the present disclosure.

FIG. 8A is a top-down view of a region of the second embodiment structure of FIG. 7D according to the second embodiment of the present disclosure.

FIG. 8B is a top-down view of a region of an alternative configuration of the second embodiment structure according to the second embodiment of the present disclosure.

FIGS. 9A-9C are sequential vertical cross-sectional views of the second embodiment structure during dicing and attachment of a fan-out package to an interposer according to the second embodiment of the present disclosure.

FIGS. 10A-10F are sequential vertical cross-sectional views of a third embodiment structure during formation of a bonded assembly of two semiconductor dies according to a third embodiment of the present disclosure.

FIGS. 11A-11D are sequential vertical cross-sectional views of a fourth embodiment structure during formation of a bonded assembly of two semiconductor dies according to a fourth embodiment of the present disclosure.

FIGS. 12A-12E are sequential vertical cross-sectional views of a fifth embodiment structure during formation of a bonded assembly of two semiconductor dies according to a fifth embodiment of the present disclosure.

FIG. 13 is a top-down view a sixth embodiment structure including a wafer or a reconstituted wafer according to a sixth embodiment of the present disclosure.

FIGS. 14A-14J are magnified views of various configurations of the sixth embodiment structure of FIG. 13.

FIGS. 15A-15L are various views of a seventh embodiment structure. FIG. 15A is a top-down view the seventh embodiment structure including a wafer or a reconstituted wafer according to a seventh embodiment of the present disclosure. FIG. 15B is a magnified view of a unit area in the seventh embodiment structure of FIG. 15A.

FIG. 15C is a vertical cross-sectional view of a region of a first configuration of the seventh embodiment structure along the vertical plane C-C′ of FIG. 15B. FIG. 15D is a vertical cross-sectional view of a region of the first configuration of the seventh embodiment structure along the vertical plane D-D′ of FIG. 15B.

FIG. 15E is a vertical cross-sectional view of a region of a second configuration of the seventh embodiment structure along the vertical plane C-C′ of FIG. 15B. FIG. 15F is a vertical cross-sectional view of a region of the second configuration of the seventh embodiment structure along the vertical plane D-D′ of FIG. 15B.

FIG. 15G is a magnified view of a unit area in a third configuration of the seventh embodiment structure of FIG. 15A. FIG. 15H is a vertical cross-sectional view of a region of the third configuration of the seventh embodiment structure along the vertical plane H-H′ of FIG. 15G. FIG. 15I is a vertical cross-sectional view of a region of the third configuration of the seventh embodiment structure along the vertical plane I-I′ of FIG. 15G. FIG. 15J is a magnified view of region J of FIG. 15H. FIG. 15K is a magnified view of region K of FIG. 15I. FIG. 15L is a detailed view of FIG. 15I.

FIGS. 16A-16E is a sequential vertical cross-sectional view of an eighth embodiment structure in which the seventh exemplary structure of FIGS. 15A-15G is processed to attach solder material portions according to an eighth embodiment of the present disclosure.

FIG. 17 is a schematic circuit diagram of a combined electrostatic discharge circuit during operation of the various leading point of discharge structures of various embodiments of the present disclosure.

FIG. 18 is a first flowchart illustrating steps for forming a device structure according to an embodiment of the present disclosure.

FIG. 19 is a second flowchart illustrating steps for forming a device structure according to an embodiment of the present disclosure.

FIG. 20 is a third flowchart illustrating steps for forming a device structure according to an embodiment of the present disclosure.

FIG. 21 is a fourth flowchart illustrating steps for forming a device structure according to an embodiment of the present disclosure.

FIG. 22 is a fifth flowchart illustrating steps for forming a device structure according to an embodiment of the present disclosure.

FIG. 23 is a sixth flowchart illustrating steps for forming a device structure according to an embodiment of the present disclosure.

FIG. 24 is a seventh flowchart illustrating steps for forming a device structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

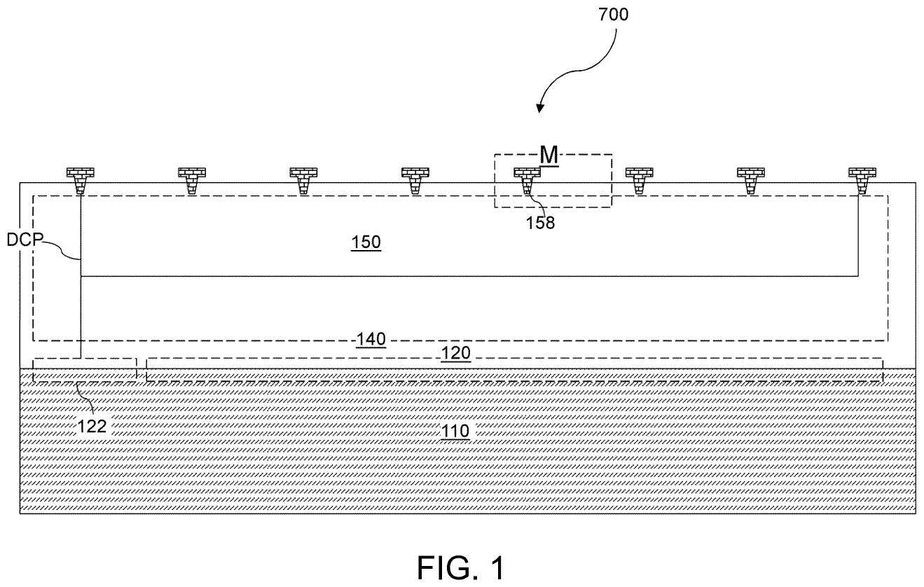

Referring to FIG. 1, a first embodiment structure according to a first embodiment of the present disclosure is illustrated, which includes a semiconductor die 700. The illustrated semiconductor die 700 may be one of a plurality of semiconductor dies 700 formed on a semiconductor substrate 110, which may be a commercially available semiconductor wafer. In this embodiment, a two-dimensional array of semiconductor dies 700 may be formed on the semiconductor substrate 110 such that each semiconductor die 700 may include a respective portion of the semiconductor substrate 100. The semiconductor die 700 may be a logic die, a memory die, or any other type of semiconductor die known in the art. Generally, semiconductor devices 120 may be formed on a top surface of the semiconductor substrate 110. The details of the semiconductor device are not depicted for simplicity sake, but any known semiconductor device 120 may be formed in the identified region.

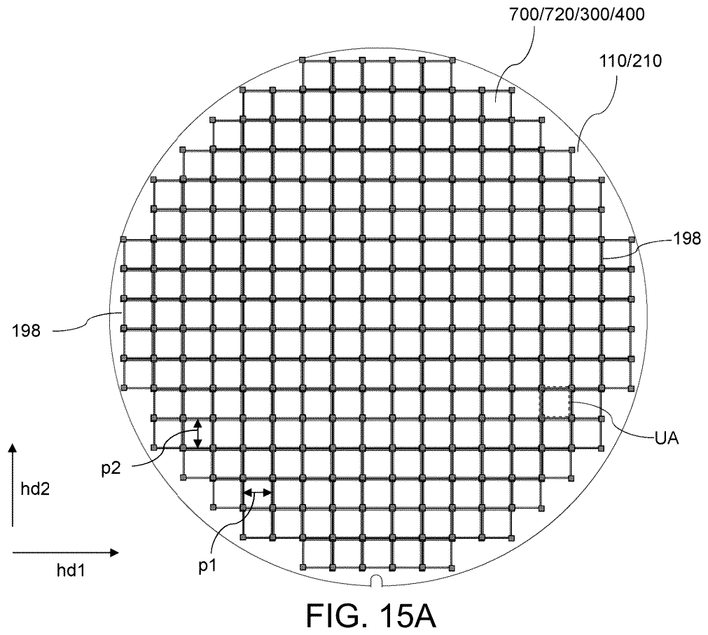

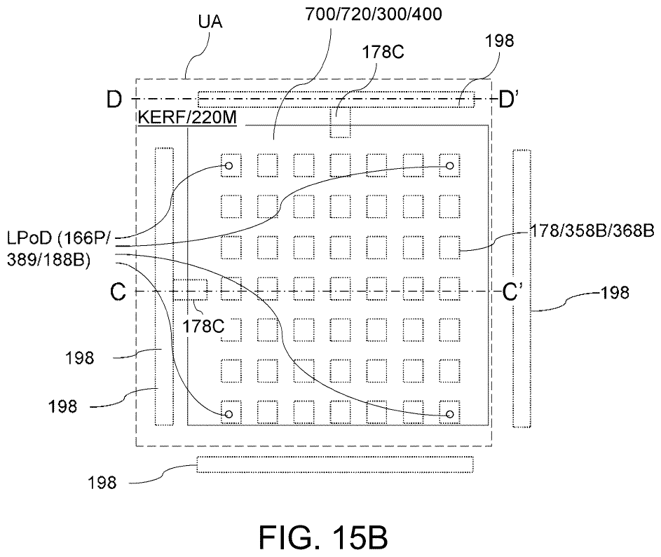

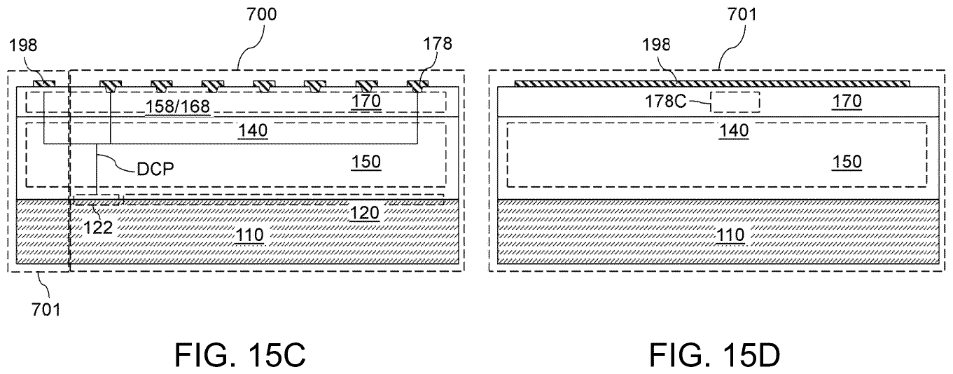

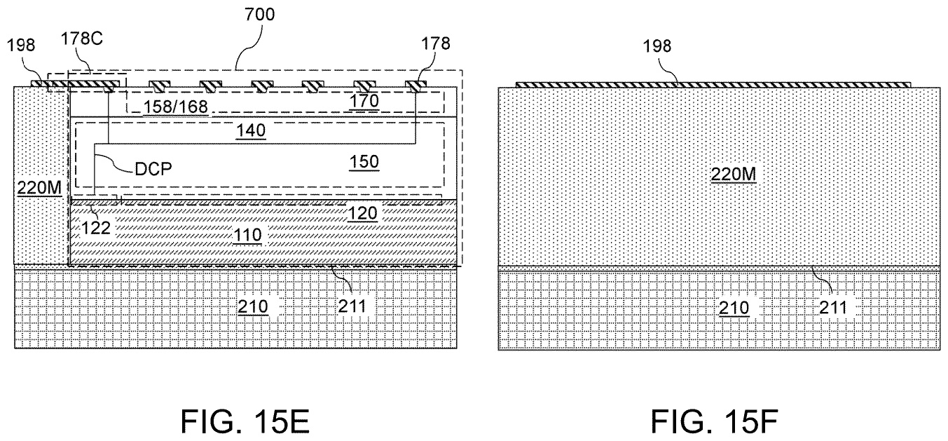

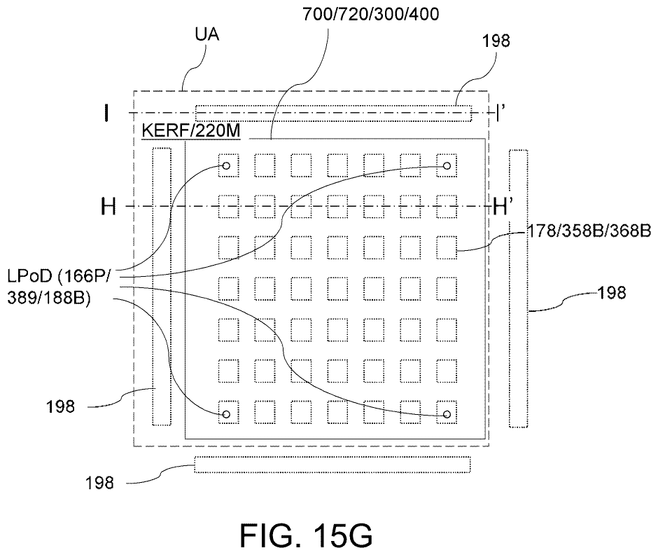

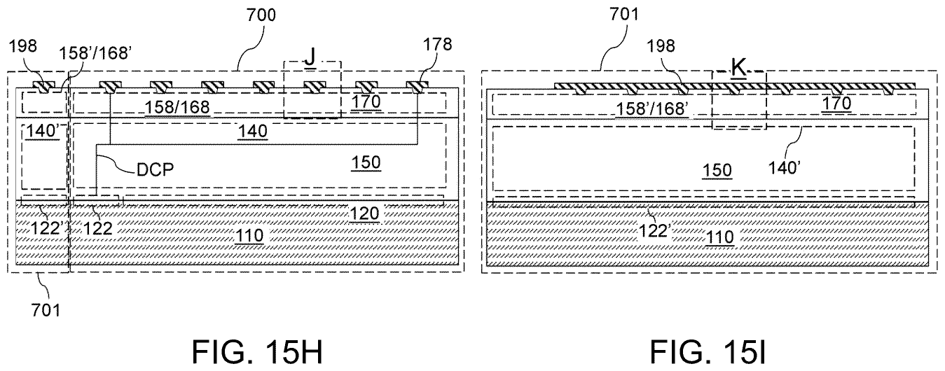

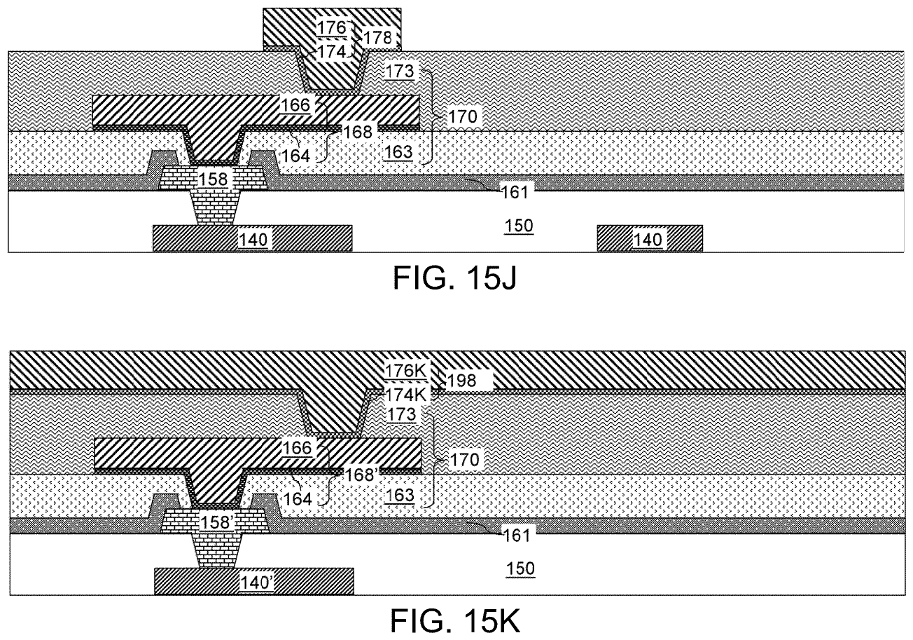

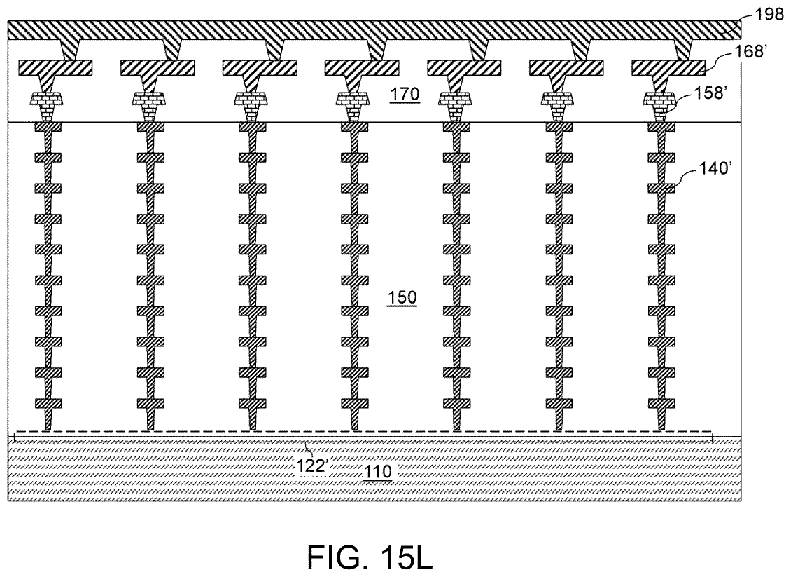

The semiconductor devices 120 may comprise any type of semiconductor devices known in the art, and may comprise, for example, field effect transistors. In one embodiment, the field effect transistors may comprise die-to-die input/output (I/O) switches that may be subjected to electrostatic discharge (ESD) events. According to an aspect of the present disclosure, an electrostatic discharge (ESD) protection circuit 122 may be formed in each semiconductor die 700. Generally, any type of ESD protection devices known in the art may be used for the ESD protection circuit 122. Further, a well-laid out network of metal interconnect structures (such as one illustrated in FIG. 15L), may be electrically connected to the ESD protection circuit 122, or in some cases, may replace the ESD protection circuit 122. As such, the ESD protection circuit 122 may comprise any type of ESD protection circuit, may be replaced with a network of metal interconnect structures that is electrically shorted to the semiconductor substrate, or may be electrically connected to a network of metal interconnect structures. In one embodiment, the ESD protection circuit 122 may comprise at least one diode, such as a plurality of diodes interconnected to one another to provide sufficient charge handling capacity when subjected to ESD events.

Metal interconnect structures 140 embedded in dielectric material layers 150 that may be formed over the semiconductor devices 120 and the ESD protection circuit 122. The metal interconnect structures 140 may comprise metal lines, metal via structures, integrated metal line and via structures, metal pads, etc. For the sake of simplicity, the details of the metal interconnect structures 140 embedded within the dielectric material layers 150 are not illustrated. The dielectric material layers 150 may comprise interlayer dielectric (ILD) materials such as silicon oxide, silicon nitride, dielectric metal oxides, porous or non-porous organosilicate glass, etc. Generally, the dielectric material layers 150 may comprise non-polymer materials. The total number of levels of metal lines in the metal interconnect structures 140 may be in a range from 1 to 20, such as from 2 to 12, although a greater number of levels may also be used. Metal pad structures 158 may be formed over a top surface of the dielectric material layers 150. In some embodiments at least one of the metal pad structures 158 may be electrically connected to the metal interconnect structures 140 and semiconductor device 120 formed over the semiconductor substrate 110.

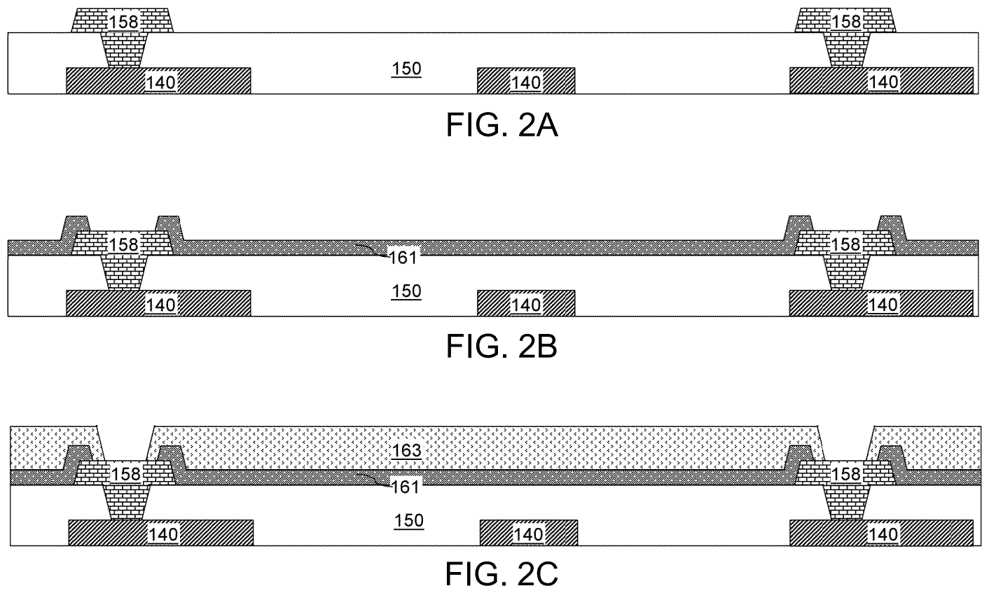

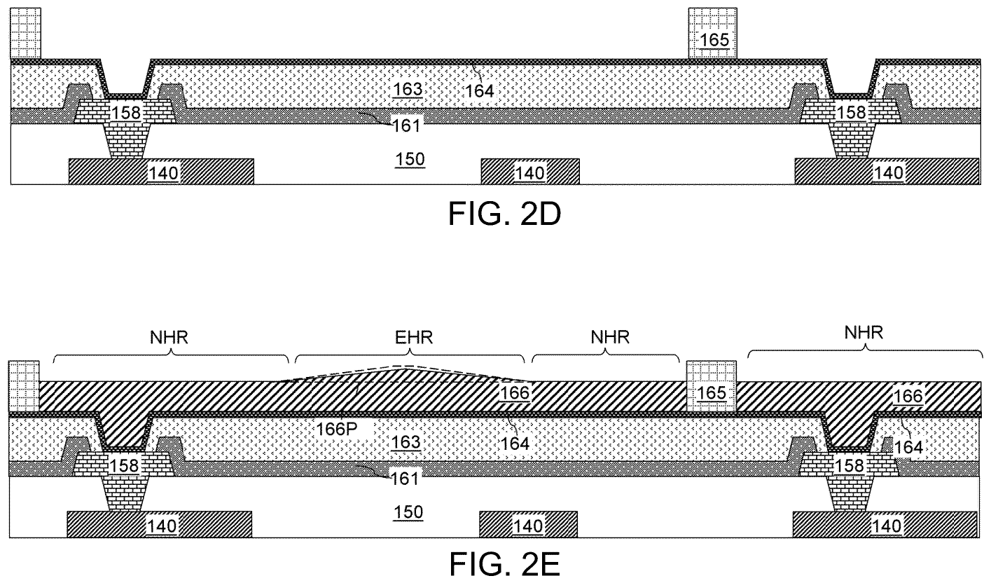

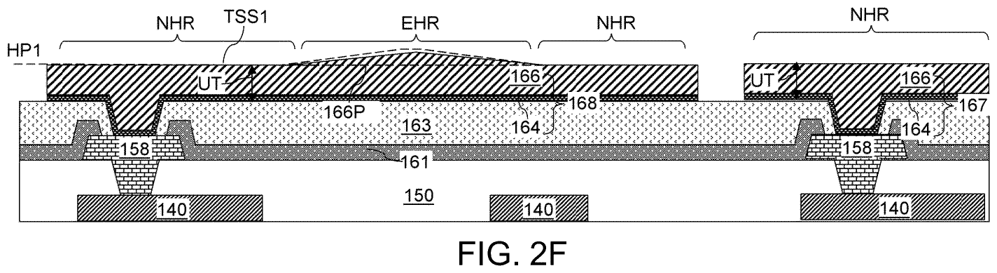

FIG. 2A-2F are sequential vertical cross-sectional views of region M of the first embodiment structure of FIG. 1 during formation of a leading point of discharge structure according to the first embodiment of the present disclosure.

Referring to FIGS. 1 and 2A, metal pad structures 158 may be formed at the topmost level of the dielectric material layers 150. For example, via openings may be formed through a topmost dielectric material layer 150 selected from the dielectric material layers 150 such that top surfaces of topmost metal interconnect structures 140 are physically exposed underneath the via openings. In some embodiments, the topmost metal interconnect structures 140 may comprise copper pads. A first passivation-level metal may be deposited in the via openings and over the top surface of the topmost dielectric material layer 150, and may be patterned by performing a lithographic patterning process and an etch process (such as an anisotropic etch process). Patterned portions of the first passivation-level metal comprise metal pad structures 158. The metal pad structures 158 may comprise aluminum, copper, an aluminum-based alloy, a copper-based alloy, etc.

A subset of metal interconnect structures 140 may be interconnected to one another to provide electrically conductive paths between a subset of the metal pad structures 158 and the ESD protection circuit 122. The electrically conductive paths may be used as current paths during electrostatic discharge events, and are herein referred to as discharge current paths DCP. In some embodiments, the discharge current paths DCP may be electrically connected to nodes of semiconductor devices 120 that need protection against electrostatic discharge events. Such semiconductor devices 120 may include input/output transistors, i.e., field effect transistors that are configured to receive, or transmit, input/output signals into, or out of, the semiconductor die 700.

Referring to FIG. 2B, a first passivation dielectric layer 161 may be deposited over the topmost dielectric material layer 150 and the metal pad structures 158. The first passivation dielectric layer 161 comprises a diffusion-blocking dielectric material such as silicon nitride or silicon carbide nitride. The thickness of the first passivation dielectric layer 161 may be in a range from 100 nm to 500 nm, although lesser and greater thicknesses may also be used. Openings may be formed over the metal pad structures 158, for example, by applying and patterning a photoresist layer (not shown), and by transferring the pattern of the openings in the photoresist layer through the first passivation dielectric layer 161 using an etch process. The photoresist layer may be subsequently removed, for example, by ashing.

Referring to FIG. 2C, a second passivation dielectric layer 163 may be formed over the first passivation dielectric layer 161. In one embodiment, the second passivation dielectric layer 163 may comprise a polymer-based passivation dielectric layer such as polyimide. The thickness of the second passivation dielectric layer 163 (as measured in a region laterally spaced from the metal pad structures 158) may be in a range from 1 micron to 10 microns, such as from 2 microns to 6 microns, although lesser and greater thicknesses may also be used. The second passivation dielectric layer 163 may be patterned to form openings therethrough such that top surfaces of the metal pad structures 158 are exposed to the ambient underneath the openings in the second passivation dielectric layer 163. The ambient may be the atmospheric ambient or a low oxygen ambient.

Referring to FIG. 2D, a metallic seed layer 164 may be formed over the second passivation dielectric layer 163. The metallic seed layer 164 comprises at least one metallic material that may function as an adhesion promoter material, a diffusion barrier material, and/or a metallic seed material for a subsequent electroplating process. For example, the metallic seed layer 164 may comprise a layer stack of a titanium layer and a copper seed layer, which may be deposited by physical vapor deposition. The thickness of the titanium layer may be in a range from 5 nm to 100 nm, and the thickness of the copper seed layer may be in a range from 50 nm to 500 nm, although lesser and greater thicknesses may be used for the titanium layer and the copper seed layer, respectively.

A first photoresist layer 165 may be deposited over the metallic seed layer 164, and may be lithographically patterned to form openings in areas in which metal structures are to be subsequently formed. The thickness of the first photoresist layer 165 may be in a range from 2 microns to 20 microns, although lesser and greater thicknesses may also be used. Generally, the area of openings in the first photoresist layer 165 include areas of the metal pad structures 158 and areas in which metallic bonding pads are to be subsequently formed. In one embodiment, a subset of the openings in the first photoresist layer 165 may be formed with a low pattern factor.

As used herein, a pattern factor refers to a local ratio of an area of a pattern to a total local area. For each pattern having a minimum lateral dimension (which is typically referred to as a “critical dimension CD”), a local ratio of an area of a pattern to a total local area may be calculated by selecting the size of the local area to be a circle having a radius of 10 times the minimum lateral dimension. In other words, for a pattern of (an) opening(s) having a minimum lateral dimension (such as a minimum width), the pattern factor may be calculated by drawing a circle having a radius of 10 times the minimum lateral dimension, by calculating the total area of the opening(s) within the circle, and by dividing the total area of the opening(s) by the area of the circle.

Referring to FIG. 2E, an electroplating process may be performed to electroplate copper or a copper-containing alloy within areas of openings in the first photoresist layer 165. Copper-based metal portions 166 may be formed by the electroplating process within the areas of openings in the first photoresist layer 165. According to an aspect of the present disclosure, process parameters of the electroplating process may be selected such that the deposition rate of the copper-based material of the copper-based metal portions 166 depends on the pattern factor of the openings in the first photoresist layer 165.

For example, the electroplating process may be performed under a condition in which supply of copper atoms in the electroplating path is insufficient to provide conformal growth of the copper-based metal, but induces a higher deposition rate in regions of a low pattern factor for the openings in the first photoresist layer 165, and induces a lower deposition rate in regions of a high pattern factor for the openings in the first photoresist layer 165. In this embodiment, the copper-based metal portions 166 may have a uniform thickness in first regions having a normal pattern factor, and may have a graded thickness (i.e., a varying thickness) in second regions having a low pattern factor. The uniform thickness is also referred to as a normal thickness, and the first regions are also referred to as normal height regions NHR. The graded thickness is a variable thickness that is greater than the normal thickness, and the second regions are also referred to as extended height regions EHR. The uniform thickness may be in a range from 1 microns to 10 microns, although lesser and greater thicknesses may also be used.

In one embodiment, at least one first copper-based metal portions 166 selected from the copper-based metal portions 166 includes at least one uniform thickness region (i.e., at least one normal height region NHR) and a graded thickness region (i.e., an extended height region EHR). In this embodiment, the graded thickness region of each such first copper-based metal portion 166 may be formed with at least one tilted top surfaces each having a tilt angle relative to a horizontal plane in a range from 0.1 degree to 10 degrees, such as from 0.3 degree to 5 degrees, and/or from 0.5 degree to 3 degrees. Each region of the copper-based metal portions 166 that is located above the horizontal plane including planar horizontal top surfaces of regions of the copper-based metal portions 166 having the uniform thickness is herein referred to as an upper protrusion portion 166P. In one embodiment, the first copper-based metal portions 166 may be electrically connected the ESD protection circuit 122 through the discharge current path DCP. At least a second copper-based metal portion 166 selected from the copper-based metal portions 166 may have the uniform thickness throughout, and thus, may consist of a single uniform thickness region (i.e., a normal height region NHR).

Generally, first copper-based metal portions 166 including a respective upper protrusion portion 166P and second copper-based metal portions consisting of a respective normal height region NHR may be simultaneously formed using a single deposition process that provides pattern-factor-dependent deposition rates. In one embodiment, the single deposition process may comprise an electroplating process that electroplates copper or a copper-containing alloy that includes copper at an atomic concentration of 98% or higher. Generally, a first areal metal density within a region including the copper-based metal portions 166 including a respective upper protrusion portion 166P is less than a second areal metal density within a region of the additional copper-based metal portions consisting of a respective normal height region NHR by a factor of at least 3. In an illustrative example, the first areal metal density may be in a range from 0.002 to 0.15; and the second areal metal density may be in a range from 0.20 to 0.60, such as from 0.35 to 0.50.

Referring to FIG. 2F, the first photoresist layer 165 may be removed, for example, by ashing. Subsequently, an isotropic etch process such as a wet etch process may be performed to remove unmasked portions of the metallic seed layer 164. Physically exposed surface portions of the copper-based metal portions 166 may be collaterally removed during the isotropic etch process.

Each remaining contiguous combination of a metallic seed layer 164 and a first copper-based metal portion 166 including a respective upper protrusion portion 166P is herein referred to as an electrostatic discharge (ESD) path metal structure 168. Each remaining contiguous combination of a metallic seed layer 164 and a second copper-based metallic portion 166 consisting of a respective normal height region NHR is herein referred to as a passivation-level metal structure 167. Generally, passivation-level metal structures 167 and at least one electrostatic discharge (ESD) path metal structure 168 may be formed. Each ESD path metal structure 168 comprises a first top surface segment TSS1 located within a first horizontal plane HP1 that contains a top surface of one, a plurality, and/or each, of the passivation-level metal structures 167. Further, each ESD path metal structure 168 comprises an upper protrusion portion 166P that protrudes above the first horizontal plane HP1. In one embodiment, the entirely of the passivation-level metal structures 167 may be formed below, or within, the first horizontal plane HP1.

The passivation-level metal structures 167 and the ESD path metal structures 168 may comprise a respective via portion contacting a respective underlying metal pad structure 158. The uniform thickness UT of horizontally-extending portions of the passivation-level metal structures 167 and the ESD path metal structures 168 outside the areas of the via portions and outside the areas of the upper protrusion portions 166P may be in a range from 1 micron to 8 microns, although lesser and greater thicknesses may also be used. The height of the upper protrusion portions 166P may be in a range from 10% to 80% of the uniform thickness UT, and may be in a range from 400 nm to 4 microns, such as from 800 nm to 2 microns.

Referring collectively to FIGS. 1 and 2A-2F, the electrostatic discharge (ESD) protection circuit 122 on the semiconductor substrate 110, and metal interconnect structures 140 embedded in dielectric material layers 150 may be formed over the semiconductor substrate 110. The ESD path metal structure 168 may be formed above the metal interconnect structures 140, and may be electrically connected to the ESD protection circuit 122 through a subset of the metal interconnect structures 140. In one embodiment, passivation-level metal structures 167 and the electrostatic discharge (ESD) path metal structure 168 are simultaneously formed using a single deposition process that provides pattern-factor-dependent deposition rates. In one embodiment, the passivation-level metal structures 167 and the ESD path metal structure 168 are formed by performing at least one electroplating process.

The ESD path metal structure 168 comprises a first top surface segment TSS1 located within a first horizontal plane HP1 that contains a top surface of one, a plurality, and/or each, of the passivation-level metal structures 167. In one embodiment, the upper protrusion portion 166P may be formed with at least one tilted top surfaces each having a tilt angle relative to the first horizontal plane HP1 in a range from 0.1 degree to 10 degrees. In one embodiment, a first areal metal density at a level of the passivation-level metal structures 167 and the ESD path metal structure 168 within a region including the upper protrusion portion 166P of the ESD path metal structure 168 is less than a second areal metal density at the level of the passivation-level metal structures 167 and the ESD path metal structure 168 within a region of the passivation-level metal structures 167 is by a factor of at least 3.

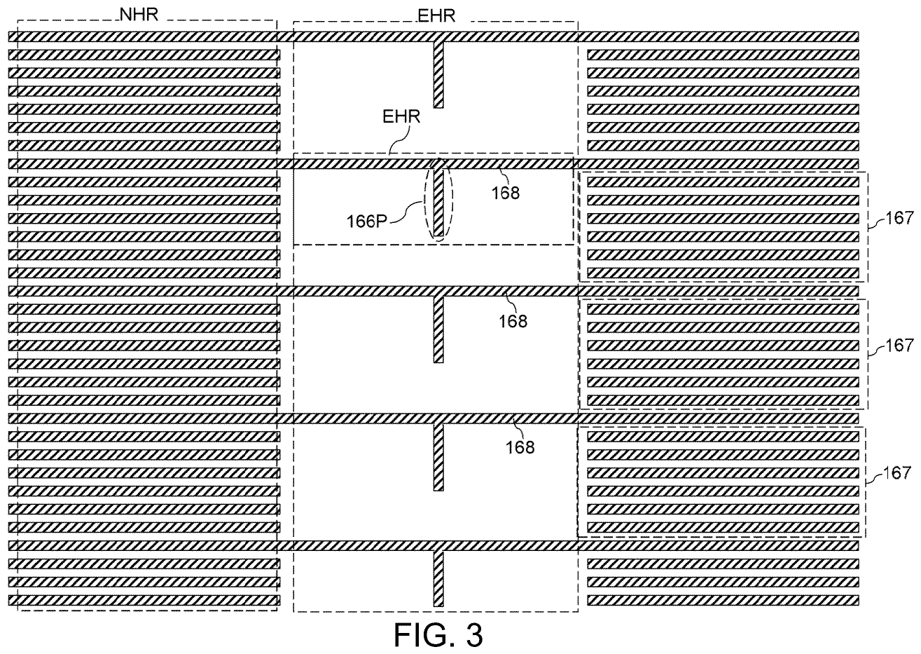

FIG. 3 is a top-down view of a region of the first embodiment structure after formation of leading point of discharge structures and passivation-level metal structures 167 according to the first embodiment of the present disclosure. In this example, the entirety of the passivation-level metal structures 167 may be formed within normal height regions NHR, and the upper protrusion portions 166P of the ESD path metal structures 168 may be formed in the extended height region EHR.

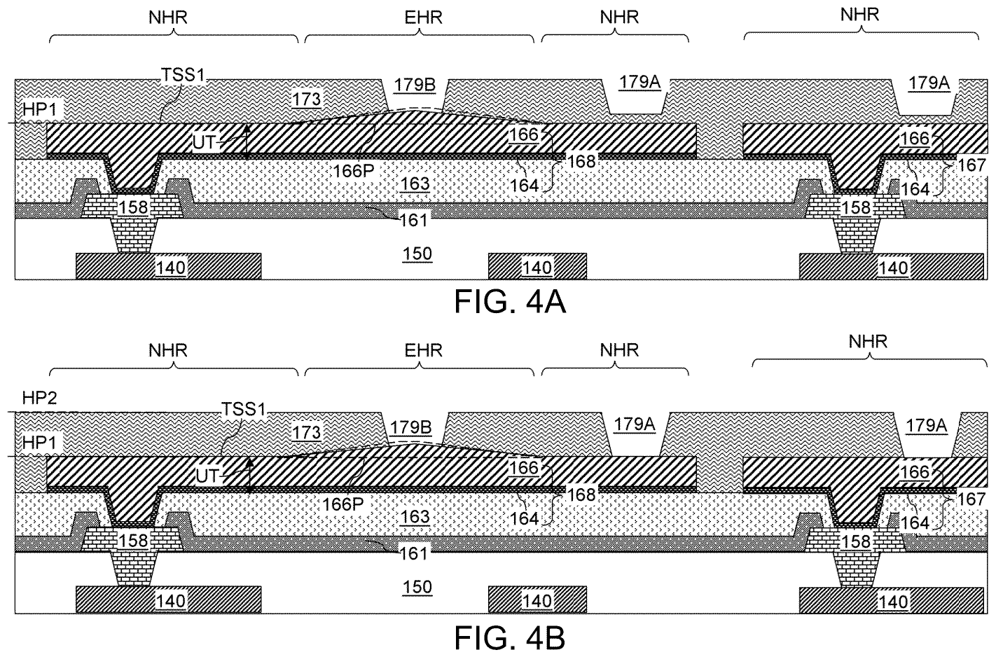

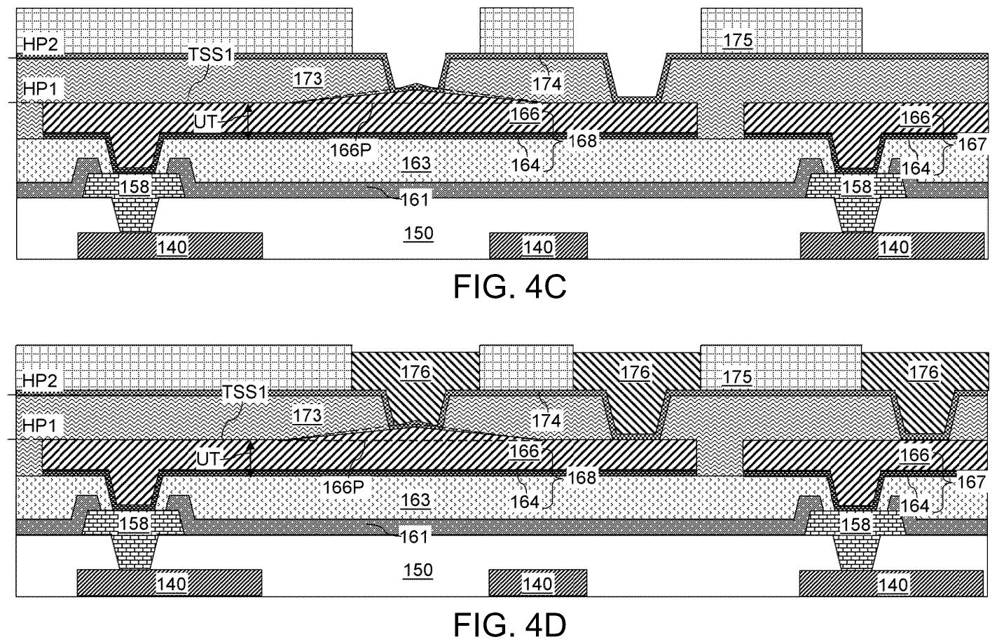

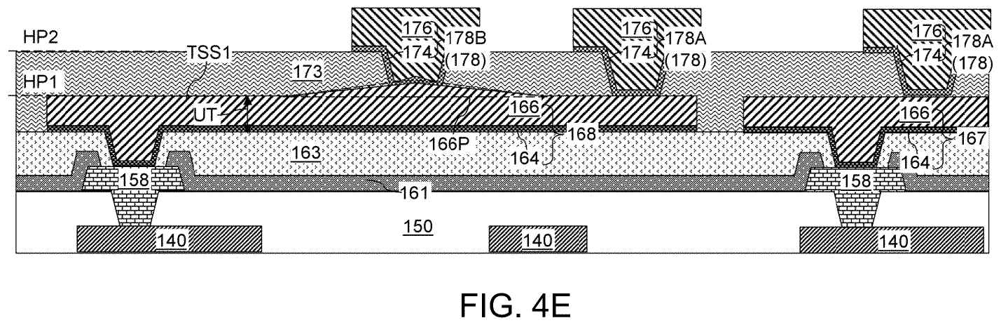

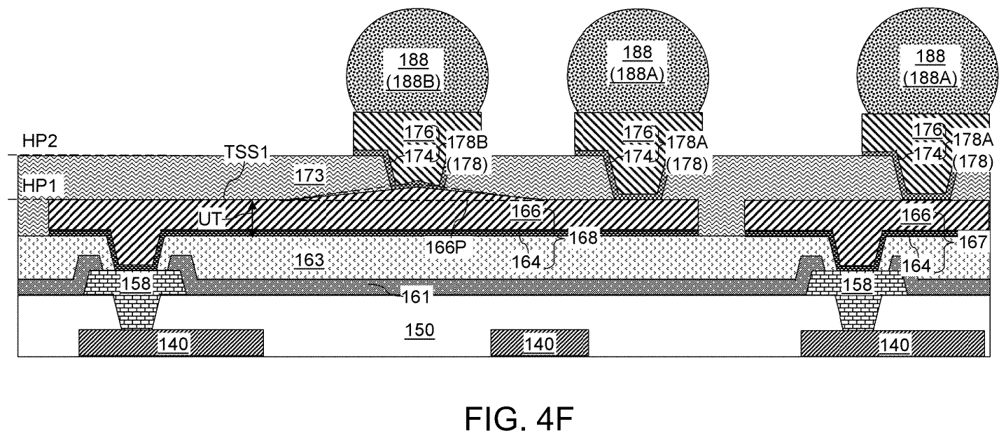

FIGS. 4A-4F are sequential vertical cross-sectional views of region M of the first embodiment structure of FIG. 1 during formation of metallic bonding pads 178 and attachment of solder material portions 188 according to the first embodiment of the present disclosure.

Referring to FIG. 4A, a capping dielectric material such as polyimide may be deposited over the passivation-level metal structures 167 and the ESD path metal structure 168 to form a capping dielectric layer 173. The thickness of the capping dielectric layer 173, as measured above the horizontally-extending portions of the passivation-level metal structures 167 and the ESD path metal structure 168, may be in a range from 2 microns to 6 microns, although lesser and greater thicknesses may also be used. The capping dielectric layer 173 may be patterned to form via openings (179A, 179B) therethrough over the areas of the passivation-level metal structures 167 and the ESD path metal structure 168. The via openings (179A, 179B) may be formed through the capping dielectric layer 173 by performing an etch process. In some embodiments, the etch process may comprise an anisotropic etch process such as a reactive ion etch process using an reactive ion plasma. Thus, instantaneous electrical discharge from the plasma to a subset of metal structures in the semiconductor die 700 may occur at a moment when the subset of metal structures in the semiconductor die 700 is physically exposed to the plasma of the reactive ion etch process. Alternatively, the etch process may employ alternative etch processes known in the art.

According to an aspect of the present disclosure, the via openings (179A, 179B) comprise first via openings 179A that are formed over the horizontally-extending portions of the passivation-level metal structures 167 and the ESD path metal structure 168 having the uniform thickness UT, and second via openings 179B that are formed over the upper protrusion portions 166P. The upper protrusion portions 166P protrude above the first horizontal plane HP1, and the anisotropic etch process that forms the first via openings 179A and the second via openings 179B etches the material of the capping dielectric layer 173 at a same etch rate. Thus, surfaces of the upper protrusion portions 166P are physically exposed underneath the second via openings 179B before the first top surface segments TSS1 of the ESD path metal structures 168 are exposed underneath the first via openings 179A during the anisotropic etch process.

FIG. 4A corresponds to a point in time during the anisotropic etch process at which surfaces of the upper protrusion portions 166P are physically exposed underneath the second via openings 179B while the first top surface segments TSS1 of the ESD path metal structures 168 are still covered by the material of the capping dielectric layer 173. Upon physical exposure of the surfaces of the upper protrusion portions 166P to the plasma ambient in an anisotropic etch process chamber, electrostatic discharge of electrical charges may occur from the plasma through the ESD path metal structures 168 and the discharge current path (DCP; shown in FIG. 1) into the ESD protection circuit 122 (shown in FIG. 1) such that semiconductor devices 120 that are electrically connected to the ESD path metal structures 168 are protected from an instantaneous surge of electrical charges in the ESD path metal structures 168. As such, the upper protrusion portions 166P of the ESD path metal structures 168 function as leading point of discharge (LPoD) structures that are exposed to a plasma during the anisotropic etch process prior to exposure of other metallic structures in the semiconductor die 700, and thus function as a connection point for an electrical discharge path in the semiconductor die 700 at the moment of exposure to the plasma.

Referring to FIG. 4B, the anisotropic etch process may be continued until the first via openings 179A vertically extend to a respective underlying portion of the passivation-level metal structures 167 and the ESD path metal structure 168. Surfaces of the passivation-level metal structures 167 and the ESD path metal structure 168 may be physically exposed underneath the first via openings 179A and the second via openings 179B after the anisotropic etch process. Each of the via openings (179A, 179B) may have at least one tapered sidewall that extends from a top surface of the capping dielectric layer 173 to a top surface of one of the passivation-level metal structures 167 and the ESD path metal structure 168. The taper angle of the tapered sidewalls, as measured from a vertical direction, may be in a range from 5 degrees to 60 degrees, such as from 10 degrees to 45 degrees, although lesser and greater taper angles may also be used. The lateral dimension of the bottom portion of each via opening (179A, 179B) (such as a diameter or a width of a physically exposed surface of a respective one of the passivation-level metal structures 167 and the ESD path metal structure 168) may be in a range from 30 microns to 50 microns, although lesser and greater lateral dimensions may also be used.

The capping dielectric layer 173 may have a planar top surface located within a second horizontal plane HP2. The thickness of the capping dielectric layer 173, as measured between the second horizontal plane HP2 and the first horizontal plane HP1 including the first top surface segments TSS1, may be in a range from 2 microns to 6 microns, although lesser and greater thicknesses may also be used. The height of the upper protrusion portions 166P may be in a range from 400 nm to 4 microns. The ratio of the height of the upper protrusion portions 166P to the thickness of the capping dielectric layer 173 may be in a range from 0.2 to 0.8, although lesser and greater ratios may also be used.

Referring to FIG. 4C, a metallic seed layer 174 may be formed over the capping dielectric layer 173. The metallic seed layer 174 comprises at least one metallic material that may function as an adhesion promoter material, a diffusion barrier material, and/or a metallic seed material for a subsequent electroplating process. For example, the metallic seed layer 174 may comprise a layer stack of a titanium layer and a copper seed layer, which may be deposited by physical vapor deposition. The thickness of the titanium layer may be in a range from 5 nm to 100 nm, and the thickness of the copper seed layer may be in a range from 50 nm to 500 nm, although lesser and greater thicknesses may be used for the titanium layer and the copper seed layer, respectively.

A second photoresist layer 175 may be deposited over the metallic seed layer 174, and may be lithographically patterned to form openings in areas in which metallic bonding pads are to be subsequently formed. The thickness of the second photoresist layer 175 may be in a range from 2 microns to 20 microns, although lesser and greater thicknesses may also be used. The areas for forming the metallic bonding pads correspond to the areas of the via openings (179A, 179B) through the capping dielectric layer 173. The lateral dimension of each opening in the second photoresist layer 175 (which may be, for example, a width in embodiments in which each opening has a shape of a rectangle or a rounded rectangle) may be in a range from 50 microns to 80 microns, although lesser and greater lateral dimensions may also be used.

Referring to FIG. 4D, a metal may be deposited within the openings in the second photoresist layer 175. For example, an electroplating process may be performed to electroplate copper or a copper-containing alloy within areas of openings in the second photoresist layer 175. Pad-level metal portions 176 may be formed by the electroplating process within the areas of openings in the second photoresist layer 175.

Referring to FIG. 4E, the second photoresist layer 175 may be removed, for example, by ashing. Subsequently, an isotropic etch process such as a wet etch process may be performed to remove unmasked portions of the metallic seed layer 174. Physically exposed surface portions of the pad-level metal portions 176 may be collaterally removed during the isotropic etch process. Each remaining contiguous combination of a metallic seed layer 164 and a pad-level metal portion 176 constitutes a metallic bonding pad 178. While the present disclosure is described using an embodiment in which the metallic bonding pads 178 comprise copper, embodiments are expressly contemplated herein in which the metallic bonding pads 178 comprise an aluminum-based metallic material or other alternative metallic materials. Generally, the metallic bonding pads 178 are formed on the passivation-level metal structures 167 and the ESD path metal structures 168. Each of the metallic bonding pads 178 may comprise a respective via portion and a respective pad portion.

According to an aspect of the present disclosure, a first metallic bonding pad 178A may be formed in each first via opening 179A directly on a first top surface segment TSS1 of a respective one of the ESD path metal structures 168, and a second metallic bonding pad 178B may be formed in each second via opening 179B directly on a top surface of an upper protrusion portion 166P of a respective one of the ESD path metal structures 168. A planar top surface of the capping dielectric layer 173 may be formed in a second horizontal plane HP2 that overlies the first horizontal plane HP1. In one embodiment, each of the first metallic bonding pads 178A and the second metallic bonding pads 178B may be formed with a respective planar portion overlying the second horizontal plane HP2 and a respective via portion underlying the second horizontal plane HP2 and vertically extending through the capping dielectric layer 173. Generally, a via portion of each first metallic bonding pad 178A has a greater vertical extent than a via portion of each second metallic bonding pad 178B.

Referring to FIG. 4F, solder material portions 188, such as solder balls, may be attached to the metallic bonding pads 178. For example, a first solder material portion 188A may be attached to each first metallic bonding pad 178A, and a second solder material portion 188B may be attached to each second metallic bonding pad 178B. Subsequently, the semiconductor wafer including a two-dimensional array of semiconductor dies 700 may be diced along dicing channels to singulate the semiconductor dies 700.

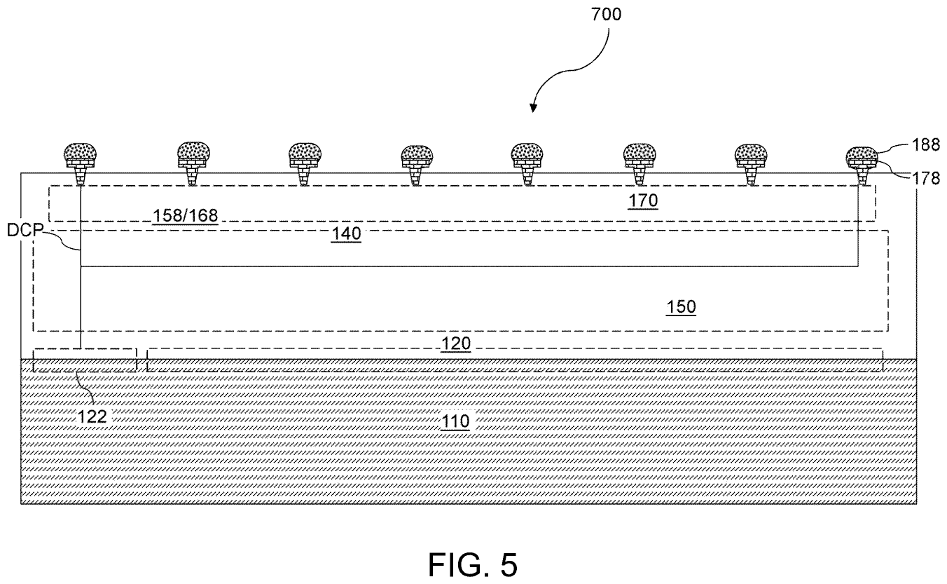

FIG. 5 is a vertical cross-sectional view of the semiconductor die 700 of the first embodiment structure after dicing according to the first embodiment of the present disclosure. The combination of the first passivation dielectric layer 161, the second passivation dielectric layer 163, and the capping dielectric layer 173 is represented as bonding-level dielectric layers 170.

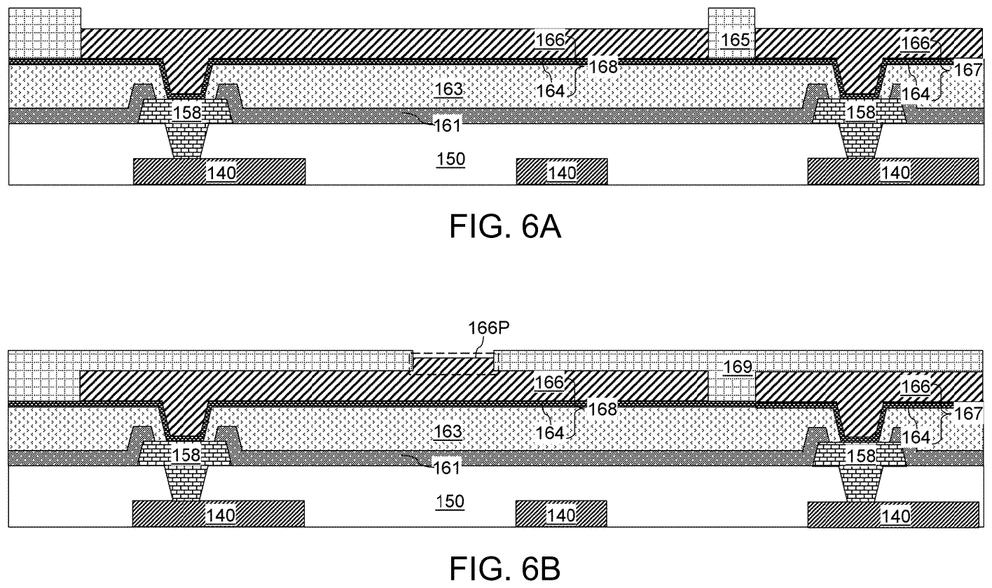

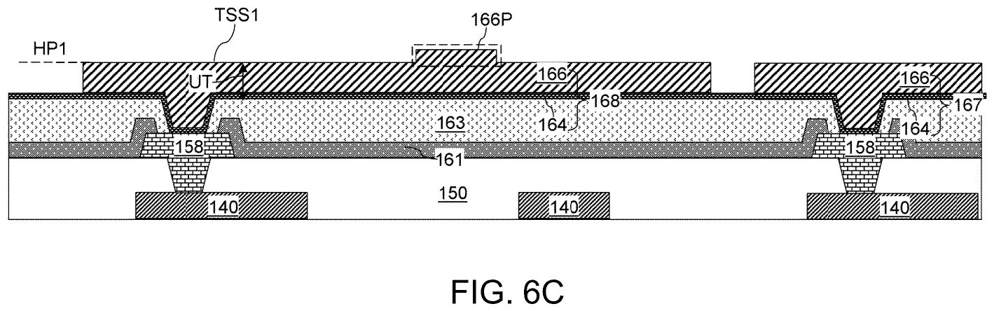

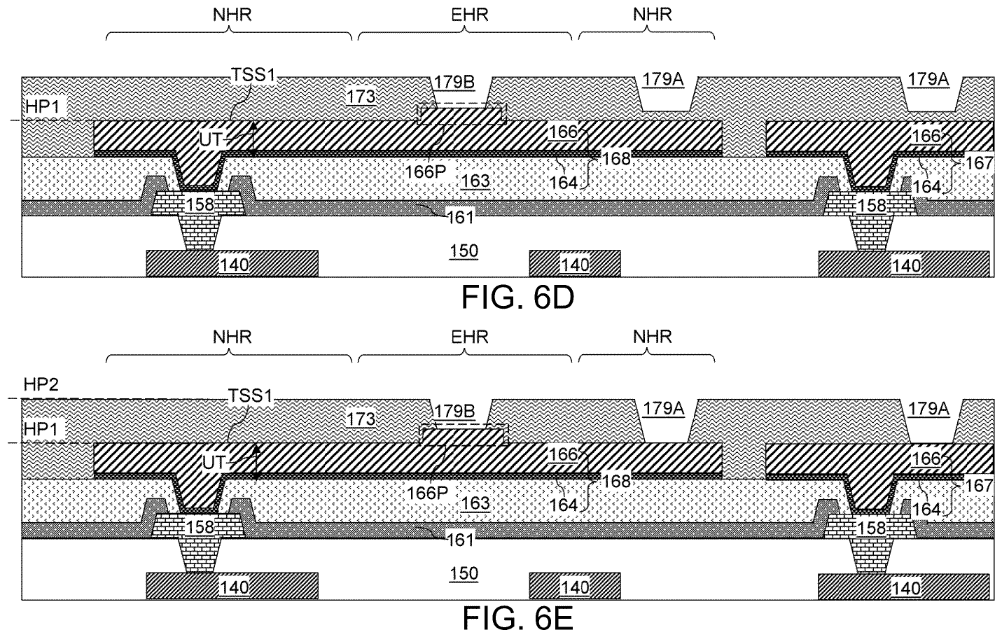

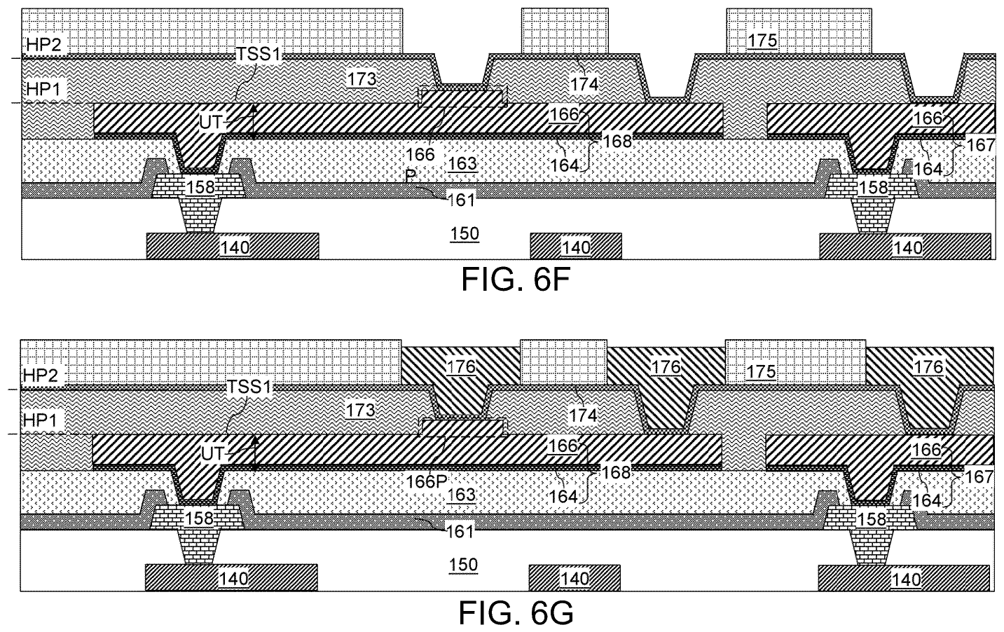

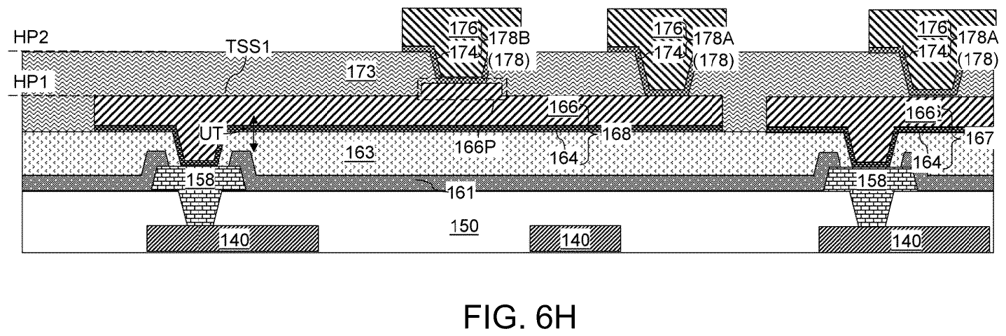

FIGS. 6A-61 are sequential vertical cross-sectional views of a region of an alternative configuration of the first embodiment structure during formation of a leading point of discharge structure and metallic bonding pads and attachment of solder material portions 188 according to the first embodiment of the present disclosure.

Referring to FIG. 6A, the alternative configuration of the first embodiment structure is illustrated at a processing step that corresponds to the processing step of FIG. 2E. In this embodiment, the electroplating process that forms the copper-based metal portions 166 may, or may not, conformally deposit a copper-based material. Each copper-based metal portion 166 includes a planar top surface, which may be located entirely within a horizontal plane, or may include a vertically protruding portion that protrudes above a horizontal plane including a horizontal top surface segment of a respective copper-based metal portion 166. The first photoresist layer 165 may be subsequently removed, for example, by ashing.

Referring to FIG. 6B, an additional photoresist layer 169 (which may be referred to as a second photoresist layer in the claims) may be applied over the metallic seed layer 164 and the copper-based metal portions 166, and may be lithographically patterned to form openings therein. Each of the openings in the additional photoresist layer 169 may have an area that is located entirely within the area of an underlying copper-based metal portion 166. An additional electroplating process may be performed to form an upper protrusion portion 166P within each opening in the additional photoresist layer 169. Each upper protrusion portion 166P may have a respective planar top surface segment. The height of each upper protrusion portion 166P may be in a range from 400 nm to 4 microns, such as from 800 nm to 2 microns, although lesser and greater heights may also be used.

Referring to FIG. 6C, the additional photoresist layer 169 may be removed, for example, by ashing. Subsequently, an isotropic etch process such as a wet etch process may be performed to remove unmasked portions of the metallic seed layer 164. Physically exposed surface portions of the copper-based metal portions 166 may be collaterally removed during the isotropic etch process.

Each remaining contiguous combination of a metallic seed layer 164 and a first copper-based metal portion 166 including a respective upper protrusion portion 166P is herein referred to as an electrostatic discharge (ESD) path metal structure 168. Each remaining contiguous combination of a metallic seed layer 164 and a second copper-based metallic portion 166 that does not include any upper protrusion portion 166P is herein referred to as a passivation-level metal structure 167. Generally, passivation-level metal structures 167 and at least one electrostatic discharge (ESD) path metal structure 168 may be formed. Each ESD path metal structure 168 comprises a first top surface segment TSS1 located within a first horizontal plane HP1 that contains a top surface of one, a plurality, and/or each, of the passivation-level metal structures 167. Further, each ESD path metal structure 168 comprises an upper protrusion portion 166P that protrudes above the first horizontal plane HP1. In one embodiment, the entirely of the passivation-level metal structures 167 may be formed below, or within, the first horizontal plane HP1.

The passivation-level metal structures 167 and the ESD path metal structures 168 may comprise a respective via portion contacting a respective underlying metal pad structure 158. The uniform thickness UT of horizontally-extending portions of the passivation-level metal structures 167 and the ESD path metal structures 168 outside the areas of the via portions and outside the areas of the upper protrusion portions 166P may be in a range from 1 micron to 8 microns, although lesser and greater thicknesses may also be used. The height of the upper protrusion portions 166P may be in a range from 10% to 80% of the uniform thickness UT, and may be in a range from 400 nm to 4 microns, such as from 800 nm to 2 microns.

Generally, the passivation-level metal structures 167 and the ESD path metal structure 168 may be formed by performing at least one electroplating process. In one embodiment, the ESD path metal structure 168 may be formed using two electroplating processes using two electroplating mask layers. In one embodiment, each upper protrusion portion 166P may be formed with a planar top surface segment and at least one vertical surface segment having a bottom periphery within the first horizontal plane HP1. In one embodiment, the passivation-level metal structures 167 and the at least one uniform-thickness region of the ESD path metal structure 168 that does not have an areal overlap with the upper protrusion portion 166P are formed by a first metal deposition process (such as a first electroplating process), and the upper protrusion portion 166P is formed by a second metal deposition process (such as a second electroplating process) that is performed after the first metal deposition process.

Referring to FIG. 6D, the processing steps described with reference to FIG. 4A may be performed to form a capping dielectric layer 173, and to form via openings (179A, 179B) that vertically extend through the capping dielectric layer 173. According to an aspect of the present disclosure, the via openings (179A, 179B) comprise first via openings 179A that are formed over the horizontally-extending portions of the passivation-level metal structures 167 and the ESD path metal structure 168 having the uniform thickness UT, and second via openings 179B that are formed over the upper protrusion portions 166P. The upper protrusion portions 166P protrude above the first horizontal plane HP1, and the anisotropic etch process that forms the first via openings 179A and the second via openings 179B etches the material of the capping dielectric layer 173 at a same etch rate. Thus, surfaces of the upper protrusion portions 166P are physically exposed underneath the second via openings 179B before the first top surface segments TSS1 of the ESD path metal structures 168 are exposed underneath the first via openings 179A during the anisotropic etch process.

FIG. 6D corresponds to a point in time during the anisotropic etch process at which surfaces of the upper protrusion portions 166P are physically exposed underneath the second via openings 179B while the first top surface segments TSS1 of the ESD path metal structures 168 are still covered by the material of the capping dielectric layer 173. Upon physical exposure of the surfaces of the upper protrusion portions 166P to the plasma ambient in an anisotropic etch process chamber, electrostatic discharge of electrical charges may occur from the plasma through the ESD path metal structures 168 and the discharge current path (DCP; shown in FIG. 1) into the ESD protection circuit 122 (shown in FIG. 1) such that semiconductor devices 120 that are electrically connected to the ESD path metal structures 168 are protected from an instantaneous surge of electrical charges in the ESD path metal structures 168. As such, the upper protrusion portions 166P of the ESD path metal structures 168 function as leading point of discharge (LPoD) structures that are exposed to a plasma during the anisotropic etch process prior to exposure of other metallic structures in the semiconductor die 700, and thus function as a connection point for an electrical discharge path in the semiconductor die 700 at the moment of exposure to the plasma.

Referring to FIG. 6E, the anisotropic etch process may be continued until the first via openings 179A vertically extend to a respective underlying portion of the passivation-level metal structures 167 and the ESD path metal structure 168. Surfaces of the passivation-level metal structures 167 and the ESD path metal structure 168 may be physically exposed underneath the first via openings 179A and the second via openings 179B after the anisotropic etch process. Each of the via openings (179A, 179B) may have at least one tapered sidewall that extends from a top surface of the capping dielectric layer 173 to a top surface of one of the passivation-level metal structures 167 and the ESD path metal structure 168. The taper angle of the tapered sidewalls, as measured from a vertical direction, may be in a range from 5 degrees to 60 degrees, such as from 10 degrees to 45 degrees, although lesser and greater taper angles may also be used. The lateral dimension of the bottom portion of each via opening (179A, 179B) (such as a diameter or a width of a physically exposed surface of a respective one of the passivation-level metal structures 167 and the ESD path metal structure 168) may be in a range from 30 microns to 50 microns, although lesser and greater lateral dimensions may also be used.

The capping dielectric layer 173 may have a planar top surface located within a second horizontal plane HP2. The thickness of the capping dielectric layer 173, as measured between the second horizontal plane HP2 and the first horizontal plane HP1 including the first top surface segments TSS1, may be in a range from 2 microns to 6 microns, although lesser and greater thicknesses may also be used. The height of the upper protrusion portions 166P may be in a range from 400 nm to 4 microns. The ratio of the height of the upper protrusion portions 166P to the thickness of the capping dielectric layer 173 may be in a range from 0.2 to 0.8, although lesser and greater ratios may also be used.

Referring to FIG. 6F, a metallic seed layer 174 may be formed over the capping dielectric layer 173. The metallic seed layer 174 comprises at least one metallic material that may function as an adhesion promoter material, a diffusion barrier material, and/or a metallic seed material for a subsequent electroplating process. For example, the metallic seed layer 174 may comprise a layer stack of a titanium layer and a copper seed layer, which may be deposited by physical vapor deposition. The thickness of the titanium layer may be in a range from 5 nm to 100 nm, and the thickness of the copper seed layer may be in a range from 50 nm to 500 nm, although lesser and greater thicknesses may be used for the titanium layer and the copper seed layer, respectively.

A second photoresist layer 175 may be deposited over the metallic seed layer 174, and may be lithographically patterned to form openings in areas in which metallic bonding pads are to be subsequently formed. The thickness of the second photoresist layer 175 may be in a range from 2 microns to 20 microns, although lesser and greater thicknesses may also be used. The areas for forming the metallic bonding pads correspond to the areas of the via openings (179A, 179B) through the capping dielectric layer 173. The lateral dimension of each opening in the second photoresist layer 175 (which may be, for example, a width in embodiments in which each opening has a shape of a rectangle or a rounded rectangle) may be in a range from 50 microns to 80 microns, although lesser and greater lateral dimensions may also be used.

Referring to FIG. 6G, a metal may be deposited within the openings in the second photoresist layer 175. For example, an electroplating process may be performed to electroplate copper or a copper-containing alloy within areas of openings in the second photoresist layer 175. Pad-level metal portions 176 may be formed by the electroplating process within the areas of openings in the second photoresist layer 175.

Referring to FIG. 6H, the second photoresist layer 175 may be removed, for example, by ashing. Subsequently, an isotropic etch process such as a wet etch process may be performed to remove unmasked portions of the metallic seed layer 174. Physically exposed surface portions of the pad-level metal portions 176 may be collaterally removed during the isotropic etch process. Each remaining contiguous combination of a metallic seed layer 164 and a pad-level metal portion 176 constitutes a metallic bonding pad 178. While the present disclosure is described using an embodiment in which the metallic bonding pads 178 comprise copper, embodiments are expressly contemplated herein in which the metallic bonding pads 178 comprise an aluminum-based metallic material or other alternative metallic materials. Generally, the metallic bonding pads 178 are formed on the passivation-level metal structures 167 and the ESD path metal structures 168. Each of the metallic bonding pads 178 may comprise a respective via portion and a respective pad portion.

According to an aspect of the present disclosure, a first metallic bonding pad 178A may be formed in each first via opening 179A directly on a first top surface segment TSS1 of a respective one of the ESD path metal structures 168, and a second metallic bonding pad 178B may be formed in each second via opening 179B directly on a top surface of an upper protrusion portion 166P of a respective one of the ESD path metal structures 168. A planar top surface of the capping dielectric layer 173 may be formed in a second horizontal plane HP2 that overlies the first horizontal plane HP1. In one embodiment, each of the first metallic bonding pads 178A and the second metallic bonding pads 178B may be formed with a respective planar portion overlying the second horizontal plane HP2 and a respective via portion underlying the second horizontal plane HP2 and vertically extending through the capping dielectric layer 173. Generally, a via portion of each first metallic bonding pad 178A has a greater vertical extent than a via portion of each second metallic bonding pad 178B.

Referring to FIG. 6I, solder material portions 188, such as solder balls, may be attached to the metallic bonding pads 178. For example, a first solder material portion 188A may be attached to each first metallic bonding pad 178A, and a second solder material portion 188B may be attached to each second metallic bonding pad 178B.

Subsequently, the semiconductor wafer including a two-dimensional array of semiconductor dies 700 may be diced along dicing channels to singulate the semiconductor dies 700.

Referring collectively to FIGS. 4F, 5, and 61 and according to the first embodiment of the present disclosure, a device structure is provided, which comprises: semiconductor devices 120 located on a semiconductor substrate 110; passivation-level metal structures 167 and an electrostatic discharge (ESD) path metal structure 168 embedded in a capping dielectric layer 173, wherein the ESD path metal structure 168 comprises a first top surface segment TSS1 located within a first horizontal plane HP1 that contains a top surface of one of the passivation-level metal structures 167 and further comprises an upper protrusion portion 166P that protrudes above the first horizontal plane HP1; a first metallic bonding pad 178A having a planar bottom surface that contacts the first top surface segment TSS1; and a second metallic bonding pad 178B contacting a top surface of the upper protrusion portion 166P.

In one embodiment, the device structure further comprises: a first solder material portion 188A contacting the first metallic bonding pad 178A; and a second solder material portion 188B contacting the second metallic bonding pad 178B. In one embodiment, the upper protrusion portion 166P has at least one tilted top surfaces each having a tilt angle relative to the first horizontal plane HP1 in a range from 0.1 degree to 10 degrees. In one embodiment, a first areal metal density at a level of the passivation-level metal structures 167 and the electrostatic discharge (ESD) path metal structure 168 within a region including the upper protrusion portion 166P of the ESD path metal structure 168 is less than a second areal metal density at the level of the passivation-level metal structures 167 and the electrostatic discharge (ESD) path metal structure 168 within a region of the passivation-level metal structures 167 is by a factor of at least 3. In another embodiment, the upper protrusion portion 166P comprises a planar top surface segment and at least one vertical surface segment having a bottom periphery within the first horizontal plane HP1.

In one embodiment, the upper protrusion portion 166P of the ESD path metal structure 168 has a same material composition as a portion of said one of the passivation-level metal structures 167 that underlie the first horizontal plane HP1. In one embodiment, the upper protrusion portion 166P of the ESD path metal structure 168 comprises copper at an atomic percentage of at least 98%.

In one embodiment, a second horizontal plane HP2 including a planar top surface of the capping dielectric layer 173 is located above the first horizontal plane HP1; and each of the first metallic bonding pad 178A and the second metallic bonding pad 178B comprises a respective planar portion overlying the second horizontal plane HP2 and a respective via portion underlying the second horizontal plane HP2 and vertically extending through the capping dielectric layer 173. In one embodiment, a via portion of the first metallic bonding pad 178A has a greater vertical extent than a via portion of the second metallic bonding pad 178B.

In one embodiment, the device structure further comprises: an electrostatic discharge (ESD) protection circuit 122 located on the semiconductor substrate 110; and metal interconnect structures 140 embedded in dielectric material layers 150 that are located between the semiconductor substrate 110 and the capping dielectric layer 173, wherein the ESD path metal structure 168 is electrically connected to the ESD protection circuit 122 through a subset of the metal interconnect structures 140.

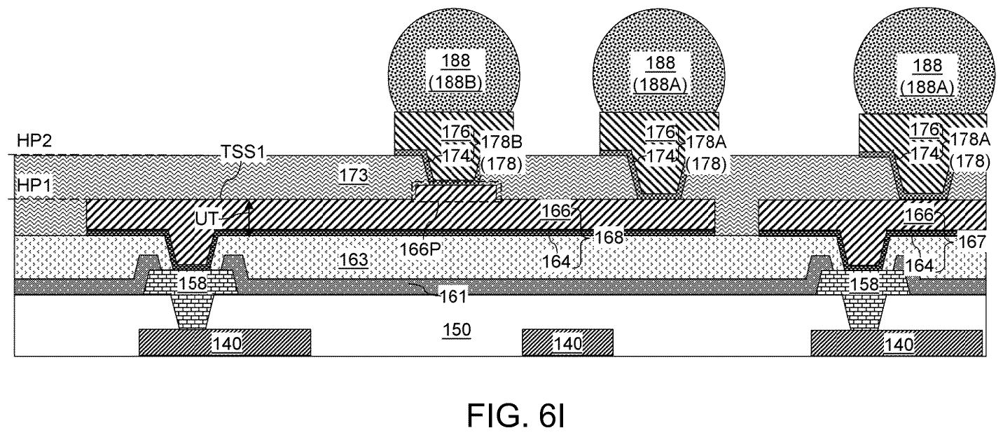

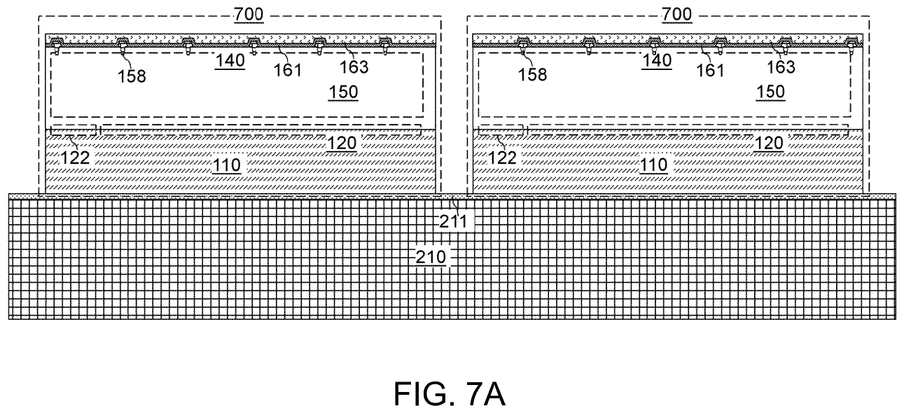

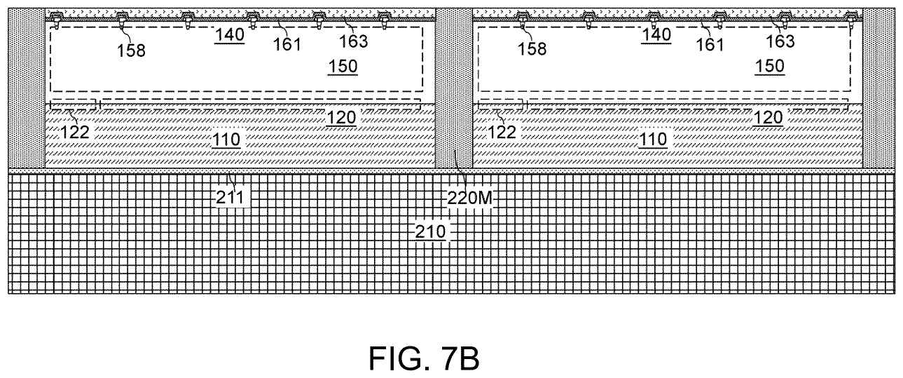

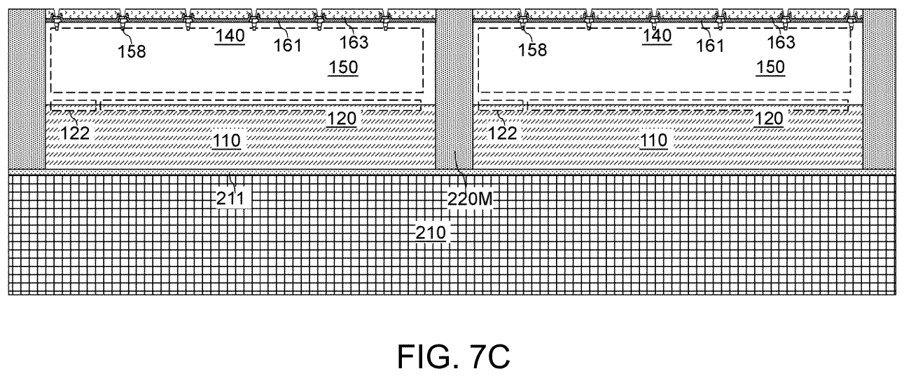

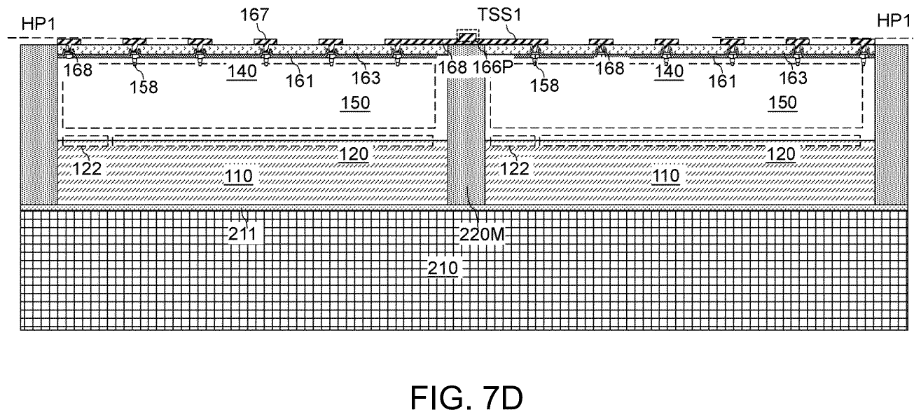

FIGS. 7A-7D are sequential vertical cross-sectional views of a second embodiment structure during formation of leading point of discharge structures according to a second embodiment of the present disclosure.

Referring to FIG. 7A, the second embodiment structure comprises a carrier substrate 210, which may be a carrier wafer on which a reconstituted wafer including a two-dimensional array of repetition units each including a respective composite die may be subsequently formed. The illustrated area in FIG. 7A corresponds to a unit area in which a single repetition unit in which a single composite die is subsequently formed. As such, the structure illustrated in FIG. 7A may be repeated in two horizontal directions to provide a two-dimensional periodic array of repetition units. The illustrated portion of the carrier substrate 210 is a portion of the carrier substrate 210 located within the area of a single repetition unit. The carrier substrate 210 may be any type of carrier substrate for forming a reconstituted wafer thereupon. For example, the carrier substrate 210 may comprise a silicon wafer, a glass wafer, a sapphire wafer, or any other recyclable wafer.

An adhesive layer 211 may be applied to the top surface of the carrier substrate 210. At least one semiconductor die 700 may be attached to the adhesive layer 211 within each unit area such that a two-dimensional periodic array of sets of at least one semiconductor die 700 may be attached to the carrier substrate 210. In one embodiment, each set of at least one semiconductor die 700 is disposed within a respective unit area, and may comprise at least two semiconductor dies 700 which include a first semiconductor die 700 and a second semiconductor die 700. The first semiconductor die 700 and the second semiconductor die 700 may be disposed over the carrier substrate 210 with a gap therebetween. Each semiconductor die 700 may be derived from the semiconductor die 700 illustrated in FIG. 1 by performing the processing steps described with reference to FIG. 2B (i.e., by depositing and patterning a first passivation dielectric layer 161) and by depositing a second passivation dielectric layer 163 thereupon. Subsequently, at least two semiconductor die 700 may be attached to the carrier substrate 210 within each unit area.

Generally, a first semiconductor die 700 and a second semiconductor die 700 may be attached to a carrier substrate 210. The first semiconductor die 700 comprises a first semiconductor substrate 110 and a first electrostatic discharge (ESD) protection circuit 122 that is electrically connected to the first semiconductor substrate 110. The second semiconductor die 700 comprises a second semiconductor substrate 110 and a second electrostatic discharge (ESD) protection circuit 122 that is electrically connected to the second semiconductor substrate 110. Discharge current paths DCP may be provided in each of the semiconductor dies 700 as illustrated in FIG. 1.

Referring to FIG. 7B, a molding compound material may applied to the gaps between neighboring pairs of semiconductor dies 700. A planarization process (e.g., chemical mechanical polish (CMP)) and a curing process may be performed to form a molding compound matrix 220M. The molding compound matrix 220M laterally surrounds, and embeds, each of the semiconductor dies 700. The combination of the molding compound matrix 220M and the semiconductor dies 700 constitutes a reconstituted wafer, which may have the same lateral extent as the carrier substrate 210. In one embodiment, top surfaces of the second passivation dielectric layers 163 of the semiconductor dies 700 may be coplanar with the top surface of the molding compound matrix 220M. Each portion of the molding compound matrix 220M located within a respective unit area constitutes a molding compound die frame that laterally surrounds a respective set of at least one semiconductor die 700 within the respective unit area.

Referring to FIG. 7C, via openings may be formed through the second passivation dielectric layers 163 by a combination of lithographic processing steps and an anisotropic etch process. Top surfaces of the metal pad structures 158 may be physically exposed underneath the via openings through the second passivation dielectric layer 163.

Referring to FIG. 7D, the processing steps described with reference to FIGS. 2D-2F or the processing steps described with reference to FIGS. 2D, 2E, and 6A-6C may be performed to form patterned metal structures (167, 168). The patterned metal structures (167, 168) within each unit area comprise first passivation-level metal structures 167 that are formed on a first semiconductor die 700, second passivation-level metal structures 167 that are formed on a second semiconductor die 700, and at least one electrostatic discharge (ESD) path metal structure 168 that is formed on a top surface of a molding compound die frame (which is a portion of the molding compound matrix 220M that is located within the unit area) and is electrically connected to the first ESD protection circuit 122 in the first semiconductor die 700, and may be electrically connected to the second ESD protection circuit 122 in the second semiconductor die 700. In one embodiment, at least one ESD path metal structure 168 extends through the molding compound matrix, and is formed on a top surface of the first semiconductor die 700 and on a top surface of the second semiconductor die 700.

Generally, each ESD path metal structure 168 in the second embodiment structure may have any feature described with reference to the first embodiment structure with a possible modification that that at least one of the ESD path metal structures 168 may be formed over, and directly on, the molding compound matrix 220M. In one embodiment, an ESD path metal structure 168 in the second embodiment structure may comprises a first top surface segment TSS1 located within a first horizontal plane HP1 that contains a top surface of one of the first passivation-level metal structures 167 and a top surface of one of the second passivation-level metal structures 167, and further comprises an upper protrusion portion 166P that protrudes above the first horizontal plane HP1. Generally, the first passivation-level metal structures 167 and the ESD path metal structure 168 are formed by performing at least one electroplating process.

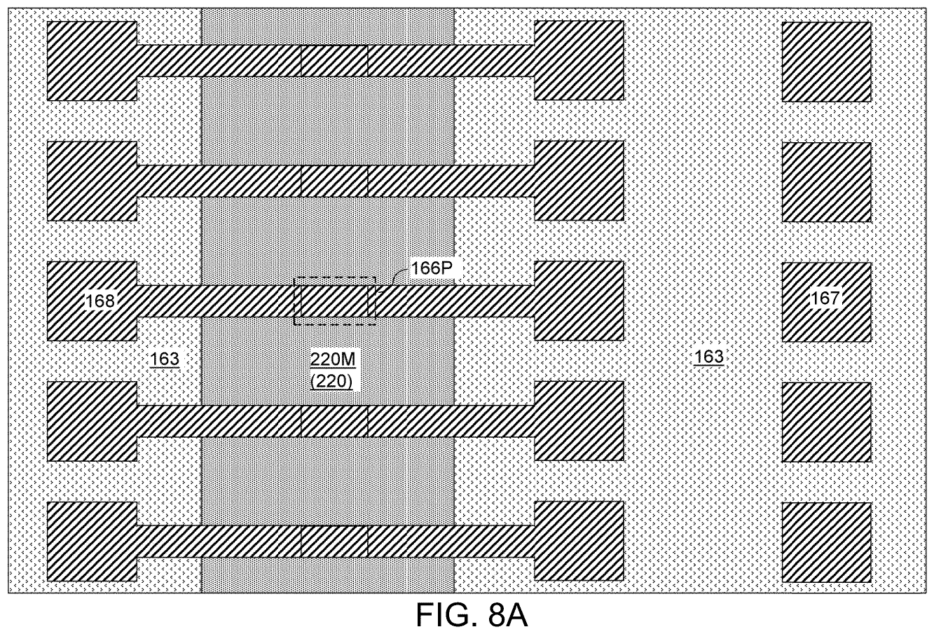

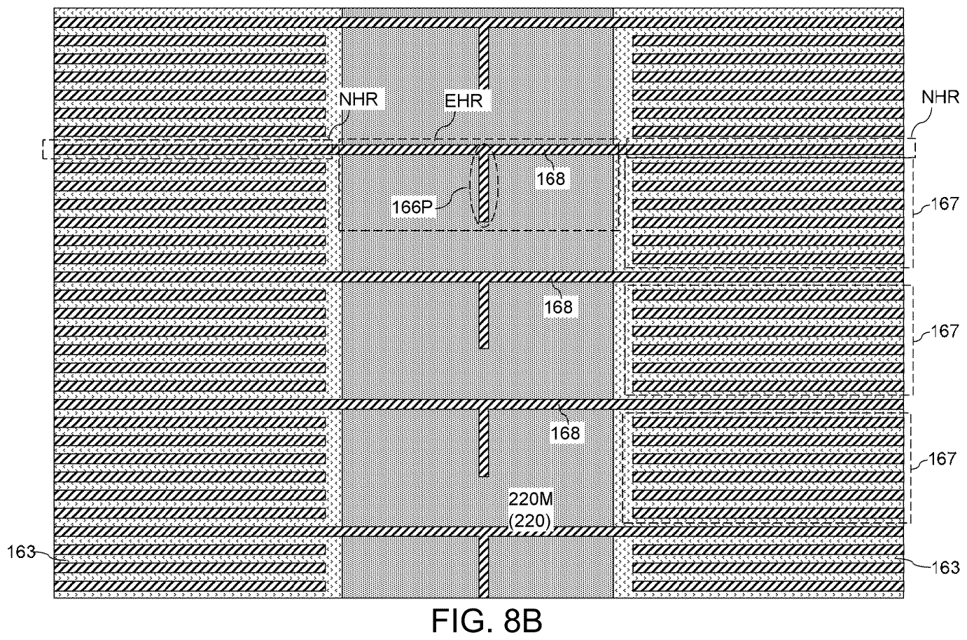

FIG. 8A is a top-down view of a region of the second embodiment structure of FIG. 7D according to the second embodiment of the present disclosure. Referring collectively to FIGS. 7D and 8A, at least one upper protrusion portion 166P has an areal overlap with a molding compound die frame 220 in a plan view. The molding compound die frame 220 is a portion of the molding compound matrix 220M that is located within a unit area of the two-dimensional periodic array of sets of at least two semiconductor dies 700. The molding compound die frame 220 laterally surrounds at least the first semiconductor die 700 and the second semiconductor die 700.

In the configuration illustrated in FIG. 8A, an upper protrusion portion 166P may be formed with a planar top surface segment and at least one vertical surface segment having a bottom periphery within the first horizontal plane HP1. In one embodiment, the first passivation-level metal structures 167 and a uniform-thickness region of the ESD path metal structure 168 that does not have an areal overlap with the upper protrusion portion 166P are formed by a first metal deposition process; and the upper protrusion portion 166P is formed by a second metal deposition process that is performed after the first metal deposition process.

FIG. 8B is a top-down view of a region of an alternative configuration of the second embodiment structure according to the second embodiment of the present disclosure. Referring collectively to FIGS. 7D and 8B, at least one upper protrusion portion 166P has an areal overlap with a molding compound die frame 220 in a plan view. Generally, the first passivation-level metal structures 167 and each ESD path metal structure 168 are formed by performing at least one electroplating process. In one embodiment, the first passivation-level metal structures 167 and each electrostatic discharge (ESD) path metal structure 168 are simultaneously formed using a single deposition process that provides pattern-factor-dependent deposition rates.

In one embodiment, the upper protrusion portion 166P is formed with at least one tilted top surfaces each having a tilt angle relative to the first horizontal plane HP1 in a range from 0.1 degree to 10 degrees. In one embodiment, a first areal metal density at a level of the patterned metal structures (167, 168) within a region including the upper protrusion portion 166P of the ESD path metal structure 168 is less than a second areal metal density at the level of the patterned metal structures (167, 168) within a region of the passivation-level metal structures 167 is by a factor of at least 3.

Referring collectively to FIGS. 7D, 8A, and 8B and in one embodiment, the first semiconductor die 700 comprises first semiconductor devices 120 located on the first semiconductor substrate 110, and first metal interconnect structures 140 embedded in first dielectric material layers 150; the first semiconductor devices 120 comprises first field effect transistors; and an ESD path metal structure 168 is electrically connected to a node of one of the first field effect transistors through a subset of the first metal interconnect structures 140 in the first semiconductor die 700. In one embodiment, the second semiconductor die 700 comprises second semiconductor devices 120 located on the second semiconductor substrate 110, and second metal interconnect structures 140 embedded in second dielectric material layers 150; the second semiconductor devices 120 comprises second field effect transistors; and the ESD path metal structure 168 is electrically connected to a node of one of the second field effect transistors through a subset of the second metal interconnect structures 140 in the second semiconductor die 700.

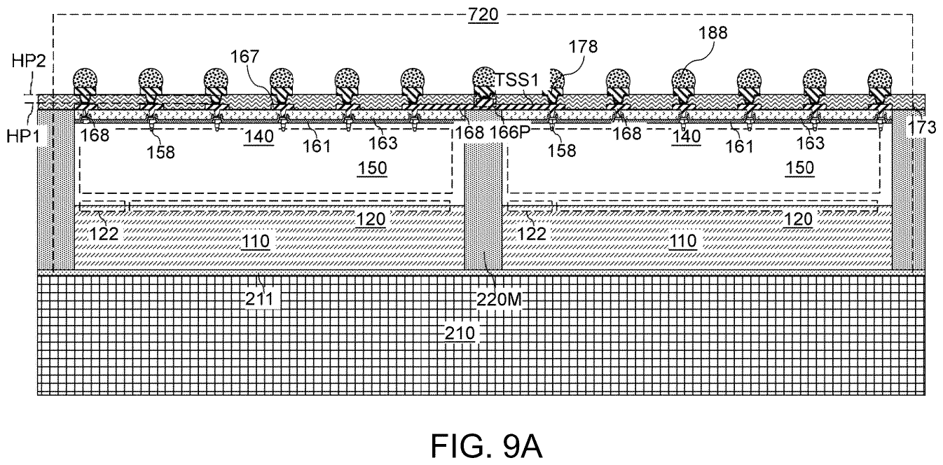

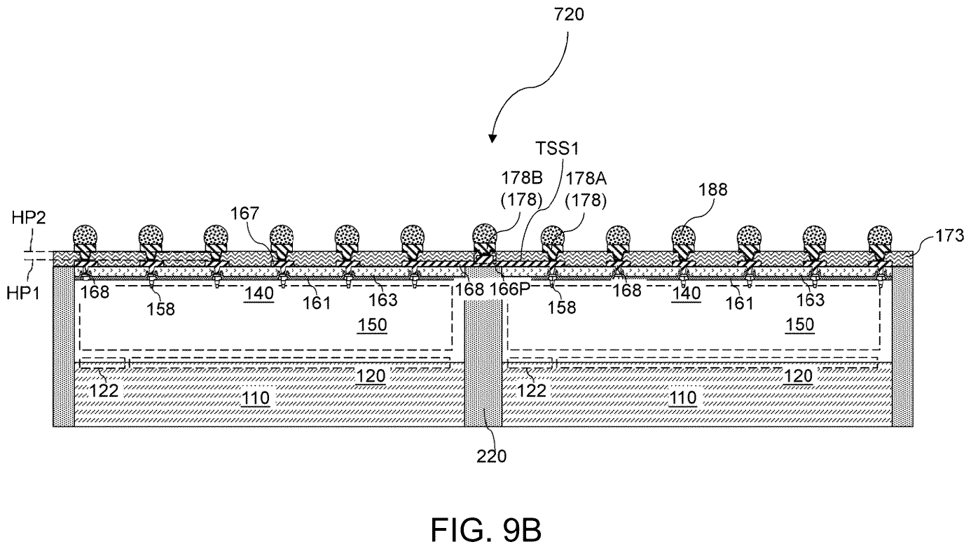

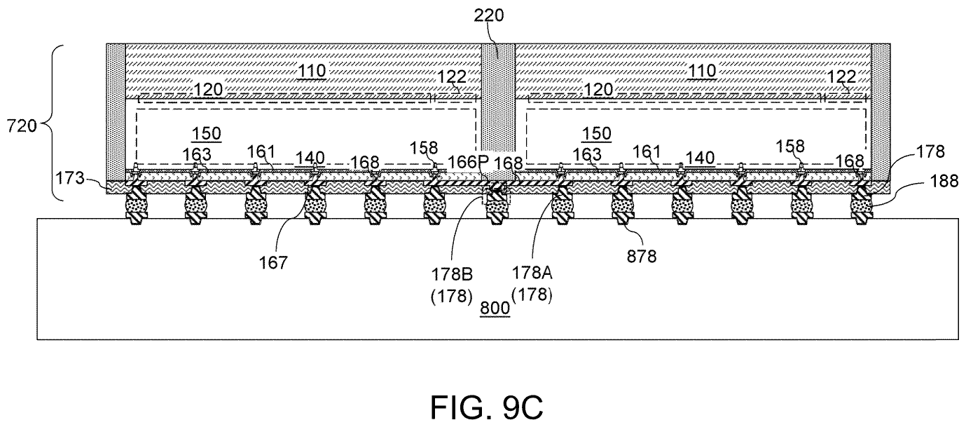

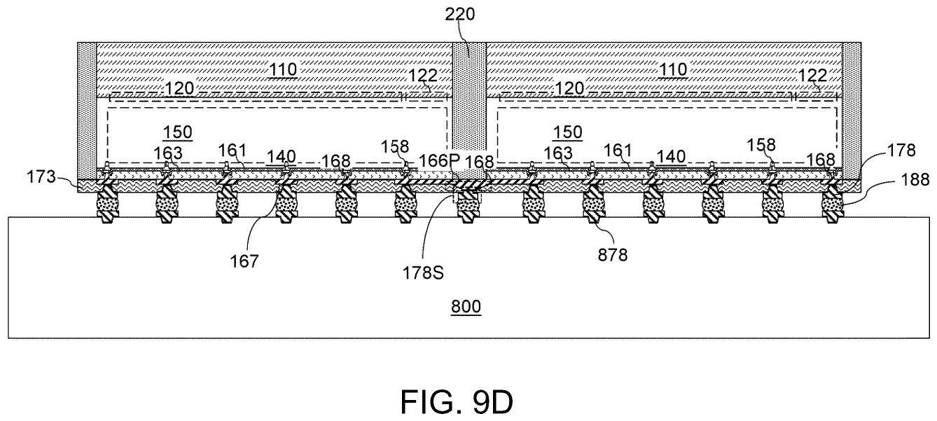

FIGS. 9A-9C are sequential vertical cross-sectional views of the second embodiment structure during dicing and attachment of a fan-out package to an interposer according to the second embodiment of the present disclosure.

Referring to FIG. 9A, the processing steps described with reference to FIGS. 4A-4F or the processing steps described with reference to FIGS. 6D-61 may be performed to form a capping dielectric layer 173 and metallic bonding pads 178, and to attach solder material portion 188 to the metallic bonding pads 178. The capping dielectric layer 173 may be formed over the patterned metal structures (167, 168) such that a planar top surface of the capping dielectric layer 173 is formed in a second horizontal plane HP2 that overlies the first horizontal plane HP1.

The metallic bonding pads 178 comprise first metallic bonding pads 178A and second metallic bonding pads 178B. Each of the first metallic bonding pad 178A and the second metallic bonding pad 178B is formed with a respective planar portion overlying the second horizontal plane HP2 and a respective via portion underlying the second horizontal plane HP2 and vertically extending through the capping dielectric layer 173. Each first metallic bonding pad 178A may be formed on a horizontal top surface of a respective patterned metal structures (167, 168) located within the first horizontal plane HP1, and second metallic bonding pad 178B may be formed on a horizontal or non-horizontal surface of a respective upper protrusion portion 166P that is located above the first horizontal plane HP1. Thus, a via portion of each first metallic bonding pad 178A has a greater vertical extent than a via portion of the second metallic bonding pad 178B.

In one embodiment, a first metallic bonding pad 178A and a second metallic bonding pad 178B may be formed over, and directly on, an ESD path metal structure 168. The first metallic bonding pad 178A has a planar bottom surface that contacts a first top surface segment TSS1; and the second metallic bonding pad 178B contacts a top surface of the upper protrusion portion 166P. In some embodiments, the first metallic bonding pad 178A has an areal overlap with the molding compound die frame 220 in a plan view; and the second metallic bonding pad 178B is located entirely within an area of the first semiconductor die 700 in the plan view. Subsequently, the solder material portions 188 may be attached to the metallic bonding pads 178.

Referring to FIG. 9B, the carrier substrate 210 may be detached from the reconstituted wafer (700, 220M), for example, by decomposing the adhesive layer 211. A suitable clean process may be performed to remove residues of the adhesive layer 211. Subsequently, the reconstituted wafer (700, 220M) may be diced along dicing channels to form a plurality of fan-out packages 720, one of which is illustrated in FIG. 9B. Each fan-out package 720 may be a composite semiconductor die including a plurality of semiconductor dies 700 and a molding compound die frame 220, which is a diced portion of the molding compound matrix 220M.

Referring to FIG. 9C, an interposer 800 including interposer bonding pads 878 may be provided. The interposer 800 may comprise an organic interposer, a ceramic interposer, or any other type of interposer known in the art. The fan-out package 720 may be bonded to the interposer 800 through the solder material portions 188.

The second embodiment structure illustrated in FIG. 9C comprises a device structure, which comprises: a molding compound die frame 220 laterally surrounding a first semiconductor die 700 and a second semiconductor die 700; first passivation-level metal structures 167 that overlie the first semiconductor die 700; second passivation-level metal structures 167 that overlie the second semiconductor die 700; an electrostatic discharge (ESD) path metal structure 168 that overlies the first semiconductor die 700, the molding compound die frame 220, and the second semiconductor die 700, wherein the ESD path metal structure 168 comprises a first top surface segment TSS1 located within a first horizontal plane HP1 that contains a top surface of one of the first passivation-level metal structures 167 and a top surface of one of the second passivation-level metal structures 167, and further comprises an upper protrusion portion 166P that protrudes above the first horizontal plane HP1; a first metallic bonding pad 178A having a planar bottom surface that contacts the first top surface segment TSS1; and a second metallic bonding pad 178B contacting a top surface of the upper protrusion portion 166P.

In one embodiment, the device structure further compress: a first solder material portion 188A contacting the first metallic bonding pad 178A; and a second solder material portion 188B contacting the second metallic bonding pad 178B. In one embodiment, the first metallic bonding pad 178A has an areal overlap with the molding compound die frame 220 in a plan view; and the second metallic bonding pad 178B is located entirely within an area of the first semiconductor die 700 in the plan view. In one embodiment, the upper protrusion portion 166P has an areal overlap with the molding compound die frame 220 in a plan view.

In one embodiment, the upper protrusion portion 166P has at least one tilted top surfaces each having a tilt angle relative to the first horizontal plane HP1 in a range from 0.1 degree to 10 degrees. In one embodiment, the device structure comprises a capping dielectric layer 173 embedding the first passivation-level metal structures 167, the second passivation-level metal structures 167, and the ESD path metal structures 168, wherein a first areal metal density at a level of the first passivation-level metal structures 167, the second passivation-level metal structures 167 within a region including the upper protrusion portion 166P of the ESD path metal structure 168 is less than a second areal metal density at the level of the first passivation-level metal structures 167, the second passivation-level metal structures 167 within a region of the first passivation-level metal structures 167 is by a factor of at least 3.

In one embodiment, the upper protrusion portion 166P comprises a planar top surface segment and at least one vertical surface segment having a bottom periphery within the first horizontal plane HP1.

In one embodiment, the upper protrusion portion 166P of the ESD path metal structure 168 has a same material composition as a portion of said one of the first passivation-level metal structures 167 that underlie the first horizontal plane HP1. In one embodiment, the upper protrusion portion 166P of the ESD path metal structure 168 comprises copper at an atomic percentage of at least 98%.

In one embodiment, a second horizontal plane HP2 including a planar top surface of the capping dielectric layer 173 is located above the first horizontal plane HP1; and each of the first metallic bonding pad 178A and the second metallic bonding pad 178B comprises a respective planar portion overlying the second horizontal plane HP2 and a respective via portion underlying the second horizontal plane HP2 and vertically extending through the capping dielectric layer 173. In one embodiment, a via portion of the first metallic bonding pad 178A has a greater vertical extent than a via portion of the second metallic bonding pad 178B.

In one embodiment, the first semiconductor die 700 comprises: first semiconductor devices 120 located on a first semiconductor substrate 110; first metal interconnect structures 140 embedded in first dielectric material layers 150 that are located between the first semiconductor substrate 110 and the capping dielectric layer 173, wherein the ESD path metal structure 168 is electrically connected to the ESD protection circuit 122 through a subset of the first metal interconnect structures 140. In one embodiment, the first semiconductor devices 120 comprises first field effect transistors; and the ESD path metal structure 168 is electrically connected to a node of one of the first field effect transistors through a subset of the first metal interconnect structures 140.

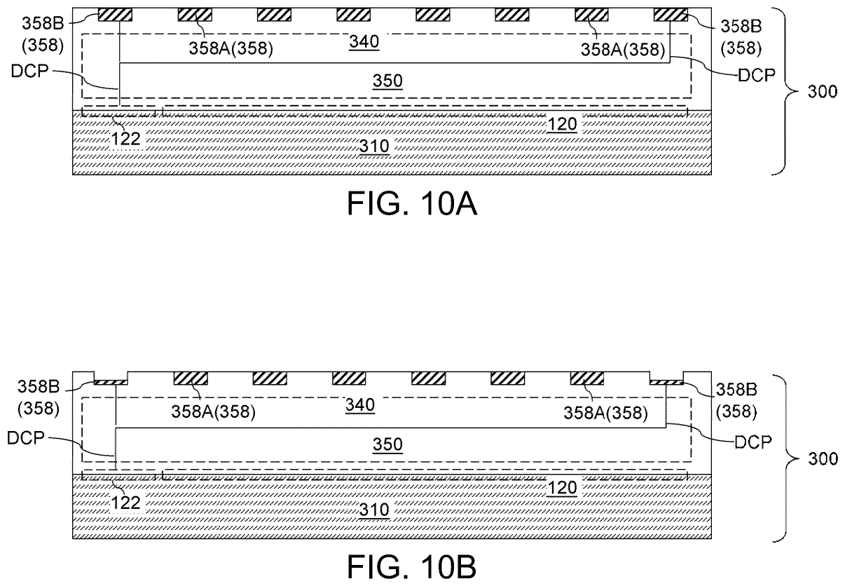

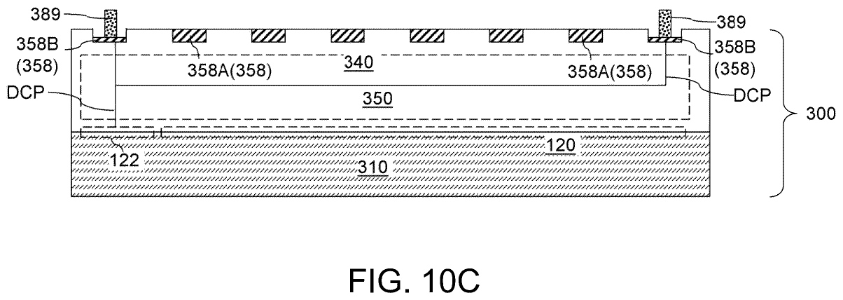

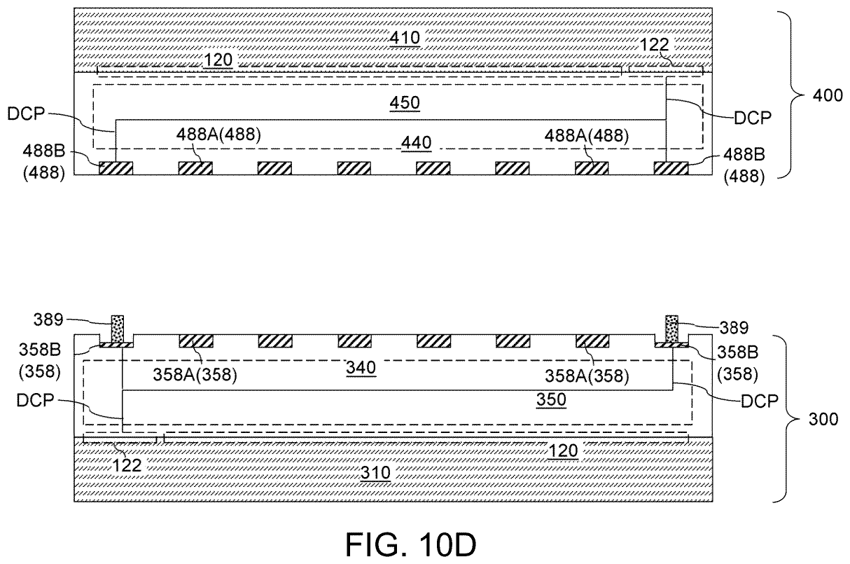

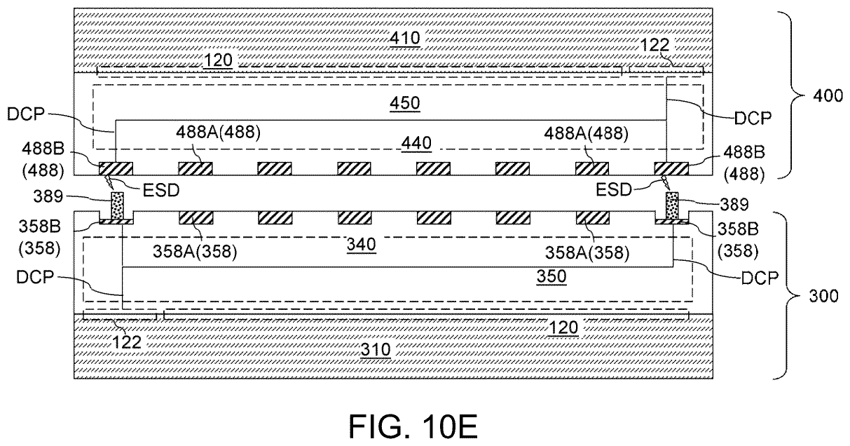

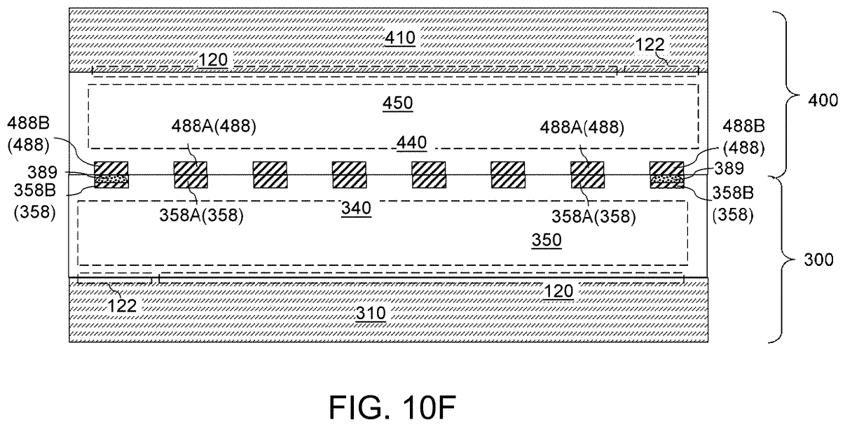

FIGS. 10A-10F are sequential vertical cross-sectional views of a third embodiment structure during formation of a bonded assembly of two semiconductor dies 700 according to a third embodiment of the present disclosure.

Referring to FIG. 10A, a first semiconductor die 300 is provided, which may be derived from the first semiconductor die 700 illustrated in FIG. 1 by omitting formation of the metal pad structures 158 and by forming first metallic bonding pads 358 that are configured for metal-to-metal bonding. Metal-to-metal bonding refers to direct bonding between two metal surfaces with use of any intermediate solder material. In this embodiment, a subset of grain boundaries between a first metal in a first metallic bonding pad and a second metal in a second metallic bonding pad cross over an initial boundary between the first metallic bonding pad and the second metallic bonding pad such that the second metal is bonded to the first metal through grain boundaries. A typical example of metal-to-metal bonding is copper-to-copper bonding.

In one embodiment, each of the first metallic bonding pads 358 may have a lateral length in a range from 2 microns to 10 microns, and a lateral width in a range from 2 microns to 10 microns. In some embodiments, the first metallic bonding pads 358 may be arranged as a two-dimensional periodic array having a first pitch along a first horizontal direction and a second pitch along a second horizontal direction. The first pitch and the second pitch may be in a range from 25 microns to 120 microns, although lesser and greater pitches may also be used.

In one embodiment, the first semiconductor die 300 comprises a first semiconductor substrate 310, first semiconductor devices 120 located on the first semiconductor substrate 310, and first dielectric material layers 350 embedding first metal interconnect structures 340 and the first metallic bonding pads 358. The first semiconductor die 300 may comprise a first electrostatic discharge (ESD) protection circuit 122 that is located on the first semiconductor substrate 310. In one embodiment, the first metallic bonding pads 358 comprise first-type first metallic bonding pads 358A that are not electrically connected to first ESD protection circuit 122, and second-type first metallic bonding pads 358B that are electrically connected to the first ESD protection circuit 122. In this embodiment, the first-type first metallic bonding pads 358A are electrically isolated from the first ESD protection circuit 122. Thus, a discharge current path DCP is provided between each second-type first metallic bonding pad 358B and the first ESD protection circuit 122.

At the processing step illustrated in FIG. 10A, the first-type first metallic bonding pads 358A and second-type first metallic bonding pads 358B may have a same first uniform thickness, which is herein referred to as a first thickness. In one embodiment, the first thickness may be in a range from 1 micron to 10 microns, such as from 2 microns to 6 microns. The top surfaces of the first-type first metallic bonding pads 358A and second-type first metallic bonding pads 358B may be located within the horizontal plane including a physically exposed top surface of the first dielectric material layers 350.

Referring to FIG. 10B, a photoresist layer (not shown) may be applied over the first dielectric material layers 350, and may be lithographically patterned to cover the first-type first metallic bonding pads 358A without covering the second-type first metallic bonding pads 358B. A selective etch process that etches the metallic material(s) of the second-type first metallic bonding pads 358B selective to the first dielectric material layers 350 may be performed to vertically recess the physically exposed horizontal surfaces of the second-type first metallic bonding pads 358B. For example, if the metallic bonding pads 358 comprise copper, the selective etch process may comprise a wet etch process that etches copper selective to the dielectric materials of the dielectric material layers 350.

Generally, top surfaces of the second-type first metallic bonding pads 358B are vertically recessed relative to top surfaces of the first-type first metallic bonding pads 358A. The vertical recess distance by which top surfaces of the second-type first metallic bonding pads 358B are recessed may be in a range from 20% to 80% of the first thickness, i.e., the thickness of the first-type first metallic bonding pads 358A. The photoresist layer may be subsequently removed, for example, by ashing. Each the first-type first metallic bonding pads 358A has a first thickness, and each of the second-type first metallic bonding pads 358B has a second thickness that is less than the first thickness. The second thickness may be in a range from 20% to 80% of the first thickness.

Referring to FIG. 10C, a patterned mask layer (not shown) may be formed over the metallic bonding pads 358 and the first dielectric material layers 350. The patterned mask layer comprises openings over the second-type first metallic bonding pads 358B. Each opening in the patterned mask layer may have a smaller area than the area of respective underlying second-type first metallic bonding pad 358B.

A metallic material having a lower Young's modulus than the material of the second-type first metallic bonding pads 358 may be deposited in the openings in the patterned mask layer. The metallic material may comprise a solder material, or a non-solder metallic material such as lead, aluminum, tin, zinc, bismuth, cadmium, etc. Each deposited portion of the metallic material may be formed as a pillar structure having a lesser area than the area of a respective underlying second-type first metallic bonding pad 358B, and is herein referred to as an intermediate metallic material portion 389.

According to an aspect of the present disclosure, the intermediate metallic material portions 389 protrude above the horizontal plane including the physically exposed horizontal surface of the first dielectric material layers 350. Each intermediate metallic material portion 389 comprises a lower portion that is formed within a respective recess cavity formed at the processing steps of FIG. 10B. Each intermediate metallic material portion 389 may have a volume that is less than the volume of the respective recess cavity. Top surfaces of the intermediate metallic material portions 389 protrude above a horizontal plane including the top surfaces of the first-type first metallic bonding pads 358A upon attaching intermediate metallic material portions 389 to the second-type first metallic bonding pads 358B.

In one embodiment, the intermediate metallic material portions 389 are formed by forming a mask layer over the first-type first metallic bonding pads 358A and the second-type first metallic bonding pads 358B, by forming openings through the mask layer in areas that overlie the second-type first metallic bonding pads 358B, and by depositing a metal in the openings. The intermediate metallic material portions 389 may be attached to the second-type first metallic bonding pads 358B without covering surfaces of the first-type first metallic bonding pads 358A with any metallic material.

Referring to FIG. 10D, a second semiconductor die 400 is provided, which may be derived from the second semiconductor die 700 illustrated in FIG. 1 by omitting formation of the metal pad structures 158 and by forming second metallic bonding pads 488 that are configured for metal-to-metal bonding. The pattern of the second metallic bonding pads 488 may be a mirror image pattern of the first metallic bonding pads 358.

In one embodiment, the second semiconductor die 400 comprises a second semiconductor substrate 410, second semiconductor devices 120 located on the second semiconductor substrate 410, and second dielectric material layers 450 embedding second metal interconnect structures 440 and the second metallic bonding pads 488. The second semiconductor die 400 may comprise a second electrostatic discharge (ESD) protection circuit 122 that is located on the second semiconductor substrate 410. In one embodiment, the second metallic bonding pads 488 comprise first-type second metallic bonding pads 488A that are not electrically connected to second ESD protection circuit 122, and second-type second metallic bonding pads 488B that are electrically connected to the second ESD protection circuit 122. In this embodiment, the first-type second metallic bonding pads 488A are electrically isolated from the second ESD protection circuit 122. Thus, a discharge current path DCP is provided between each second-type second metallic bonding pad 488B and the second ESD protection circuit 122.

The second metallic bonding pads 488 may have a same second uniform thickness, which is herein referred to as a third thickness. In one embodiment, the third thickness may be in a range from 1 micron to 10 microns, such as from 2 microns to 6 microns. The physically exposed planar horizontal surfaces of the second metallic bonding pads 488 may be located within the horizontal plane including a physically exposed top surface of the second dielectric material layers 450. The second metallic bonding pads 488 comprises a second metallic material that may be bonded to the first metallic material of the first metallic bonding pads 358. In one embodiment, the second metallic bonding pads 488 and the first metallic bonding pads 358 may comprise copper. Generally, the Young's modulus of a material of the intermediate metallic material portions 389 is less than the Young's modulus of a material of the second metallic bonding pads 488.

The second semiconductor die 400 may be positioned such that the second metallic bonding pads 488 face the first metallic bonding pads 358. The second-type second metallic bonding pads 488B may face the intermediate metallic material portions 389 upon alignment of the second semiconductor die 400 to the first semiconductor die 300.

Referring to FIG. 10E, the vertical spacing between the second semiconductor die 400 and the first semiconductor die 300 may be gradually reduced during an initial step of a bonding process. The distance between each intermediate metallic material portion 389 and a respective overlying second-type second metallic bonding pad 488B may decrease until the intermediate metallic material portions 389 contact the second-type second metallic bonding pads 488B. An electrostatic discharge (ESD) event may occur immediately before the intermediate metallic material portions 389 make contact with the second-type second metallic bonding pads 488B. Thus, the intermediate metallic material portions 389 function as leading point of discharge (LPoD) structures in the third embodiment structure.

In one embodiment, one, a plurality, and/or each of the intermediate metallic material portions 389 may be electrically connected to the first ESD protection circuit 122 in the first semiconductor die 300 through a respective one of the second-type first metallic bonding pads 358B and through a subset of the first metal interconnect structures 340. One, a plurality, and/or each of the second-type second metallic bonding pads 488B may become electrically connected to the first ESD protection circuit 122 through one, a plurality, and/or each, of the intermediate metallic material portions 389 upon contact of the one, the plurality, and/or each, of the second-type second metallic bonding pads 488B with the one, the plurality, and/or each, of the intermediate metallic material portions 389.

In one embodiment, the second semiconductor die 400 comprises a second electrostatic discharge (ESD) protection circuit 122 located on the second semiconductor substrate 410. One, a plurality, and/or each, of the second-type second metallic bonding pads 488B may be electrically connected to the second ESD protection circuit 122 through a subset of the second metal interconnect structures 440. Instantaneous electrostatic discharge current may flow between the first ESD protection circuit 122 located on the first semiconductor substrate 310 and the second ESD protection circuit 122 located on the second semiconductor substrate 420 during the ESD event that occurs at a moment of electrical contact between the intermediate metallic material portions 389 and the second-type second metallic bonding pads 488B.

Referring to FIG. 10F, the distance between the horizontal plane including the physically exposed planar horizontal surface of the first dielectric material layers 350 and the horizontal plane including the physically exposed planar horizontal surface of the second dielectric material layers 450 may be gradually decreases to zero. As discussed above, the Young's modulus of the intermediate metallic material portion 389 is less than the Young's moduli of the metallic materials of the second metallic bonding pads 488 and the first metallic bonding pads 358. Thus, the intermediate metallic material portion 389 is deformed during this processing step, and is contained entirely within the volumes of the recess cavitied formed at the processing steps of FIG. 10B.

An anneal process may be performed at an elevated temperature while the first semiconductor die 300 and the second semiconductor die 400 are pressed against each other. The first-type second metallic bonding pads 488A may be bonded to the first-type first metallic bonding pads 358A by metal-to-metal bonding (such as copper-to-copper bonding) while the intermediate metallic material portions 389 are interposed between mating pairs of the second-type second metallic bonding pads 488B and the second-type first metallic bonding pads 358B. Generally, the first-type second metallic bonding pads 488A are bonded to the first-type first metallic bonding pads 358A by metal-to-metal bonding.

Further, a surface of the second dielectric material layers 450 may be bonded to a surface of the first dielectric material layers 350 by dielectric-to-dielectric bonding such that the second semiconductor die 400 is bonded to the first semiconductor die 300 by hybrid bonding. The elevated temperature may be in a range from 200 degrees Celsius to 400 degrees Celsius, although lower and higher temperatures may also be used. The duration of the anneal process at the elevated temperature may be in a range from 30 minutes to 240 minutes, although lesser and greater durations may also be used.

In one embodiment, the intermediate metallic material portions 389 may be deformed such that each of the intermediate metallic material portions 389 has a metallic material portion thickness that equals a difference between the first thickness and the second thickness after the first-type second metallic bonding pads 488A are bonded to the first-type first metallic bonding pads 358A. In one embodiment, each of the intermediate metallic material portions 389 may have a respective horizontal surface segment that is located within a horizontal plane including bonding surfaces of the first-type first metallic bonding pads 358A after the first-type second metallic bonding pads 488A are bonded to the first-type first metallic bonding pads 358A.

In one embodiment, each of the first-type second metallic bonding pads 488A and the second-type second metallic bonding pads 488B has a respective horizontal surface that is located within a horizontal plane including the bonding interface between the first dielectric material layers 350 and the second dielectric material layers 450. In one embodiment, cavity that is free of any solid phase material and is free of any liquid phase material laterally may be formed around one, a plurality, and/or each, of the intermediate metallic material portions 389 after the first-type second metallic bonding pads 488A are bonded to the first-type first metallic bonding pads 358A. The cavity is laterally surrounded by the first dielectric material layers 350.

The third embodiment structure illustrated in FIG. 10E comprises a device structure, which comprises: a first semiconductor die 300 comprising a first semiconductor substrate 310, first semiconductor devices 120 located on the first semiconductor substrate 310, and first dielectric material layers 350 embedding first metal interconnect structures 340 and first metallic bonding pads 358, wherein the first metallic bonding pads 358 comprise first-type first metallic bonding pads 358A and second-type first metallic bonding pads 358B; a second semiconductor die 400 comprising a second semiconductor substrate 410, second semiconductor devices 420 located on the second semiconductor substrate 410, and second dielectric material layers 450 embedding second metal interconnect structures 440 and second metallic bonding pads 488, wherein the second metallic bonding pads 488 comprise first-type second metallic bonding pads 488A that are directly bonded to the first-type first metallic bonding pads 358A and second-type second metallic bonding pads 488B that do not contact any of the first metallic bonding pads 358; and intermediate metallic material portions 389, wherein each of the intermediate metallic material portions 389 is in contact with a respective one of the second-type first metallic bonding pads 358B and with a respective one of the second-type second metallic bonding pads 488B.

In one embodiment, each the first-type first metallic bonding pads 358A has a first thickness; and each of the second-type first metallic bonding pads 358B has a second thickness that is less than the first thickness. In one embodiment, each of the second metallic bonding pads 488 has a uniform thickness throughout. In one embodiment, each of the intermediate metallic material portions 389 has a metallic material portion thickness that equals a difference between the first thickness and the second thickness.

In one embodiment, each of the intermediate metallic material portions 389 has a respective horizontal surface segment that is located within a horizontal plane including bonding surfaces of the first-type first metallic bonding pads 358A. In one embodiment, each of the first-type second metallic bonding pads 488A and the second-type second metallic bonding pads 488B has a respective horizontal surface that is located within the horizontal plane.

In one embodiment, the second dielectric material layers 450 are bonded to the first dielectric material layers 350 by dielectric-to-dielectric bonding. In one embodiment, the first-type second metallic bonding pads 488A are bonded to the first-type first metallic bonding pads 358A by metal-to-metal bonding in which a subset of grain boundaries between a first metal in the first-type first metallic bonding pads 358A and a second metal in the first-type second metallic bonding pads 488A cross over a horizontal plane including a horizontal interface between the first dielectric material layers 350 and the second dielectric material layers 450.

In one embodiment, a Young's modules of a material of the intermediate metallic material portions 389 is less than a first Young's modulus of a first metal in the first metallic bonding pads 358, and is less than a second Young's modulus of a second metal in the second metallic bonding pads 488.

In one embodiment, a cavity that is free of any solid phase material and is free of any liquid phase material laterally surrounds one of the intermediate metallic material portions 389, and is laterally surrounded by the first dielectric material layers 350.

In one embodiment, the first semiconductor die 300 comprises a first electrostatic discharge (ESD) protection circuit 122 located on the first semiconductor substrate 310, wherein one of the second-type first metallic bonding pads 358B is electrically connected to the first ESD protection circuit 122 through a subset of the first metal interconnect structures 340. In one embodiment, the second semiconductor die 400 comprises a second electrostatic discharge (ESD) protection circuit 122 located on the second semiconductor substrate 410, wherein said one of the second-type first metallic bonding pads 358B is electrically connected to the second ESD protection circuit 122 through a subset of the second metal interconnect structures 440. In one embodiment, the first-type first metallic bonding pads 358A are electrically isolated from the first ESD protection circuit 122.

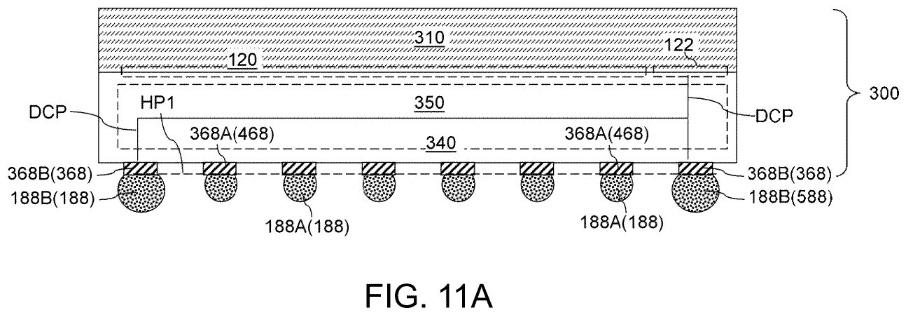

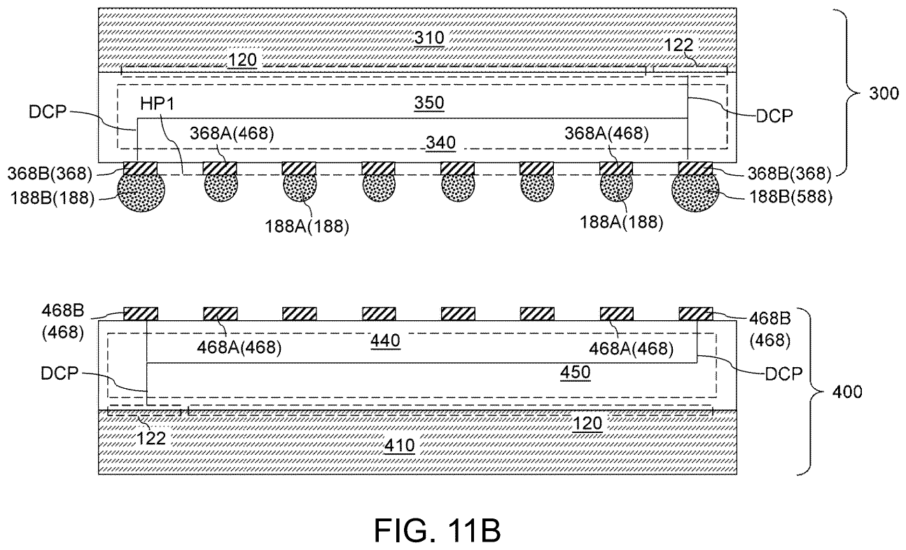

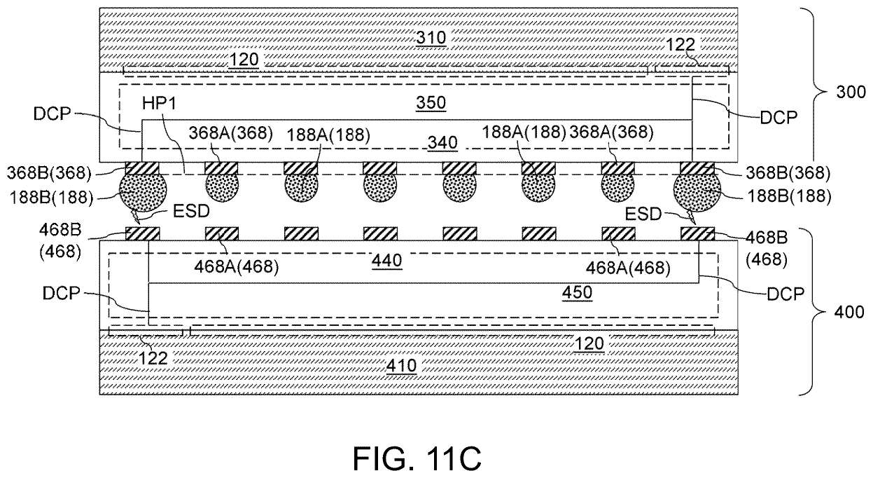

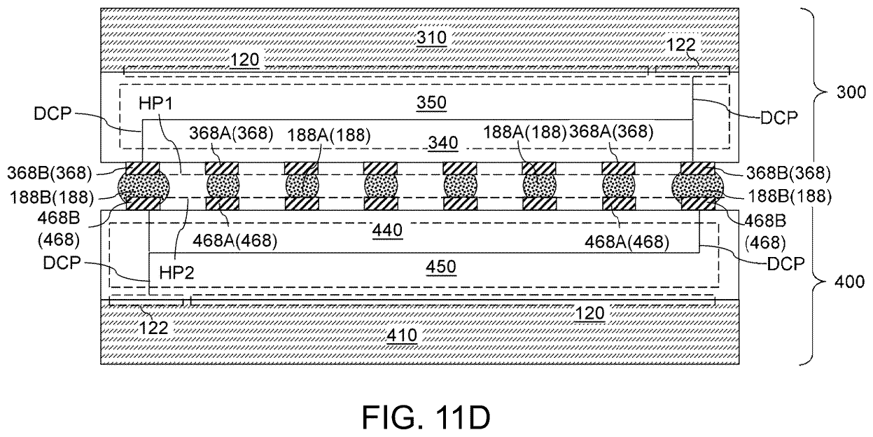

FIGS. 11A-11D are sequential vertical cross-sectional views of a fourth embodiment structure during formation of a bonded assembly of two semiconductor dies 700 according to a fourth embodiment of the present disclosure.

Referring to FIG. 11A, a first semiconductor die 300 is provided, which may be derived from the first semiconductor die 300 illustrated in FIG. 10A by forming first metallic bonding pads 368 in lieu of the first metallic bonding pads 358. The first metallic bonding pads 358 used in the fourth embodiment structure comprise solder bonding pads, i.e., bonding pads configured to be bonded to other bonding pads through solder material portions such as solder balls. In this embodiment, the first metallic bonding pads 368 in the first semiconductor die 300 of the fourth embodiment structure may comprise C4 bonding pads or microbump structures (which are also referred to as C2 bump structures).

The first semiconductor die 300 comprises a first semiconductor substrate 310, first semiconductor devices 120 located on the first semiconductor substrate 310, first dielectric material layers 350 embedding first metal interconnect structures 340, and first metallic bonding pads 368. The first metallic bonding pads 368 comprise first-type first metallic bonding pads 368A and second-type first metallic bonding pads 368B. In one embodiment, the first semiconductor die 300 comprises a first electrostatic discharge (ESD) protection circuit 122 located on the first semiconductor substrate 310. In one embodiment, one, a plurality, and/or each, of the second-type first metallic bonding pads 368B may be electrically connected to the first ESD protection circuit 122 in the first semiconductor die 300 through a subset of the first metal interconnect structures 340. In one embodiment, the first semiconductor devices 120 comprises a first field effect transistor having an electrical node that is electrically connected to said one of the second-type first metallic bonding pads 368B. In one embodiment, the first-type first metallic bonding pads 368A are electrically isolated from the first ESD protection circuit 122.

First solder material portions 188A may be attached to a respective one of the first-type first metallic bonding pads 368A. Each of the first solder material portions 188A may have a first height. Further, second solder material portions 188B may be attached to a respective one of the second-type first metallic bonding pads 368B. Each of the second solder material portions 188B may have a second height that is greater than the first height. In an illustrative example, the first height may be in a range from 20 microns to 60 microns, such as from 30 microns to 50 microns. The second height may be in a range from 25 microns to 100 microns, such as from 40 microns to 70 microns. The difference between the second height and the first height may be in a range from 5 microns to 40 microns, such as from 10 microns to 30 microns.

In one embodiment, each of the first solder material portions 188A may have a respective volume that is in a range from 80% to 120%, such as from 90% to 110%, and/or from 98% to 102%, of a first reference volume. In one embodiment, each of the second solder material portions 188B may have a respective volume that is in a range from 80% to 120%, such as from 90% to 110%, and/or from 98% to 102%, of a second reference volume. According wherein a ratio of the second reference volume to the first reference volume is in a range from 1.5 to 4, such as from 2 to 3. Interfaces between the first metallic bonding pads 368, the first solder material portions 188A, and the second solder material portions 188B may be formed within a first horizontal plane HP1 upon attachment of the first solder material portions 188A and the second solder material portions 188B to the first metallic bonding pads 368.

Referring to FIG. 11B, an interconnect-containing structure may be provided, which may comprise a second semiconductor die 400. The second semiconductor die 400 of the fourth embodiment structure may be derived from the second semiconductor die 400 of the third embodiment structure illustrated in FIG. 10D by forming second metallic bonding pads 468 in lieu of the second metallic bonding pads 488. The second metallic bonding pads 468 used in the fourth embodiment structure comprise solder bonding pads, i.e., bonding pads configured to be bonded to other bonding pads through solder material portions such as solder balls. In this embodiment, the second metallic bonding pads 468 in the second semiconductor die 400 of the fourth embodiment structure may comprise C4 bonding pads or microbump structures (which are also referred to as C2 bump structures).

The pattern of the second metallic bonding pads 468 may be a mirror image pattern of the pattern of the first metallic bonding pads 368. The second metallic bonding pads 468 may comprise first-type second metallic bonding pads 468A and second-type second metallic bonding pads 468B.

In one embodiment, the interconnect-containing structure comprises a second semiconductor die 400 which comprises: a second semiconductor substrate 410; second semiconductor devices 420 located on the second semiconductor substrate 410; and second dielectric material layers 450 embedding the second metal interconnect structures 440. In one embodiment, second semiconductor die 400 comprises an electrostatic discharge (ESD) protection circuit 122 located on the second semiconductor substrate 410. One, a plurality, and/or each, of the second-type first metallic bonding pads 368B may be electrically connected to the second ESD protection circuit 122 through a subset of the second metal interconnect structures 440. The first-type second metallic bonding pads 468A may be electrically isolated from the ESD protection circuit 122 in the second semiconductor die 400. The second semiconductor die 400 may be positioned such that the second metallic bonding pads 468 face the first metallic bonding pads 368.

Referring to FIG. 11C, the vertical spacing between the second semiconductor die 400 and the first semiconductor die 300 may be gradually reduced during an initial step of a bonding process. The distance between each second solder material portion 188B and a respective underlying second-type second metallic bonding pad 468B may decrease until the second solder material portions 188B contact the second-type second metallic bonding pads 468B. An electrostatic discharge (ESD) event may occur immediately before the second solder material portions 188B make contact with the second-type second metallic bonding pads 468B. Thus, the second solder material portions 188B function as leading point of discharge (LPoD) structures in the fourth embodiment structure.

In one embodiment, one, a plurality, and/or each of the second solder material portions 188B may be electrically connected to the first ESD protection circuit 122 in the first semiconductor die 300 through a respective one of the second-type first metallic bonding pads 368B and through a subset of the first metal interconnect structures 340. One, a plurality, and/or each of the second-type second metallic bonding pads 468B may become electrically connected to the first ESD protection circuit 122 in the first semiconductor die 300 through one, a plurality, and/or each, of the second solder material portions 188B upon contact of the one, the plurality, and/or each, of the second-type second metallic bonding pads 468B with the one, the plurality, and/or each, of the second solder material portions 188B.

In one embodiment, the second semiconductor die 400 comprises a second electrostatic discharge (ESD) protection circuit 122 located on the second semiconductor substrate 410. One, a plurality, and/or each, of the second-type second metallic bonding pads 468B may be electrically connected to the second ESD protection circuit 122 through a subset of the second metal interconnect structures 440. Instantaneous electrostatic discharge current may flow between the first ESD protection circuit 122 located on the first semiconductor substrate 310 and the second ESD protection circuit 122 located on the second semiconductor substrate 420 during the ESD event that occurs at a moment of electrical contact between the second solder material portions 188B and the second-type second metallic bonding pads 468B.

Generally, the second solder material portions 188B make contact with the second-type second metallic bonding pads 488B before the first solder material portions 188A make contact with the first-type second metallic bonding pads 488A during the bonding process. In one embodiment, the second solder material portions 188B make contact with the second-type second metallic bonding pads 488B while the second solder material portions 188B are at, or above, a reflow temperature of a solder material of the second solder material portions 188B such that the second solder material portions 188B do not crack upon contact with the second-type second metallic bonding pads 468B, but are reflowed and deformed.

Referring to FIG. 11D, the vertical distance between the first semiconductor die 300 and the second semiconductor die 400 may be gradually decreases until the first-type solder material portions 188A contact the first-type first metallic bonding pads 368A, and are bonded to the first-type first metallic bonding pads 368A. The temperature of the solder material portions 188 may be controlled to induce solder bonding between each mating pair of a first metallic bonding pad 368 and a second metallic bonding pad 468. Generally, the first-type second metallic bonding pads 468A are bonded to the first-type first metallic bonding pads 368A by solder bonding.

Generally, a bonding process may be performed in which the first solder material portions 188A are bonded to a respective one of the first-type second metallic bonding pads 488A and the second solder material portions 188B are bonded to a respective one of the second-type second metallic bonding pads 488B. In one embodiment, all horizontal interfaces between the first solder material portions 188A and the first-type second metallic bonding pads 488A are formed within a second horizontal plane HP2 during the bonding process; and all horizontal interfaces between the second solder material portions 188B and the second-type second metallic bonding pads 488B are formed within the second horizontal plane HP2 during the bonding process.

In one embodiment, the first solder material portions 188A are bonded to the first-type second metallic bonding pads 488A such that the first solder material portions 188A do not contact sidewalls of the first-type first metallic bonding pads 368A and do not contact sidewalls of the first-type second metallic bonding pads 488A. In one embodiment, the second solder material portions 188B are bonded to the second-type second metallic bonding pads 488B such that the second solder material portions 188B contact sidewalls of the second-type first metallic bonding pads 368B and contact sidewalls of the second-type second metallic bonding pads 488B.

The fourth embodiment structure illustrated in FIG. 11D comprises a device structure, which comprises: a first semiconductor die 300 comprising a first semiconductor substrate 310, first semiconductor devices 120 located on the first semiconductor substrate 310, and first dielectric material layers 350 embedding first metal interconnect structures 340 and first metallic bonding pads 368, wherein the first metallic bonding pads 368 comprise first-type first metallic bonding pads 368A and second-type first metallic bonding pads 368B; an interconnect-containing structure (such as a second semiconductor die 400) embedding second metal interconnect structures 440 and second metallic bonding pads 488, wherein the second metallic bonding pads 488 comprise first-type second metallic bonding pads 488A and second-type second metallic bonding pads 488B; first solder material portions 188A bonded to a respective one of the first-type first metallic bonding pads 368A and to a respective one of the first-type second metallic bonding pads 488A and having a volume in a range from 80% to 120% of a first reference volume; and second solder material portions 188B bonded to a respective one of the second-type first metallic bonding pads 368B and to a respective one of the second-type second metallic bonding pads 488B and having a volume in a range from 80% to 120% of a second reference volume, wherein a ratio of the second reference volume to the first reference volume is in a range from 1.5 to 4.

In one embodiment, a first vertical spacing between the respective one of the first-type first metallic bonding pads 368A and the respective one of the first-type second metallic bonding pads 488A is the same as a second vertical spacing between the respective one of the second-type first metallic bonding pads 368B and the respective one of the second-type second metallic bonding pads 488B.

In one embodiment, all horizontal interfaces between the first solder material portions 188A and the first-type first metallic bonding pads 368A are located within a first horizontal plane HP1; and all horizontal interfaces between the second solder material portions 188B and the second-type first metallic bonding pads 368B are located within the first horizontal plane HP1. In one embodiment, all horizontal interfaces between the first solder material portions 188A and the first-type second metallic bonding pads 488A are located within a second horizontal plane HP2; and all horizontal interfaces between the second solder material portions 188B and the second-type second metallic bonding pads 488B are located within the second horizontal plane HP2.

In one embodiment, each of the first-type first metallic bonding pads 368A and second-type first metallic bonding pads 368B has a same area. In one embodiment, the first semiconductor die 300 comprises a first electrostatic discharge (ESD) protection circuit 122 located on the first semiconductor substrate 310, wherein one of the second-type first metallic bonding pads 368B is electrically connected to the first ESD protection circuit 122 through a subset of the first metal interconnect structures 340. In one embodiment, the first semiconductor devices 120 comprises a first field effect transistor having an electrical node that is electrically connected to said one of the second-type first metallic bonding pads 368B. In one embodiment, the first-type first metallic bonding pads 368A are electrically isolated from the first ESD protection circuit 122.

In one embodiment, the first solder material portions 188A do not contact sidewalls of the first-type first metallic bonding pads 368A and do not contact sidewalls of the first-type second metallic bonding pads 488A; and the second solder material portions 188B contact sidewalls of the second-type first metallic bonding pads 368B and contact sidewalls of the second-type second metallic bonding pads 488B.

In one embodiment, the interconnect-containing structure comprises a second semiconductor die 400 that comprises: a second semiconductor substrate 410; second semiconductor devices 420 located on the second semiconductor substrate 410; and second dielectric material layers 450 embedding the second metal interconnect structures 440. In one embodiment, the second semiconductor die 400 comprises an electrostatic discharge (ESD) protection circuit 122 located on the second semiconductor substrate 410, wherein one of the second-type first metallic bonding pads 368B is electrically connected to the second ESD protection circuit 122 through a subset of the second metal interconnect structures 440.

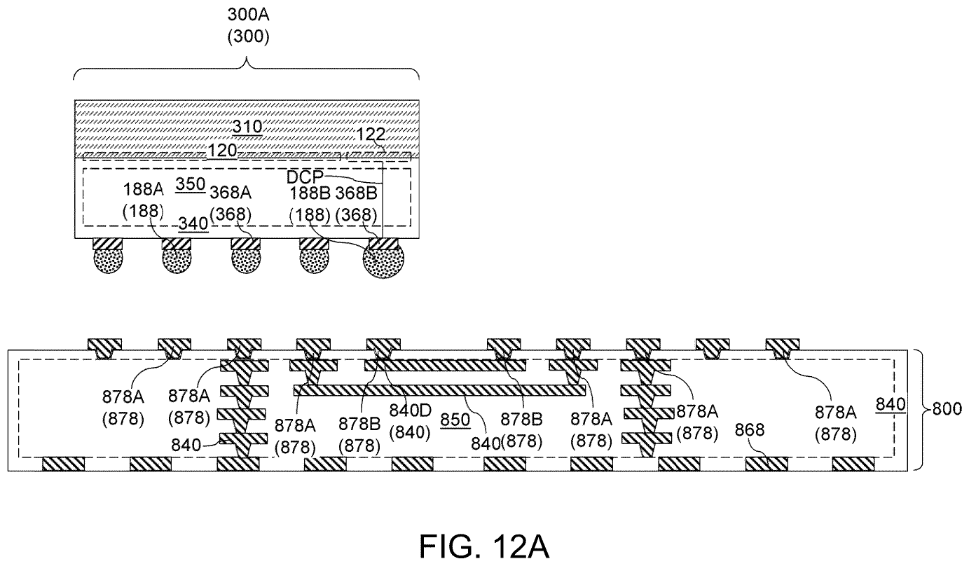

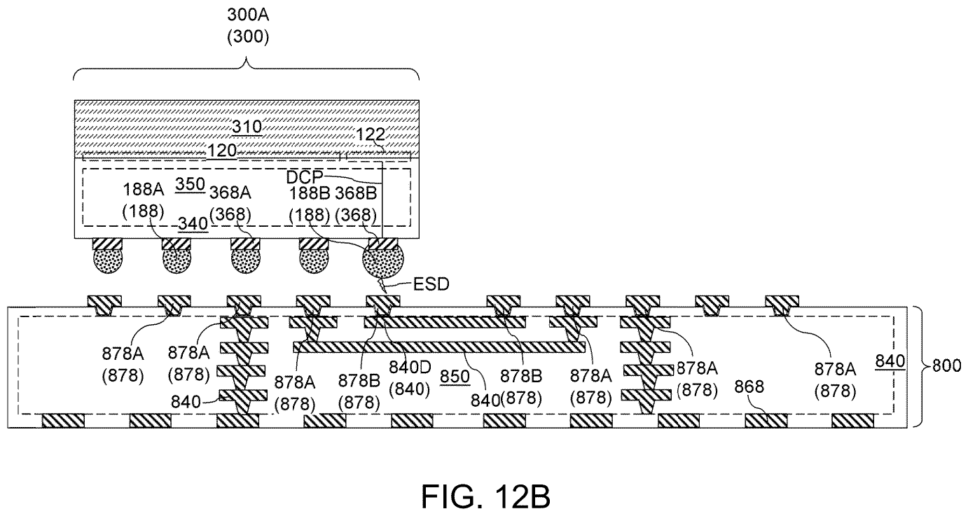

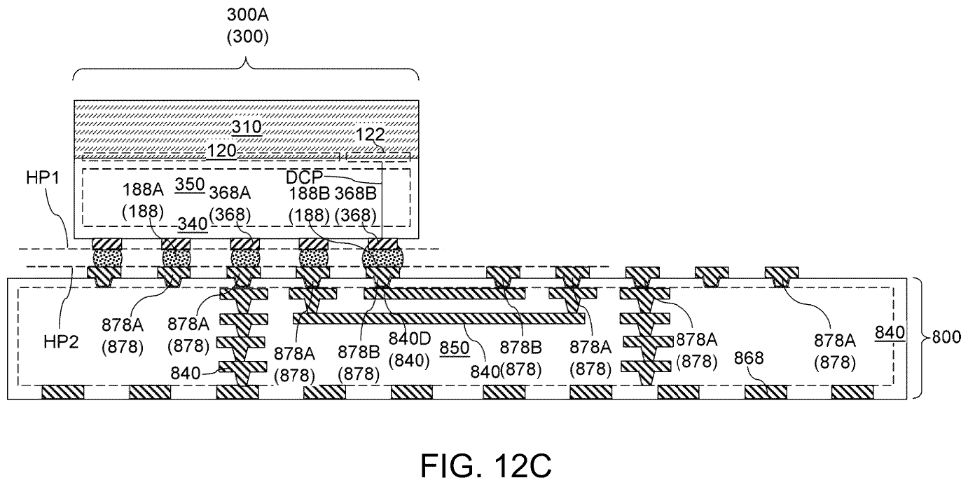

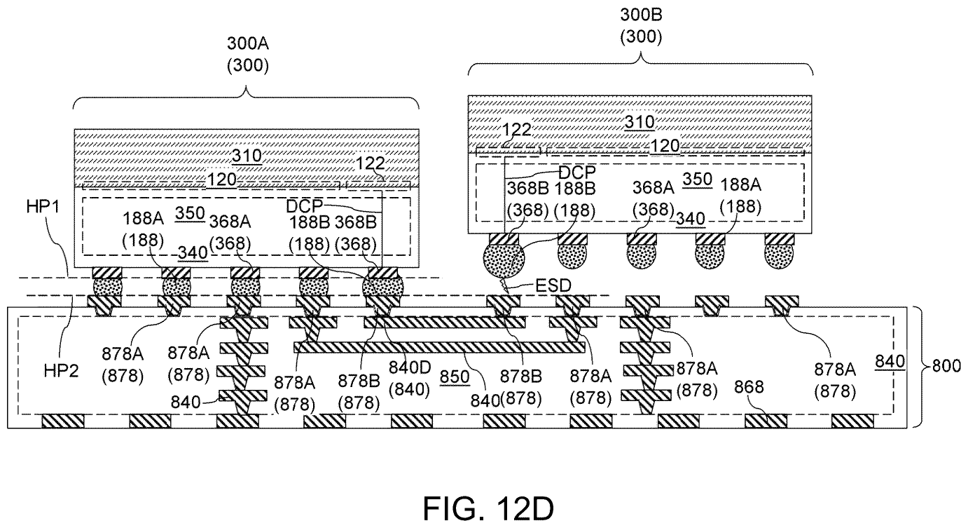

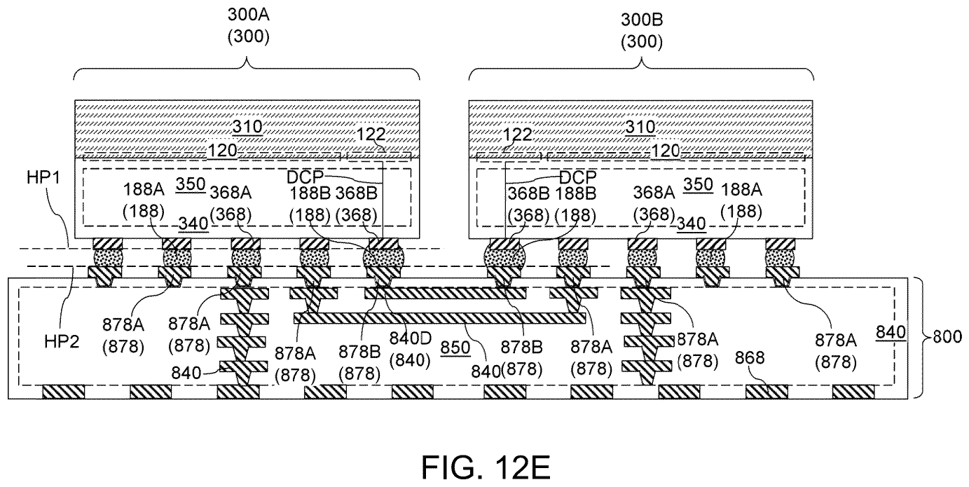

FIGS. 12A-12E are sequential vertical cross-sectional views of a fifth embodiment structure during formation of a bonded assembly of two semiconductor dies 300 according to a fifth embodiment of the present disclosure.

Referring to FIG. 12A, a first semiconductor die 300A and an interconnect-containing structure are provided. The first semiconductor die 300A may be the same as the first semiconductor die 300 described with reference to FIG. 11A.

The first semiconductor die 300A comprises a first semiconductor substrate 310, first semiconductor devices 120 located on the first semiconductor substrate 310, first dielectric material layers 350 embedding first metal interconnect structures 340, and first metallic bonding pads 368. The first metallic bonding pads 368 comprise first-type first metallic bonding pads 368A and second-type first metallic bonding pads 368B. In one embodiment, the first semiconductor die 300A comprises a first electrostatic discharge (ESD) protection circuit 122 located on the first semiconductor substrate 310. In one embodiment, one, a plurality, and/or each, of the second-type first metallic bonding pads 368B may be electrically connected to the first ESD protection circuit 122 in the first semiconductor die 300A through a subset of the first metal interconnect structures 340. In one embodiment, the first semiconductor devices 120 comprises a first field effect transistor having an electrical node that is electrically connected to said one of the second-type first metallic bonding pads 368B. In one embodiment, the first-type first metallic bonding pads 368A are electrically isolated from the first ESD protection circuit 122.

First solder material portions 188A may be attached to a respective one of the first-type first metallic bonding pads 368A. Each of the first solder material portions 188A may have a first height. Further, second solder material portions 188B may be attached to a respective one of the second-type first metallic bonding pads 368B. Each of the second solder material portions 188B may have a second height that is greater than the first height. Generally, the heights and the volumes of the first solder material portions 188A and the second solder material portions 188B may be the same as described with reference to the first semiconductor die 300 of the fourth embodiment structure. Generally, interfaces between the first metallic bonding pads 368, the first solder material portions 188A, and the second solder material portions 188B are formed within a first horizontal plane HP1 upon attachment of the first solder material portions 188A and the second solder material portions 188B to the first metallic bonding pads 368.

In one embodiment, the first semiconductor die 300A comprises a first electrostatic discharge (ESD) protection circuit 122 located on the first semiconductor substrate 310. One, a plurality, and/or each, of the second-type first metallic bonding pads 368B may be electrically connected to the first ESD protection circuit 122 through a subset of the first metal interconnect structures 340. In one embodiment, the first semiconductor devices 120 comprises a first field effect transistor having an electrical node that is electrically connected to one of the second-type first metallic bonding pads 368B. In one embodiment, the first-type first metallic bonding pads 368A may be electrically isolated from the first ESD protection circuit 122.

The interconnect-containing structure may be an interposer 800, which may comprise an organic interposer, a ceramic interposer, or any other type of interposer known in the art. In one embodiment, the interposer 800 comprises redistribution wiring interconnects 840 embedded in redistribution dielectric layers 850 comprising polymer materials. In one embodiment, the interposer 800 comprises interposer metallic bonding pads 878. The interposer metallic bonding pads 878 comprise first-type interposer metallic bonding pads 878A and second-type interposer metallic bonding pads 878B. Generally, the interconnect-containing structure (such as an interposer 800) embedding second metal interconnect structures (such as redistribution wiring interconnects 840) and comprising second metallic bonding pads (such as the interposer bonding pads 878) is provided. The second metallic bonding pads 878 comprise first-type second metallic bonding pads (such as first-type interposer bonding pads 878A) and second-type second metallic bonding pads (such as second-type interposer bonding pads 878B).

In one embodiment, the interposer 800 comprises substrate-side metallic bonding pads 868 that are located on an opposite side of the interposer metallic bonding pads 878. The interposer metallic bonding pads 878 may be configured to bond with at least two semiconductor dies including the first semiconductor die 300A. In this embodiment, a first subset of the interposer metallic bonding pads 878 may have a mirror image pattern of the pattern of the first metallic bonding pads 368 of the first semiconductor die 300A. The first semiconductor die 300A may be aligned to the first subset of the interposer metallic bonding pads 878 of the interposer 800.

Referring to FIG. 12B, a first bonding process may be performed. The first solder material portions 188A are bonded to a respective one of the first-type second metallic bonding pads (such as the first-type interposer bonding pads 878A), and the second solder material portions 188B are bonded to a respective one of the second-type second metallic bonding pads (such as the second-type interposer bonding pads 878B). Generally, the second solder material portions 188B make contact with the second-type interposer metallic bonding pads (such as the second-type interposer bonding pads 878B) before the first solder material portions 188A make contact with the first-type interposer metallic bonding pads (such as the first-type interposer bonding pads 878A) during the bonding process. The second solder material portions 188B make contact with the second-type interposer metallic bonding pads (such as the second-type interposer bonding pads 878B) while the second solder material portions 188B are at, or above, a reflow temperature of a solder material of the second solder material portions 188B.

The vertical spacing between the first semiconductor die 300A and the interposer 800 may be gradually reduced during an initial step of the first bonding process. The distance between each second solder material portion 188B and a respective underlying second-type interposer bonding pad 878B may decrease until the second solder material portions 188B contact the second-type interposer bonding pads 878B. An electrostatic discharge (ESD) event may occur immediately before the second solder material portions 188B make contact with the second-type interposer bonding pads 878B. Thus, the second solder material portions 188B function as leading point of discharge (LPoD) structures in the fifth embodiment structure.

Referring to FIG. 12C, the vertical distance between the first semiconductor die 300A and the interposer 800 may be further reduced while the solder material portions 188 are maintained at a reflow temperature. Each of the first-type first metallic bonding pads 368A may be bonded to a respective first-type interposer bonding pad 878A through a respective first solder material portion 188A, and each of the second-type first metallic bonding pads 368B may be bonded to a respective second-type interposer bonding pad 878B through a respective second solder material portion 188B.

In one embodiment, all horizontal interfaces between the first solder material portions 188A and the first-type interposer metallic bonding pads 878A are formed within a second horizontal plane HP2 during the bonding process; and all horizontal interfaces between the second solder material portions 188B and the second-type interposer metallic bonding pads 878B are formed within the second horizontal plane HP2 during the bonding process. In one embodiment, the difference between the volume of each first solder material portion 188A and the volume of each second solder material portion 188B may result in different bonding configurations for the first solder material portions 188A and the second solder material portions 188B. In one embodiment, the first solder material portions 188A do not contact sidewalls of the first-type first metallic bonding pads 368A and do not contact sidewalls of the first-type interposer metallic bonding pads 878A after performing the bonding process; and the second solder material portions 188B contact sidewalls of the second-type first metallic bonding pads 368B and contact sidewalls of the second-type interposer metallic bonding pads 878B after performing the bonding process.

Referring to FIG. 12D, a second semiconductor die 300B may be provided, which comprises a second semiconductor substrate 310, second semiconductor devices 320 located on the second semiconductor substrate 310, second dielectric material layers 350 (which may be referred to as additional dielectric material layers in the claims) embedding second metal interconnect structures (which may be referred to as additional metal interconnect structures in the claims), and second metallic bonding pads 368 (which may also be referred to as additional metallic bonding pads or as third metallic bonding pads in the claims).

In one embodiment, the second semiconductor die 300B comprises an electrostatic discharge (ESD) protection circuit 122 located on the second semiconductor substrate 310. In one embodiment, one, a plurality, and/or each, of the second-type second metallic bonding pads 878B is electrically connected to the ESD protection circuit 122 through a subset of the second metal interconnect structures 340.

The second metallic bonding pads 368 of the second semiconductor die 300B comprise first-type second metallic bonding pads 368A and second-type second metallic bonding pads 368B. Additional first solder material portions 188A may be attached to a respective one of the first-type second metallic bonding pads 368A of the second semiconductor die 300B; and additional second solder material portions 188B may be attached to a respective one of the second-type second metallic bonding pads 878B of the second semiconductor die 300B. A second bonding process (which may also be referred to as an additional bonding process) may be performed, in which the additional first solder material portions 188A are bonded to a respective additional one of the first-type interposer bonding pads 878A, and the additional second solder material portions 188B are bonded to a respective additional one of the second-type interposer bonding pads 878B.

The vertical spacing between the second semiconductor die 300B and the interposer 800 may be gradually reduced during an initial step of the second bonding process. The distance between each additional second solder material portion 188B and a respective underlying second-type interposer bonding pad 878B may decrease until the additional second solder material portions 188B contact the additional second-type interposer bonding pads 878B. An electrostatic discharge (ESD) event may occur immediately before the additional second solder material portions 188B make contact with the additional second-type interposer bonding pads 878B. Thus, the additional second solder material portions 188B function as leading point of discharge (LPoD) structures in the fifth embodiment structure.

Referring to FIG. 12E, the vertical distance between the second semiconductor die 300B and the interposer 800 may be further reduced while the additional solder material portions 188 are maintained at a reflow temperature. Each of the first-type first metallic bonding pads 368A of the second semiconductor die 300B may be bonded to a respective additional first-type interposer bonding pad 878A through a respective additional first solder material portion 188A, and each of the second-type first metallic bonding pads 368B of the second semiconductor die 300B may be bonded to a respective additional second-type interposer bonding pad 878B through a respective additional second solder material portion 188B.

According to an aspect of the present disclosure, the second semiconductor die 300B may be attached to the interposer 800 such that at least one electrical connection is provided between the second semiconductor die 300B and the first semiconductor die 300A. In one embodiment, a first electrically conductive path is formed between the first semiconductor die 300A and the second semiconductor die 300B through a first subset of the redistribution wiring interconnects 840 and through a pair of first-type interposer metallic bonding pads 878A selected from the first-type interposer metallic bonding pads 878A. In one embodiment, a second electrically conductive path is formed between the first semiconductor die 300A and the second semiconductor die 300B through a second subset of the redistribution wiring interconnects 840 and through a pair of second-type interposer metallic bonding pads 878B selected from the second-type interposer metallic bonding pads 878B.

In one embodiment, the interposer 800 comprises substrate-side metallic bonding pads 868 that are located on an opposite side of the interposer metallic bonding pads 878. In one embodiment, a third electrically conductive path is provided within the interposer 800. The third electrically conductive path comprises one of the first-type interposer metallic bonding pads 878A, a third subset of the redistribution wiring interconnect, and one of the substrate-side metallic bonding pads. In one embodiment, the third electrically conductive path is electrically isolated from the first electrically conductive path and the second electrically conductive path.

Referring to FIG. 12E, the fifth embodiment structure comprises a device structure, which comprises: a first semiconductor die 300A comprising a first semiconductor substrate 310, first semiconductor devices 120 located on the first semiconductor substrate 310, and first dielectric material layers 350 embedding first metal interconnect structures 340 and first metallic bonding pads 368, wherein the first metallic bonding pads 368 comprise first-type first metallic bonding pads 368A and second-type first metallic bonding pads 368B; an interposer 800 comprising redistribution wiring interconnects 840 embedded in redistribution dielectric layers 850 comprising polymer materials and further comprising interposer metallic bonding pads 878, wherein the interposer metallic bonding pads 878 comprise first-type interposer metallic bonding pads 878A and second-type interposer metallic bonding pads 878B; first solder material portions 188A bonded to a respective one of the first-type first metallic bonding pads 368A and to a respective one of the first-type interposer metallic bonding pads 878A and having a volume in a range from 80% to 120% of a first reference volume; and second solder material portions 188B bonded to a respective one of the second-type first metallic bonding pads 368B and to a respective one of the second-type interposer metallic bonding pads 878B and having a volume in a range from 80% to 120% of a second reference volume, wherein a ratio of the second reference volume to the first reference volume is in a range from 1.5 to 3.

In one embodiment, a first vertical spacing between the respective one of the first-type first metallic bonding pads 368A and the respective one of the first-type interposer metallic bonding pads 878A is the same as a second vertical spacing between the respective one of the second-type first metallic bonding pads 368B and the respective one of the second-type interposer metallic bonding pads 878B.

In one embodiment, all horizontal interfaces between the first solder material portions 188A and the first-type first metallic bonding pads 368A are located within a first horizontal plane HP1; and all horizontal interfaces between the second solder material portions 188B and the second-type first metallic bonding pads 368B are located within the first horizontal plane HP1. In one embodiment, all horizontal interfaces between the first solder material portions 188A and the first-type interposer metallic bonding pads 878A are located within a second horizontal plane HP2; and all horizontal interfaces between the second solder material portions 188B and the second-type interposer metallic bonding pads 878B are located within the second horizontal plane HP2.

In one embodiment, the first semiconductor die 300A comprises a first electrostatic discharge (ESD) protection circuit 122 located on the first semiconductor substrate 310, wherein one of the second-type first metallic bonding pads 368B is electrically connected to the first ESD protection circuit 122 through a subset of the first metal interconnect structures 340. In one embodiment, the first semiconductor devices 120 comprises a first field effect transistor having an electrical node that is electrically connected to said one of the second-type first metallic bonding pads 368B. In one embodiment, the first-type first metallic bonding pads 368A are electrically isolated from the first ESD protection circuit 122.

In one embodiment, each of the first-type first metallic bonding pads 368A and second-type first metallic bonding pads 368B has a same area. In one embodiment, the first solder material portions 188A do not contact sidewalls of the first-type first metallic bonding pads 368A and do not contact sidewalls of the first-type interposer metallic bonding pads 878A; and the second solder material portions 188B contact sidewalls of the second-type first metallic bonding pads 368B and contact sidewalls of the second-type interposer metallic bonding pads 878B.

In one embodiment, the device structure further comprises: a second semiconductor die 300B comprising a second semiconductor substrate 310, second semiconductor devices 320 located on the second semiconductor substrate 310, second dielectric material layers 350 embedding second metal interconnect structures (such as redistribution wiring interconnects 840), and second metallic bonding pads 878, wherein the second metallic bonding pads 878 comprise first-type second metallic bonding pads 878A and second-type second metallic bonding pads 878B; additional first solder material portions 188A bonded to a respective one of the first-type second metallic bonding pads 878A and to a respective additional one of the first-type interposer metallic bonding pads 878A and having a volume in a range from 80% to 120% of the first reference volume; and additional second solder material portions 188B bonded to a respective one of the second-type second metallic bonding pads 878B and to a respective additional one of the second-type interposer metallic bonding pads 878B and having a volume in a range from 80% to 120% of the second reference volume.

In one embodiment, a first electrically conductive path extends between the first semiconductor die 300A and the second semiconductor die 300B through a first subset of the redistribution wiring interconnects 840 and through a pair of first-type interposer metallic bonding pads 878A selected from the first-type interposer metallic bonding pads 878A; and a second electrically conductive path extends between the first semiconductor die 300A and the second semiconductor die 300B through a second subset of the redistribution wiring interconnects 840 and through a pair of second-type interposer metallic bonding pads 878B selected from the second-type interposer metallic bonding pads 878B.

In one embodiment, the interposer 800 comprises substrate-side metallic bonding pads 868 that are located on an opposite side of the interposer metallic bonding pads 878; a third electrically conductive path is provided within the interposer 800, wherein the third electrically conductive path comprises one of the first-type interposer metallic bonding pads 878A, a third subset of the redistribution wiring interconnect, and one of the substrate-side metallic bonding pads; and the third electrically conductive path is electrically isolated from the first electrically conductive path and the second electrically conductive path.

In one embodiment, the second semiconductor die 300B comprises an electrostatic discharge (ESD) protection circuit 122 located on the second semiconductor substrate 310, wherein one of the second-type second metallic bonding pads 878B is electrically connected to the ESD protection circuit 122 through a subset of the second metal interconnect structures (such as redistribution wiring interconnects 840).

Referring collectively to FIGS. 11D and 12E and according to various embodiments of the present disclosure, a device structure is provided, which comprises: a first semiconductor die (300 or 300A) comprising a first semiconductor substrate 310, first semiconductor devices 120 located on the first semiconductor substrate 310, and first dielectric material layers 350 embedding first metal interconnect structures 340 and first metallic bonding pads 368, wherein the first metallic bonding pads 368 comprise first-type first metallic bonding pads 368A and second-type first metallic bonding pads 368B; an interconnect-containing structure (such as a second semiconductor die 400 or an interposer 800) embedding second metal interconnect structures (such as redistribution wiring interconnects 840 or the second metal interconnect structures 440 in the second semiconductor die 400) and comprising second metallic bonding pads (which may comprise interposer bonding pads 878 or second metallic bonding pads 468 in the second semiconductor die 400), wherein the second metallic bonding pads (878 or 468) comprise first-type second metallic bonding pads (878A or 468A) and second-type second metallic bonding pads (878B or 468B); first solder material portions 188A bonded to a respective one of the first-type first metallic bonding pads 368A and to a respective one of the first-type second metallic bonding pads (878A or 468A) and having a volume in a range from 80% to 120% of a first reference volume; and second solder material portions 188B bonded to a respective one of the second-type first metallic bonding pads 368B and to a respective one of the second-type second metallic bonding pads (878B or 468B) and having a volume in a range from 80% to 120% of a second reference volume, wherein a ratio of the second reference volume to the first reference volume is in a range from 1.5 to 3.

In one embodiment, a first vertical spacing between the respective one of the first-type first metallic bonding pads 368A and the respective one of the first-type second metallic bonding pads (878A or 468A) is the same as a second vertical spacing between the respective one of the second-type first metallic bonding pads 368B and the respective one of the second-type second metallic bonding pads (878B or 468B).

In one embodiment, all horizontal interfaces between the first solder material portions 188A and the first-type first metallic bonding pads 368A are located within a first horizontal plane HP1; and all horizontal interfaces between the second solder material portions 188B and the second-type first metallic bonding pads 368B are located within the first horizontal plane HP1. In one embodiment, all horizontal interfaces between the first solder material portions 188A and the first-type second metallic bonding pads (878A or 468A) are located within a second horizontal plane HP2; and all horizontal interfaces between the second solder material portions 188B and the second-type second metallic bonding pads (878B or 468B) are located within the second horizontal plane HP2.

In one embodiment, the first semiconductor die (300 or 300A) comprises a first electrostatic discharge (ESD) protection circuit 122 located on the first semiconductor substrate 310, wherein one of the second-type first metallic bonding pads 368B is electrically connected to the first ESD protection circuit 122 through a subset of the first metal interconnect structures 340. In one embodiment, the first semiconductor devices 120 comprises a first field effect transistor having an electrical node that is electrically connected to said one of the second-type first metallic bonding pads 368B. In one embodiment, the first-type first metallic bonding pads 368A are electrically isolated from the first ESD protection circuit 122.

In one embodiment, each of the first-type first metallic bonding pads 368A and second-type first metallic bonding pads 368B has a same area. In one embodiment, the first solder material portions 188A do not contact sidewalls of the first-type first metallic bonding pads 368A and do not contact sidewalls of the first-type second metallic bonding pads (878A or 468A); and the second solder material portions 188B contact sidewalls of the second-type first metallic bonding pads 368B and contact sidewalls of the second-type second metallic bonding pads (878B or 468B).

In one embodiment, the interconnect-containing structure comprises an interposer 800; and the second metal interconnect structures comprise redistribution wiring interconnects 840 that are embedded within redistribution dielectric layers 850 comprising polymer materials.

In one embodiment, the interconnect-containing structure comprises a second semiconductor die 300B that comprises: a second semiconductor substrate 310; second semiconductor devices 320 located on the second semiconductor substrate 310; and additional dielectric material layers 350 embedding additional metal interconnect structures 340. In one embodiment, the second semiconductor die 300B comprises an electrostatic discharge (ESD) protection circuit 122 located on the second semiconductor substrate 310. One, a plurality, and/or each, of the second-type first metallic bonding pads 368B is electrically connected to the second ESD protection circuit 122 through a subset of the additional metal interconnect structures 340.

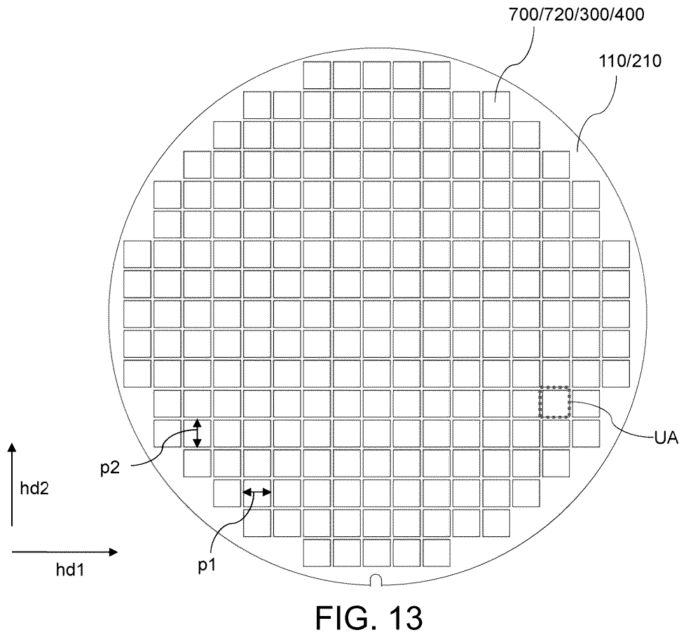

FIG. 13 is a top-down view a sixth embodiment structure including a wafer or a reconstituted wafer according to a sixth embodiment of the present disclosure. The sixth embodiment structure comprises a two-dimensional periodic array of semiconductor dies (700, 720, 300, 400) located on a substrate (110, 210). Each semiconductor die (700, 720, 300, 400) may be located within a respective unit area UA. The semiconductor die (700, 720, 300, 400) may comprise any semiconductor die (700, 720, 300, or 400) described above. The two-dimensional periodic array of semiconductor dies (700, 720, 300, 400) may be arranged with a first pitch p1 along a first horizontal direction hd1, and with a second pitch p2 along a second horizontal direction hd2. Generally, the features described with reference to the sixth embodiment structure may be applied to each of the previously described embodiments of the present disclosure.

The substrate (110, 210) may comprise a semiconductor substrate 110 or a carrier substrate 210. If a semiconductor substrate 110 is used, the semiconductor die within each unit area UA may comprise a semiconductor die (700, 300, 400) including a respective portion of the semiconductor substrate 110, which may be any of the semiconductor substrates (110, 310, 410) of the semiconductor dies (700, 300, 400) described above. In embodiments in which a carrier substrate 210 is used, the semiconductor die may be a fan-out package 720 described above.

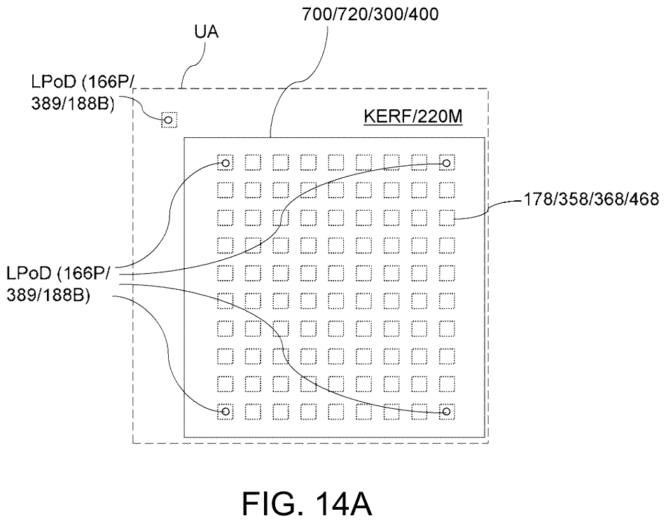

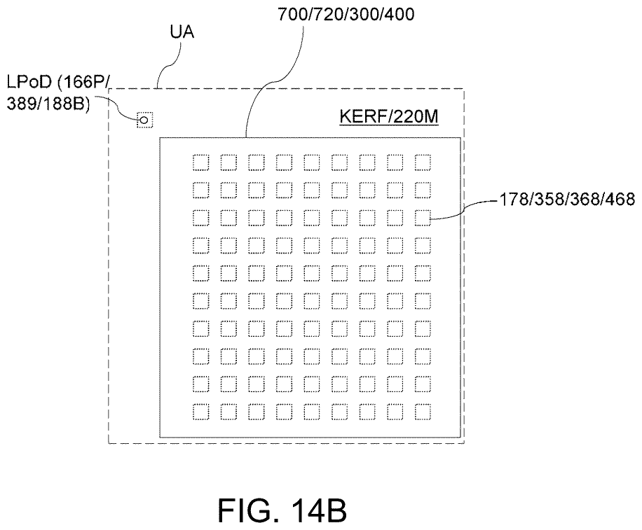

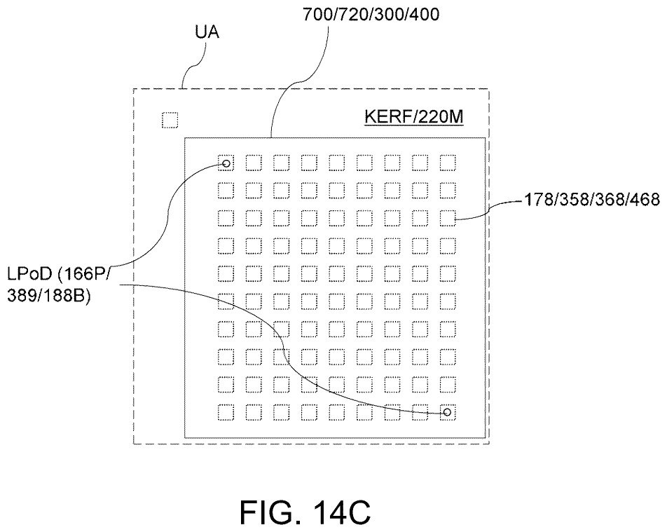

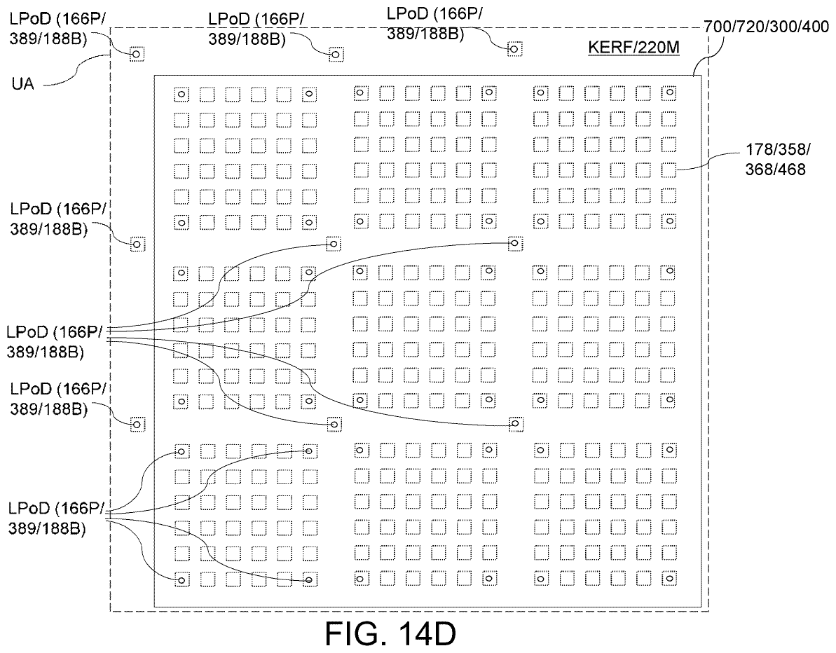

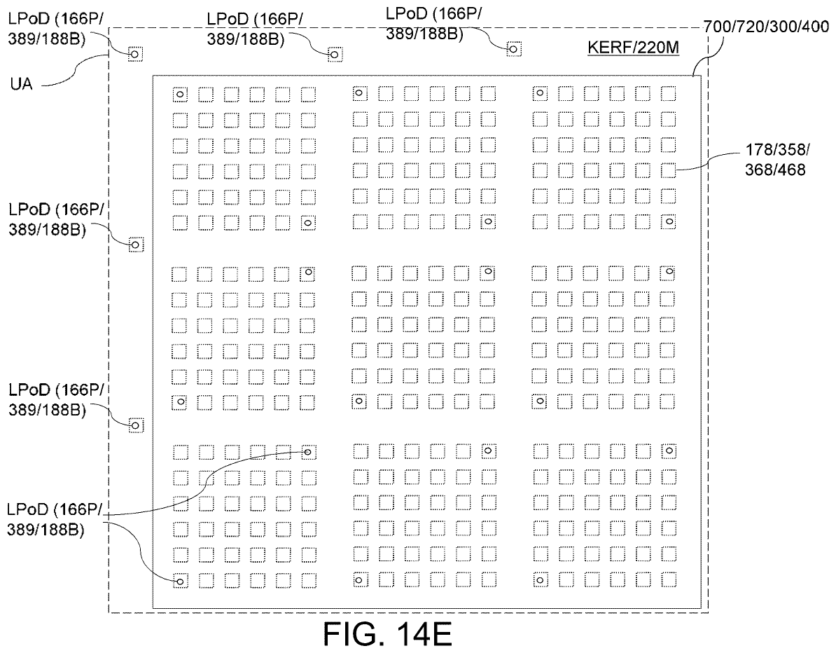

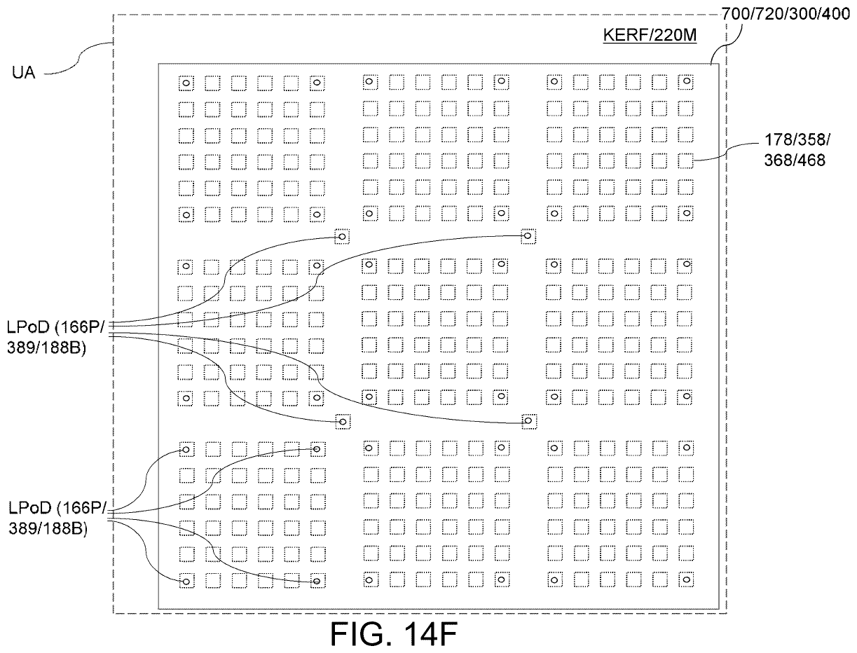

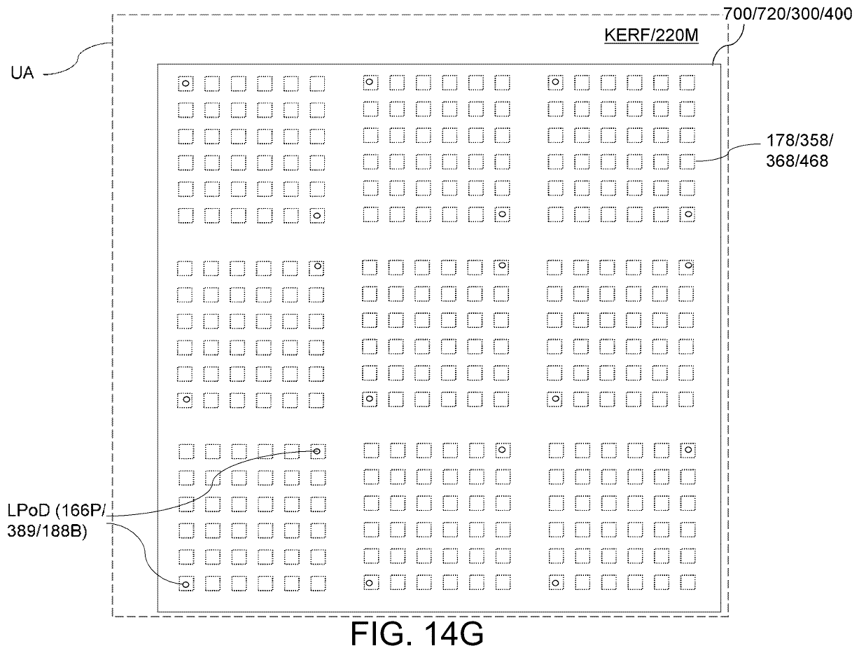

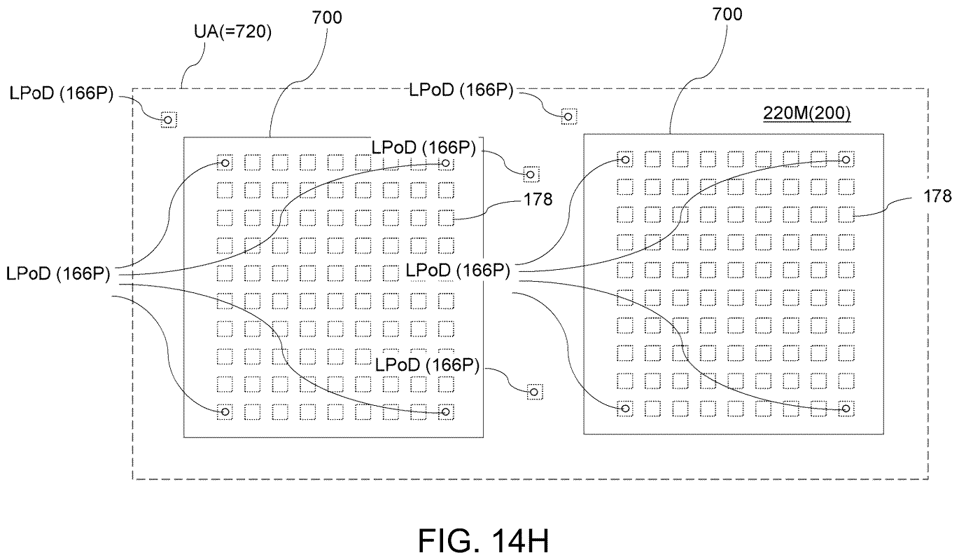

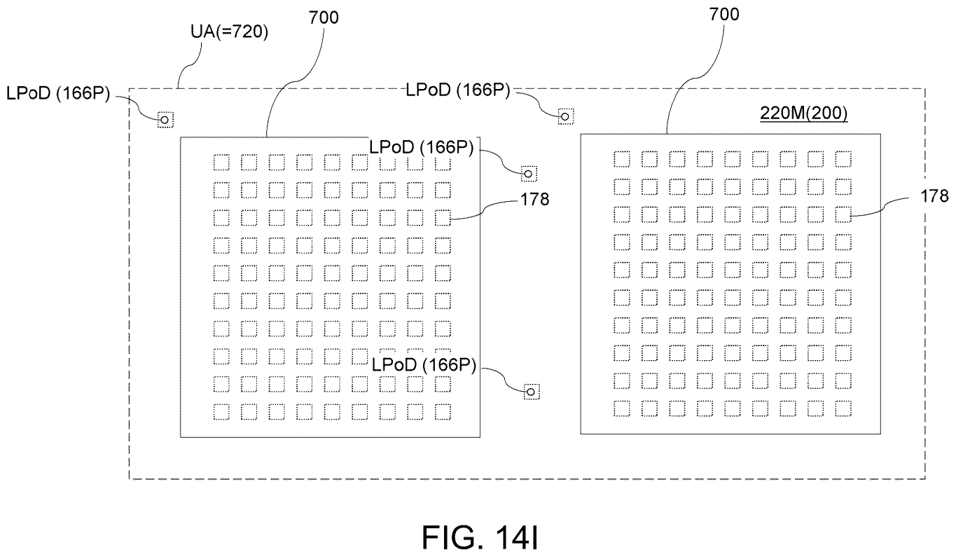

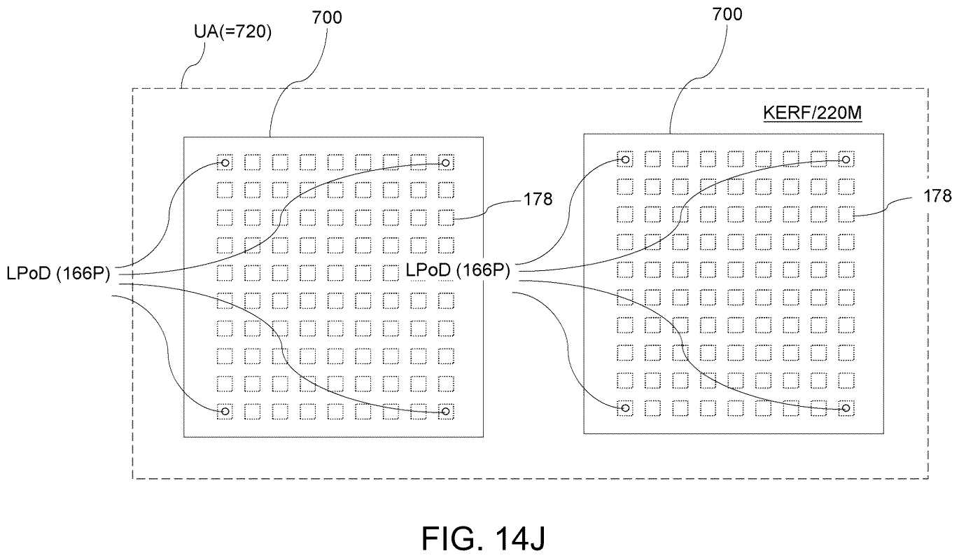

FIGS. 14A-14J are magnified views of various configurations of the sixth embodiment structure of FIG. 13. Generally, each unit area UA includes a semiconductor die (700, 720, 300, 400) and an area (i.e., a non-die area) that is not occupied by the semiconductor die (700, 720, 300, 400). In embodiments in which the substrate comprises a semiconductor substrate 110, the non-die area comprises a kerf area (represented by “KERF” in FIGS. 14A-14G). In embodiments in which the substrate comprises a carrier substrate 210, the non-die area comprises an area of a molding compound die frame 220, which is a portion of a molding compound matrix 220M located within a respective unit area UA.

According to an aspect of the present disclosure, at least one leading point of discharge (LPoD) structure (166P, 389, 188B) may be provided within each unit area UA. The at least one LPoD structure (166P, 389, 188B) may comprise any of the previously described LPoD structures. The at least one LPoD structure (166P, 389, 188B) may be provided within the areas of a respective semiconductor die (700, 720, 300, 400), and/or may be provided within a respective non-die area, which may be a kerf area (i.e., the area of a kerf structure) or the area of a molding compound die frame 220 (which is a portion of a molding compound matrix 220M). Generally, the at least one LPoD structure (166P, 389, 188B) may be formed on, or in proximity to, a subset of metallic bonding pads (178, 358, 368, 468).

Referring to FIG. 14A, a first configuration of the unit area UA is illustrated. In the first configuration, the LPoD structures (166P, 389, 188B) are formed in the area of a semiconductor die (700, 720, 300, 400) and in the area of a kerf structure or a molding compound matrix 220M.

Referring to FIG. 14B, a second configuration of the unit area UA is illustrated. In the second configuration, an LPoD structure (166P, 389, 188B) is formed only in the area of a kerf structure or a molding compound matrix 220M.

Referring to FIG. 14C, a third configuration of the unit area UA is illustrated. In the third configuration, the LPoD structures (166P, 389, 188B) are formed only in the area of a semiconductor die (700, 720, 300, 400).

Referring to FIG. 14D, a fourth configuration of the unit area UA is illustrated. In the fourth configuration, the semiconductor die (700, 720, 300, 400) may be a relatively large semiconductor die (such as an artificial intelligence (AI) semiconductor die), and a plurality of arrays of metallic bonding pads (178, 358, 368, 468) may be provided within the area of the semiconductor die (700, 720, 300, 400). In the fourth configuration, the LPoD structures (166P, 389, 188B) are formed in the area of a semiconductor die (700, 720, 300, 400) and in the area of a kerf structure or a molding compound matrix 220M. The LPoD structures (166P, 389, 188B) are formed between neighboring arrays of metallic bonding pads (178, 358, 368, 468).

Referring to FIG. 14E, a fifth configuration of the unit area UA is illustrated. In the fifth configuration, the semiconductor die (700, 720, 300, 400) may be a relatively large semiconductor die (such as an artificial intelligence (AI) semiconductor die), and a plurality of arrays of metallic bonding pads (178, 358, 368, 468) may be provided within the area of the semiconductor die (700, 720, 300, 400). In the fifth configuration, the LPoD structures (166P, 389, 188B) are formed in the area of a semiconductor die (700, 720, 300, 400) and in the area of a kerf structure or a molding compound matrix 220M, and but not between neighboring arrays of metallic bonding pads (178, 358, 368, 468).

Referring to FIG. 14F, a sixth configuration of the unit area UA is illustrated. In the sixth configuration, the semiconductor die (700, 720, 300, 400) may be a relatively large semiconductor die (such as an artificial intelligence (AI) semiconductor die), and a plurality of arrays of metallic bonding pads (178, 358, 368, 468) may be provided within the area of the semiconductor die (700, 720, 300, 400). In the sixth configuration, the LPoD structures (166P, 389, 188B) are formed in the area of a semiconductor die (700, 720, 300, 400), but not in the area of a kerf structure or a molding compound matrix 220M. The LPoD structures (166P, 389, 188B) may be formed between neighboring arrays of metallic bonding pads (178, 358, 368, 468).

Referring to FIG. 14G, a seventh configuration of the unit area UA is illustrated. In the seventh configuration, the semiconductor die (700, 720, 300, 400) may be a relatively large semiconductor die (such as an artificial intelligence (AI) semiconductor die), and a plurality of arrays of metallic bonding pads (178, 358, 368, 468) may be provided within the area of the semiconductor die (700, 720, 300, 400). In the seventh configuration, the LPoD structures (166P, 389, 188B) are formed in the area of a semiconductor die (700, 720, 300, 400), but not in the area of a kerf structure or a molding compound matrix 220M. The LPoD structures (166P, 389, 188B) are absent between neighboring arrays of metallic bonding pads (178, 358, 368, 468).

Referring to FIG. 14H, an eighth configuration of the unit area UA is illustrated. In the eighth configuration, the LPoD structures (166P, 389, 188B) are formed in the areas of semiconductor dies 700 and in the area of a molding compound matrix 220M. The unit area UA may be the same as the area of a fan-out package 720.

Referring to FIG. 14I, a ninth configuration of the unit area UA is illustrated. In the ninth configuration, the LPoD structures (166P, 389, 188B) are formed in the area of a molding compound matrix 220M, but not in the areas of semiconductor dies 700. The unit area UA may be the same as the area of a fan-out package 720.

Referring to FIG. 14J, a tenth configuration of the unit area UA is illustrated. In the tenth configuration, the LPoD structures (166P, 389, 188B) are formed in the areas of semiconductor dies 700, but not in the area of a molding compound matrix 220M. The unit area UA may be the same as the area of a fan-out package 720.

Referring collectively to FIGS. 1-9D, 13, and 14A-14J and according to various embodiments of the present disclosure, a method of forming a device structure is provided. The method comprises: forming a two-dimensional array of unit structures on a substrate (110, 210), wherein each of the unit structures comprises at least one semiconductor die (700, 720, 300, 400) containing semiconductor devices (120, 320, 420) therein, metal interconnect structures (140, 340, 440) embedded in dielectric material layers (150, 350, 450), and a capping dielectric layer 173 overlying the dielectric material layers (150, 350, 450); and forming passivation-level metal structures 167 and a first electrostatic discharge (ESD) path metal structure 168 in each of the unit structures, wherein each first ESD path metal structure 168 comprises a first top surface segment TSS1 located within a first horizontal plane HP1 that contains a top surface of one of the passivation-level metal structures 167 and further comprises an upper protrusion portion 166P that protrudes above the first horizontal plane HP1.

In one embodiment, the method further comprises: forming a capping dielectric layer 173 over the passivation-level metal structures 167 and the first ESD path metal structure 168 in each of the unit structures; and forming via openings (179A, 179B) through the capping dielectric layer 173 by performing an etch process, wherein the upper protrusion portion 166P of said each first ESD path metal structure 168 is physically exposed before the passivation-level metal structures 167 are physically exposed. In one embodiment, the method further comprises forming a first metallic bonding pad 178A and a second metallic bonding pad 178B on said each first ESD path metal structure 168, wherein: a first metallic bonding pad 178A having a planar bottom surface that contacts the first top surface segment TSS1; and a second metallic bonding pad 178B contacting a top surface of the upper protrusion portion 166P. In one embodiment, the method further comprises: attaching a first solder material portion 188A to the first metallic bonding pad 178A; and attaching a second solder material portion 188B to the second metallic bonding pad 178B.

In one embodiment, each of the unit structures comprises a single semiconductor die (700, 720, 300, 400) and a kerf structure 701; and the substrate comprises a semiconductor wafer. In one embodiment, within each of the unit structures, the first ESD path metal structure 168 is formed in the kerf structure 701. In one embodiment, each of the unit structures comprises a second ESD path metal structure 168 that is formed in the single semiconductor die (700, 720, 300, 400). In one embodiment, within each of the unit structures, the first ESD path metal structure 168 is formed in the single semiconductor die (700, 720, 300, 400).

In one embodiment, each of the unit structures comprises a molding compound die frame 220 that laterally surrounds the at least one semiconductor die (700, 720, 300, 400). In one embodiment, within each of the unit structures, the first ESD path metal structure 168 is formed over the molding compound die frame 220. In one embodiment, each of the unit structures comprises a second ESD path metal structure 168 that is formed in the at least one semiconductor die (700, 720, 300, 400). In one embodiment, within each of the unit structures, the first ESD path metal structure 168 is formed in the at least one semiconductor die (700, 720, 300, 400). In one embodiment, the at least one semiconductor die (700, 720, 300, 400) comprises a plurality of semiconductor die (700, 720, 300, 400) s each laterally surrounded by the molding compound die frame 220.

In one embodiment, the upper protrusion portion 166P of each first ESD path metal structure 168 is formed with at least one tilted top surfaces each having a tilt angle relative to the first horizontal plane HP1 in a range from 0.1 degree to 10 degrees. In one embodiment, a first areal metal density at a level of the passivation-level metal structures 167 and the first electrostatic discharge (ESD) path metal structure 168 within a region including the upper protrusion portion 166P of the ESD path metal structure 168 is less than a second areal metal density at the level of the passivation-level metal structures 167 and the first electrostatic discharge (ESD) path metal within a region of the passivation-level metal structures 167 is by a factor of at least 3.

In one embodiment, the upper protrusion portion 166P of each first ESD path metal structure 168 is formed with a planar top surface segment and at least one vertical surface segment having a bottom periphery within the first horizontal plane HP1.

In one embodiment, the upper protrusion portion 166P of the ESD path metal structure 168 of each first ESD path metal structure 168 has a same material composition as a portion of said one of the passivation-level metal structures 167 that underlie the first horizontal plane HP1. In one embodiment, the upper protrusion portion 166P of the ESD path metal structure 168 of each first ESD path metal structure 168 comprises copper at an atomic percentage of at least 98%.

In one embodiment, the method comprises forming a capping dielectric layer 173 over the passivation-level metal structures 167 and the first ESD path metal structure 168 in each of the unit structures, wherein a second horizontal plane HP2 including a planar top surface of the capping dielectric layer 173 is located above the first horizontal plane HP1. In one embodiment, the method comprises forming a first metallic bonding pad 178A and a second metallic bonding pad 178B, wherein each of the first metallic bonding pad 178A and the second metallic bonding pad 178B comprises a respective planar portion overlying the second horizontal plane HP2 and a respective via portion underlying the second horizontal plane HP2 and vertically extending through the capping dielectric layer 173. In one embodiment, a via portion of the first metallic bonding pad 178A has a greater vertical extent than a via portion of the second metallic bonding pad 178B.

In one embodiment, the at least one semiconductor die (700, 720, 300, 400) in each of the unit structures comprises: an electrostatic discharge (ESD) protection circuit 122 located on a semiconductor material portion; and metal interconnect structures (140, 340, 440) embedded in dielectric material layers (150, 350, 450) that are located between the semiconductor substrate (110, 210) 110 and the capping dielectric layer 173, wherein the first ESD path metal structure 168 is electrically connected to the ESD protection circuit 122 through a subset of the metal interconnect structures (140, 340, 440).

Referring collectively to FIGS. 1-9D, 13, and 14A-14J and according to various embodiments of the present disclosure, a device structure is provided. The device structure comprises a two-dimensional array of unit structures located on a substrate (110, 210). Each of the unit structures comprises at least one semiconductor die (700, 720, 300, 400) containing semiconductor devices (120, 320, 420) therein, metal interconnect structures (140, 340, 440) embedded in dielectric material layers (150, 350, 450), and a capping dielectric layer 173 overlying the dielectric material layers (150, 350, 450). Passivation-level metal structures 167 are embedded in the capping dielectric layer 173 are located in the at least one semiconductor die (700, 720, 300, 400) in each of the unit structures. A first electrostatic discharge (ESD) path metal structure 168 is embedded in the capping dielectric layer 173 in each of the unit structures. The first ESD path metal structure 168 comprises a first top surface segment TSS1 located within a first horizontal plane HP1 that contains a top surface of one of the passivation-level metal structures 167 and further comprises an upper protrusion portion 166P that protrudes above the first horizontal plane HP1.

In one embodiment, each of the unit structures comprises: a first metallic bonding pad 178A having a planar bottom surface that contacts the first top surface segment TSS1; and a second metallic bonding pad 178B contacting a top surface of the upper protrusion portion 166P. In one embodiment, the device structure further comprises: a first solder material portion 188A contacting the first metallic bonding pad 178A; and a second solder material portion 188B contacting the second metallic bonding pad 178B.

In one embodiment, each of the unit structures comprises a single semiconductor die (700, 720, 300, 400) and a kerf structure 701; and the substrate comprises a semiconductor wafer. In one embodiment, within each of the unit structures, the first ESD path metal structure 168 is located in the kerf structure 701. In one embodiment, each of the unit structures comprises a second ESD path metal structure 168 that is located in the single semiconductor die (700, 720, 300, 400). In one embodiment, within each of the unit structures, the first ESD path metal structure 168 is located in the single semiconductor die (700, 720, 300, 400).

In one embodiment, each of the unit structures comprises a molding compound die frame 220 that laterally surrounds the at least one semiconductor die (700, 720, 300, 400). In one embodiment, within each of the unit structures, the first ESD path metal structure 168 is located over the molding compound die frame 220. In one embodiment, each of the unit structures comprises a second ESD path metal structure 168 that is located in the at least one semiconductor die (700, 720, 300, 400). In one embodiment, within each of the unit structures, the first ESD path metal structure 168 is located in the at least one semiconductor die (700, 720, 300, 400). In one embodiment, the at least one semiconductor die (700, 720, 300, 400) comprises a plurality of semiconductor die (700, 720, 300, 400) s each laterally surrounded by the molding compound die frame 220.

In one embodiment, the upper protrusion portion 166P has at least one tilted top surfaces each having a tilt angle relative to the first horizontal plane HP1 in a range from 0.1 degree to 10 degrees. In one embodiment, a first areal metal density at a level of the passivation-level metal structures 167 and the first ESD path metal structure 168 within a region including the upper protrusion portion 166P of the first ESD path metal structure 168 is less than a second areal metal density at the level of the passivation-level metal structures 167 and the first ESD path metal structure 168 within a region of the passivation-level metal structures 167 is by a factor of at least 3.

In one embodiment, the upper protrusion portion 166P comprises a planar top surface segment and at least one vertical surface segment having a bottom periphery within the first horizontal plane HP1.

In one embodiment, the upper protrusion portion 166P of the ESD path metal structure 168 has a same material composition as a portion of said one of the passivation-level metal structures 167 that underlie the first horizontal plane HP1. In one embodiment, the upper protrusion portion 166P of the ESD path metal structure 168 comprises copper at an atomic percentage of at least 98%.

In one embodiment, a second horizontal plane HP2 including a planar top surface of the capping dielectric layer 173 is located above the first horizontal plane HP1; and each of the first metallic bonding pad 178A and the second metallic bonding pad 178B comprises a respective planar portion overlying the second horizontal plane HP2 and a respective via portion underlying the second horizontal plane HP2 and vertically extending through the capping dielectric layer 173. In one embodiment, a via portion of the first metallic bonding pad 178A has a greater vertical extent than a via portion of the second metallic bonding pad 178B.

In one embodiment, the at least one semiconductor die (700, 720, 300, 400) in each of the unit structures comprises: an electrostatic discharge (ESD) protection circuit 122 located on a semiconductor material portion; and metal interconnect structures (140, 340, 440) embedded in dielectric material layers (150, 350, 450) that are located between the semiconductor substrate (110, 210) 110 and the capping dielectric layer 173, wherein the first ESD path metal structure 168 is electrically connected to the ESD protection circuit 122 through a subset of the metal interconnect structures (140, 340, 440).

FIGS. 15A-15L are various views of a seventh embodiment structure. FIG. 15A is a top-down view the seventh embodiment structure including a wafer or a reconstituted wafer according to a seventh embodiment of the present disclosure. FIG. 15B is a magnified view of a unit area in the seventh embodiment structure of FIG. 15A. FIG. 15C is a vertical cross-sectional view of a region of a first configuration of the seventh embodiment structure along the vertical plane C-C′ of FIG. 15B. FIG. 15D is a vertical cross-sectional view of a region of the first configuration of the seventh embodiment structure along the vertical plane D-D′ of FIG. 15B. FIG. 15E is a vertical cross-sectional view of a region of a second configuration of the seventh embodiment structure along the vertical plane C-C′ of FIG. 15B. FIG. 15F is a vertical cross-sectional view of a region of the second configuration of the seventh embodiment structure along the vertical plane D-D′ of FIG. 15B.

Referring collectively to FIGS. 15A-15F, the first configuration and the second configuration of the seventh embodiment structure illustrated in FIGS. 15A-15G may be derived from the sixth embodiment structure illustrated in FIGS. 13 and 14A-14J by forming elongated metal bar structures 198 outside the areas of the semiconductor dies (700, 720, 300, 400). The elongated metal bar structures 198 may be formed concurrently with formation of the metallic bonding pads 178 in any of the previously described embodiments in which the metallic bonding pads 178 are formed. As such, horizontally-extending portions of the elongated metal bar structures 198 may have the same thickness and the same material composition as horizontally-extending portions of the metallic bonding pads 178. Generally speaking, in the seventh embodiment structure, the leading point of discharge (LPoD) structures (166P, 389, 188B) that are used in the sixth embodiment structure are optional, and thus, may be present or may be omitted.

The first configuration of the seventh embodiment structure illustrated in FIGS. 15A-15D corresponds to an embodiment in which the substrate comprises a semiconductor substrate 110, each semiconductor die comprises a respective portion of the semiconductor substrate 110 (prior to dicing of the semiconductor substrate 110), and kerf structures 701 are formed in the kerf region within each unit area UA. In this embodiment, the elongated metal bar structures 198 are formed as elements of the kerf structures 701 over bonding-level dielectric layers 170, which may include a stack of a first passivation dielectric layer 161, a second passivation dielectric layer 163, and a capping dielectric layer 173 as described above. Metallic connection structures 178C provide electrical connection between the elongated metal bar structures 198 and the ESD protection circuit 122, for example, through a discharge current path that may be provided between one of the metallic bonding pads 178 and the ESD protection circuit 122. The metallic connection structures 178C may be provided at the level of the elongated metal bar structures 198, at the level of the ESD path metal structures 168, at the level of the metal pad structures 158, and/or at the level of the metal interconnect structures 140.

The second configuration of the seventh embodiment structure illustrated in FIGS. 15A, 15B, 15F, and 15G corresponds to an embodiment in which the substrate comprises a carrier substrate 210, and the semiconductor dies 700 are bonded to the carrier substrate 210 through an adhesive layer 211. In this embodiment, the elongated metal bar structures 198 are formed over the molding compound matrix 220M, which laterally surrounds a plurality of semiconductor dies 700 within a two-dimensional array of semiconductor dies 700. Metallic connection structures 178C provide electrical connection between the elongated metal bar structures 198 and the ESD protection circuit 122, for example, through a discharge current path that may be provided between one of the metallic bonding pads 178 and the ESD protection circuit 122. The metallic connection structures 178C may be provided at the level of the elongated metal bar structures 198 and the metallic bonding pads 178.

FIG. 15G is a magnified view of a unit area in a third configuration of the seventh embodiment structure of FIG. 15A. FIG. 15H is a vertical cross-sectional view of a region of the third configuration of the seventh embodiment structure along the vertical plane H-H′ of FIG. 15G. FIG. 15I is a vertical cross-sectional view of a region of the third configuration of the seventh embodiment structure along the vertical plane I-I′ of FIG. 15G. FIG. 15J is a magnified view of region J of FIG. 15H. FIG. 15K is a magnified view of region K of FIG. 15I. FIG. 15L is a detailed view of FIG. 15I.

The third configuration of the seventh embodiment structure may be derived from the first configuration of the seventh embodiment structure by forming an ESD protection circuit 122′ (which may be referred to as an additional ESD protection circuit or a second ESD protection circuit) in the kerf structure 701, i.e., outside the semiconductor dies 700. Metal interconnect structures 140′ (which may be referred to as additional metal interconnect structures or second metal interconnect structures) may be formed in the dielectric material layers 150, and additional metal connection structures (which may comprise additional ESD path metal structures 168′ and additional metal pad structures 158′) may be formed in the bonding-level dielectric layers 170. The elongated metal bar structures 198 may be electrically connected to the ESD protection circuit 122′ in the kerf structure 701 through the metal interconnect structures 140′ and the additional metal connection structures (158′, 168′). Thus, Formation of metallic connection structures 178C that are used in the first configuration of the seventh embodiment structure is unnecessary. In some embodiments, the metal interconnect structures 140′ may be arranged as a row of vertical interconnection paths that vertically extend from the ESD protection circuit 122′ to the additional metal connection structures (158′, 168′) as illustrated in FIG. 15L.

Referring collectively to FIGS. 1-61, 15A, and 15H-15L and according to various embodiments of the present disclosure, a method of forming device structure is provided. The method comprises: forming a two-dimensional array of unit structures located on a substrate (which may be a semiconductor substrate 110 such as a semiconductor wafer), wherein each unit structure within the two-dimensional array of unit structures comprises a semiconductor die 700 and a kerf structure 701, wherein the semiconductor die 700 comprises semiconductor devices 120, first metal interconnect structures 140 embedded in a first portion of dielectric material layers 150, and wherein the kerf structure 701 comprises an electrostatic discharge (ESD) protection circuit 122, second metal interconnect structures 140′ embedded in a second portion of the dielectric material layers 150; and forming patterned metal structures (178, 198) on said each unit structure, wherein the patterned metal structures (178, 198) comprise a set of metallic bonding pads 178 electrically connected to the semiconductor devices 120 through the first metal interconnect structures 140 in the semiconductor die 700 in said each unit structure, and further comprise a first elongated metal bar structure 198 having a top surface located within a horizontal plane including top surfaces of the metallic bonding pads 178 and electrically connected to the ESD protection circuit 122 of said each unit structure through the second metal interconnect structures 140′ of said each unit structure.

In one embodiment, the two-dimensional array of unit structures has a first pitch p1 along a first horizontal direction hd1; and the first elongated metal bar structure 198 laterally extends along the first horizontal direction hd1 at least by one half of the first pitch p1. In one embodiment, the kerf structure 701 comprises a second elongated metal bar structure 198 having a top surface located within the horizontal plane and electrically connected to the ESD protection circuit 122 through additional second metal interconnect structures 140′. In one embodiment, the two-dimensional array of unit structures has a second pitch p2 along a second horizontal direction hd2; and the second elongated metal bar structure 198 laterally extends along the second horizontal direction hd2 at least by one half of the second pitch p2.

In one embodiment, the method further comprises forming a capping dielectric layer 173 over the two-dimensional array of unit structures; and forming via openings through the capping dielectric layer 173, wherein each of the metallic bonding pads 178 and the first elongated metal bar structure 198 comprises a respective via portion that vertically extends through a respective via opening in the capping dielectric layer 173. In one embodiment, each of the metallic bonding pads 178 comprises a respective plate portion that overlies the capping dielectric layer 173; and the first elongated metal bar structure 198 comprises a line portion that overlies the capping dielectric layer 173.

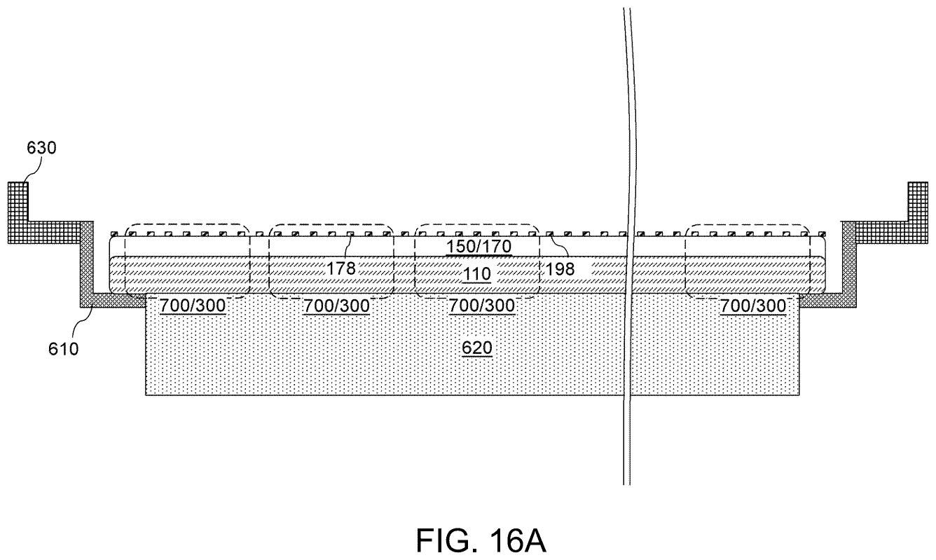

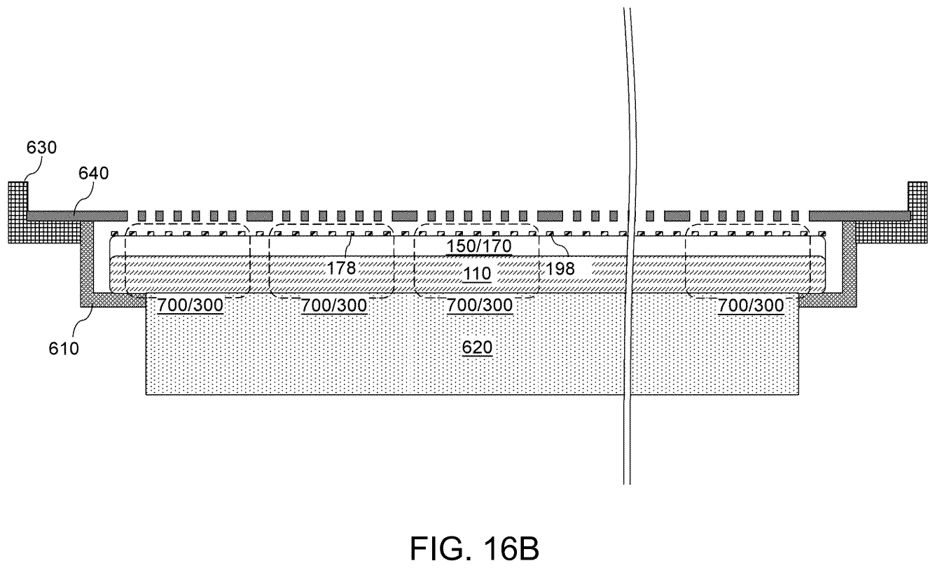

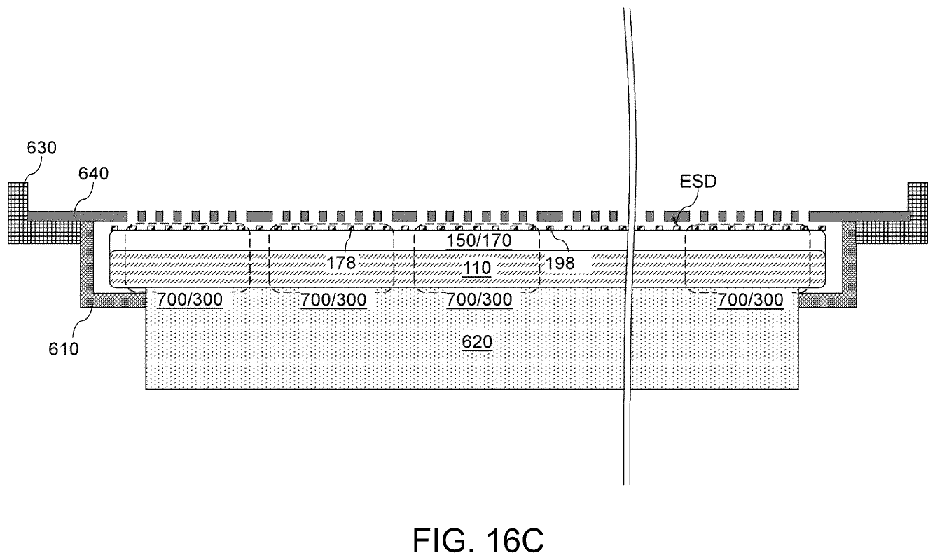

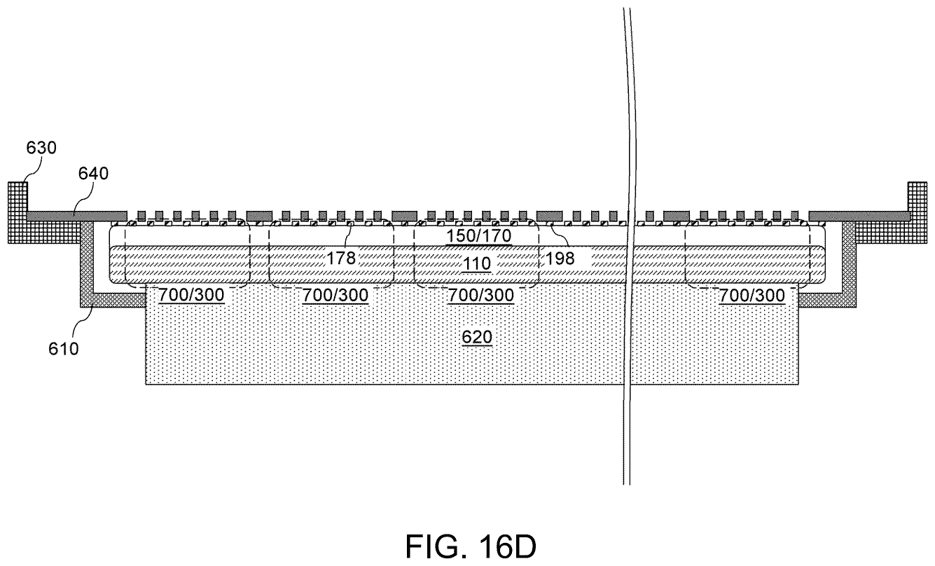

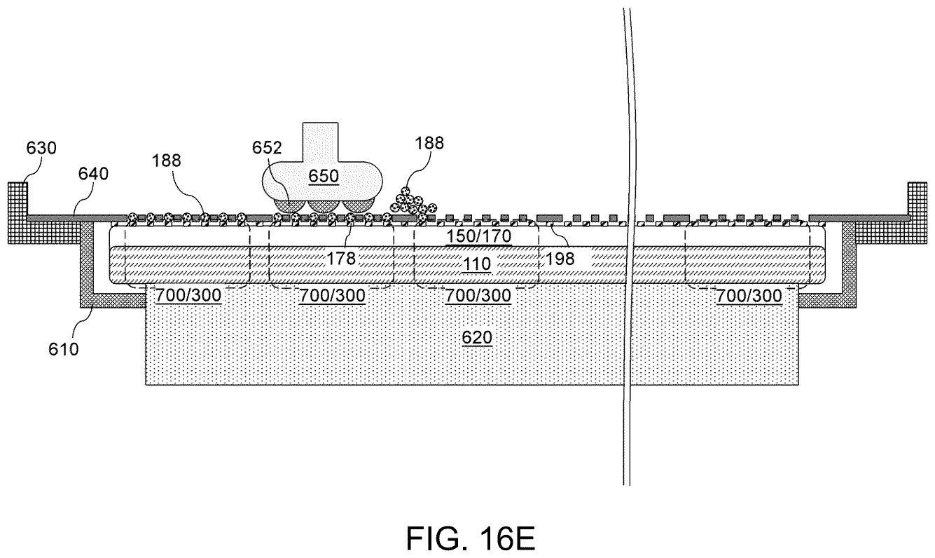

FIGS. 16A-16E is a sequential vertical cross-sectional view of an eighth embodiment structure in which the seventh exemplary structure of FIGS. 15A-15G is processed to attach solder material portions 188 according to an eighth embodiment of the present disclosure.

Referring to FIG. 16A, a solder ball attachment apparatus is provided, which comprises a chuck 620 configurated to mount a wafer or a reconstituted wafer thereupon, a frame 610 attached to a periphery of the chuck 620 and functioning as a lateral enclosure, and a stencil support structure 630 configured to structurally support a conductive stencil to be subsequently placed thereupon. A wafer including a two-dimensional array of unit structures and a substrate (110, 210) may be mounted on the chuck 620. Generally, a wafer or a reconstituted wafer including any configuration of the seventh embodiment structure may be positioned on a top surface of the chuck 620. While the present disclosure is described using an embodiment in which a wafer comprising the first configuration or the third configuration of the seventh embodiment structure is used, embodiments are expressly contemplated herein in which a reconstituted wafer comprising the second configuration of the seventh embodiment structure is used.

Referring to FIG. 16B, a conductive stencil 640 including arrays of openings may be disposed over the two-dimensional array of unit structures. The pattern of the openings in the conductive stencil 640 matches the pattern of the metallic bonding pads 178 on the wafer. The conductive stencil 640 may be aligned to the wafer such that opening in the conductive stencil 640 is aligned to a respective underlying metallic bonding pad 178, and each elongated metal bar structure 198 is positioned outside areas of the openings in the conductive stencil 640.

Each opening in the conductive stencil 640 may have a same size and a same shape (such as a circular shape). The size of the openings in the conductive stencil 640 is determined by the size of the solder balls to be attached to the metallic bonding pads 178 on the wafer. The openings in the conductive stencil 640 are large enough to pass through a single solder ball while preventing passage of a plurality of solder balls. Further, the thickness of the conductive stencil 640 is selected to prevent piling of two or more solder balls in a single opening. In an illustrative example, the metallic bonding pads 178 may be configured to bond with a solder ball having a diameter in a range from 20 microns to 80 microns. In this embodiment, the diameter of each opening in the conductive stencil 640 may be in a range from 101% to 150% of the diameter of the solder balls to be subsequently used. Further, the thickness of the conductive stencil 640 may be in a range from 50% to 100% of the diameter of the solder balls to be subsequently used.

Referring to FIG. 16C, a vertical distance between the conductive stencil 640 and the two-dimensional array of unit structures may be reduced such that the elongated metal bar structures 198 contact a bottom surface of the conductive stencil 640 while the sets of metallic bonding pads 178 do not contact the conductive stencil 640. An electrostatic discharge (ESD) event may occur immediately before the elongated metal bar structures 198 make contact with the bottom surface of the conductive stencil 640, and static electrical charge may flow between the conductive stencil 640 and the elongated metal bar structures 198. The electrical discharge may be directed to the ESD protection circuit (122 or 122′) that is described with reference to the seventh embodiment structure. Thus, the elongated metal bar structures 198 function as leading point of discharge (LPoD) structures in the seventh and eighth embodiment structures.

Referring to FIG. 16D, the vertical distance between the conductive stencil 640 and the two-dimensional array of unit structure may be reduced to zero, and the elongated metal bar structures 198 contact the bottom surface of the conductive stencil 640. The metallic bonding pads 178 are aligned to the openings in the conductive stencil 640. In one embodiment, the metallic bonding pads 178 are not in contact with the conductive stencil 640.

Referring to FIG. 16E, solder balls 188 may be passed through the openings in the conductive stencil 640, for example, by spreading the solder balls 188 over the conductive stencil 640 and by sweeping the solder balls 188 with a roller 650 including at least one rotating brush 652. A single solder ball 188 falls into each opening in the conductive stencil 640, and lands on a respective one of the metallic bonding pads 178. Excess solder balls 188 may be removed from above the conductive stencil 640. Subsequently, the solder balls 188 may be attached to each set of metallic bonding pads 178 within a respective semiconductor die 700 by reflowing the solder balls 188. Generally, solder balls 188 may be attached to the metallic bonding pads 178 of the semiconductor dies 700 in the two-dimensional array of unit structures without attaching the solder balls 188 to the elongated metal bar structures 198.

Referring collectively to FIGS. 1-61, 15A, 15H-15L, and FIGS. 16A-16E and according to various embodiments of the present disclosure, a device structure is provided, which comprises a two-dimensional array of unit structures located on a substrate. Each of the unit structures comprises a semiconductor die 700 and a kerf structure 701. The semiconductor die 700 comprises semiconductor devices 120, first metal interconnect structures 140 embedded in a first portion of dielectric material layers 150, and metallic bonding pads 178 electrically connected to the semiconductor devices 120 through the first metal interconnect structures 140. The kerf structure 701 comprises an electrostatic discharge (ESD) protection circuit 122, second metal interconnect structures 140′ embedded in a second portion of the dielectric material layers 150, and a first elongated metal bar structure 198 having a top surface located within a horizontal plane including top surfaces of the metallic bonding pads 178 and electrically connected to the ESD protection circuit 122 through the second metal interconnect structures 140′.

In one embodiment, the two-dimensional array of unit structures has a first pitch p1 along a first horizontal direction hd1; and the first elongated metal bar structure 198 laterally extends along the first horizontal direction hd1 at least by one half of the first pitch p1. In one embodiment, the kerf structure 701 comprises a second elongated metal bar structure 198 having a top surface located within the horizontal plane and electrically connected to the ESD protection circuit 122 through additional second metal interconnect structures 140′. In one embodiment, the two-dimensional array of unit structures has a second pitch p2 along a second horizontal direction hd2; and the second elongated metal bar structure 198 laterally extends along the second horizontal direction hd2 at least by one half of the second pitch p2.

In one embodiment, the device structure comprises solder balls 188 bonded to the metallic bonding pads 178 of the semiconductor dies 700 in the two-dimensional array of unit structures, wherein the first elongated metal bar structure 198 is not in contact with a material of the solder balls 188.

In one embodiment, a capping dielectric layer 173 continuously extends through the two-dimensional array of unit structures; and each of the metallic bonding pads 178 and the first elongated metal bar structure 198 comprises a respective via portion that vertically extends through a respective via opening in the capping dielectric layer 173. In one embodiment, each of the metallic bonding pads 178 comprises a respective plate portion that overlies the capping dielectric layer 173; and the first elongated metal bar structure 198 comprises a line portion that overlies the capping dielectric layer 173.

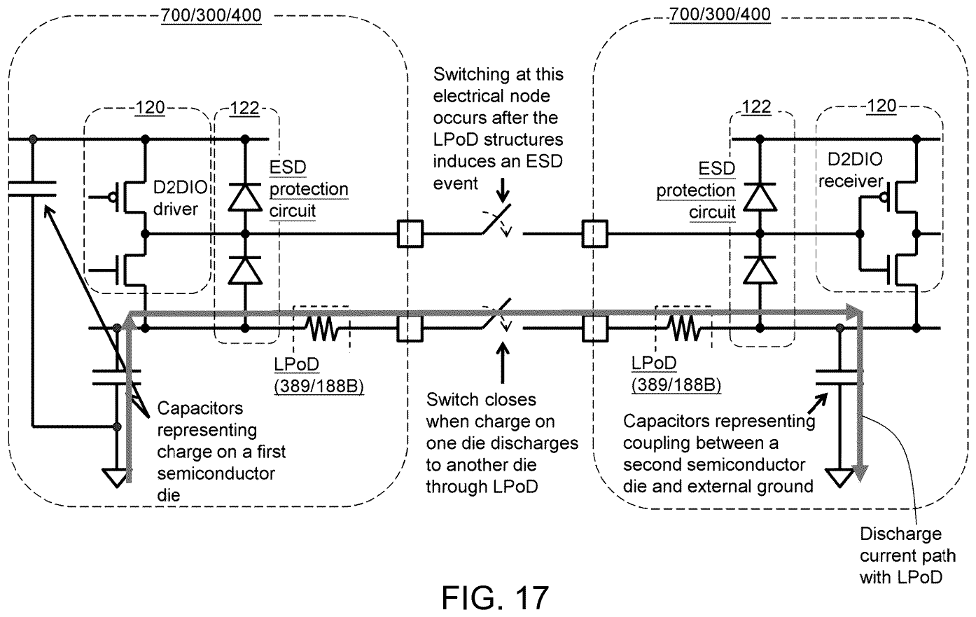

FIG. 17 is a schematic circuit diagram of a combined electrostatic discharge circuit during operation of the various leading point of discharge structures of various embodiments of the present disclosure. Generally, a first semiconductor die (700, 300, 400) including first semiconductor devices 120 and a first ESD protection circuit 122 and a second semiconductor die (700, 300, 400) including second semiconductor devices 120 and a second ESD protection circuit 122 may be provided. Each ESD protection circuit 122 may comprise any ESD protection circuit elements known in the art, such as at least one diode. The first semiconductor devices 120 and the second semiconductor devices 120 may comprise any semiconductor device known in the art, and may comprise a device component that is sensitive to ESD events such as die-to-die input/output drivers. Static electrical charges on the first semiconductor die (700, 300, 400) and on the second semiconductor die (700, 300, 400) are represented by capacitors.

Leading point of discharge (LPoD) structures are provided between the first semiconductor die (700, 300, 400) and the second semiconductor die (700, 300, 400). The LPoD structures may be any of the LPoD structures described above, and may be portions of the first semiconductor die (700, 300, 400), may be portions of the second semiconductor die (700, 300, 400), or may be external components that do not belong to the first semiconductor die (700, 300, 400) or the second semiconductor die (700, 300, 400). During bonding of the second semiconductor die (700, 300, 400), the LPoD structure induces electrical connection between an electrical node of the first semiconductor die (700, 300, 400) and an electrical node of the second semiconductor die (700, 300, 400) and induces an electrostatic discharge event. The discharge current flows through the LPoD structure. Electrical connection between electrical nodes of semiconductor devices 120 that need to be protected from ESD events occur only after the ESD event. Thus, the semiconductor devices 120 in the first semiconductor die (700, 300, 400) and the second semiconductor die (700, 300, 400) may be protected from ESD events through the LPoD structures of the present disclosure.

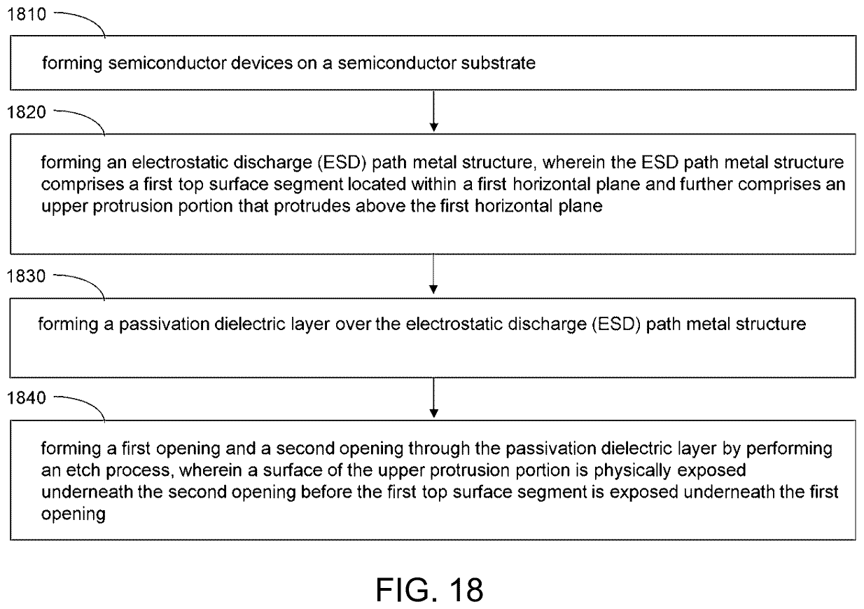

FIG. 18 is a first flowchart illustrating steps for forming a device structure according to an embodiment of the present disclosure.

Referring to step 1810 and FIG. 1, semiconductor devices 120 may be formed on a semiconductor substrate 110.

Referring to step 1820 and FIGS. 2A-2F, 3, and 6A-6C, passivation-level metal structures 167 and an electrostatic discharge (ESD) path metal structure 168 may be formed. The ESD path metal structure 168 comprises a first top surface segment TSS1 located within a first horizontal plane HP1 that contains a top surface of one of the passivation-level metal structures 167 and further comprises an upper protrusion portion 166P that protrudes above the first horizontal plane HP1.

Referring to step 1830 and FIGS. 4A and 6D, a capping dielectric layer 173 may be formed over the passivation-level metal structures 167 and the electrostatic discharge (ESD) path metal structure 168.

Referring to step 1840 and FIGS. 4A, 4B, 6D, and 6E, a first via opening 179A and a second via opening 179B may be formed through the capping dielectric layer 173 by performing an etch process. A surface of the upper protrusion portion 166P is physically exposed underneath the second via opening 179B before the first top surface segment TSS1 is exposed underneath the first via opening 179A.

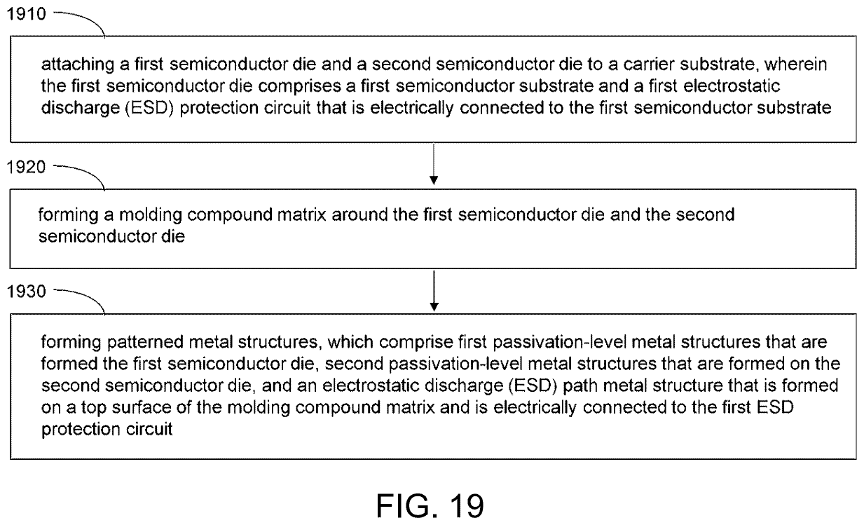

FIG. 19 is a second flowchart illustrating steps for forming a device structure according to an embodiment of the present disclosure.

Referring to step 1910 and FIG. 7A, a first semiconductor die 700 and a second semiconductor die 700 may be attached to a carrier substrate 210. The first semiconductor die 700 comprises a first semiconductor substrate 110 and a first electrostatic discharge (ESD) protection circuit 122 that is electrically connected to the first semiconductor substrate 110.

Referring to step 1920 and FIG. 7B, a molding compound matrix 220M may be formed around the first semiconductor die 700 and the second semiconductor die 700.

Referring to step 1930 and FIGS. 7C, 7D, 8A, and 8B, patterned metal structures (167, 168) may be formed, which comprise first passivation-level metal structures 167 that are formed the first semiconductor die 700, second passivation-level metal structures 167 that are formed on the second semiconductor die 700, and an electrostatic discharge (ESD) path metal structure 168 that is formed on a top surface of the molding compound die frame 220 and is electrically connected to the first ESD protection circuit 122.

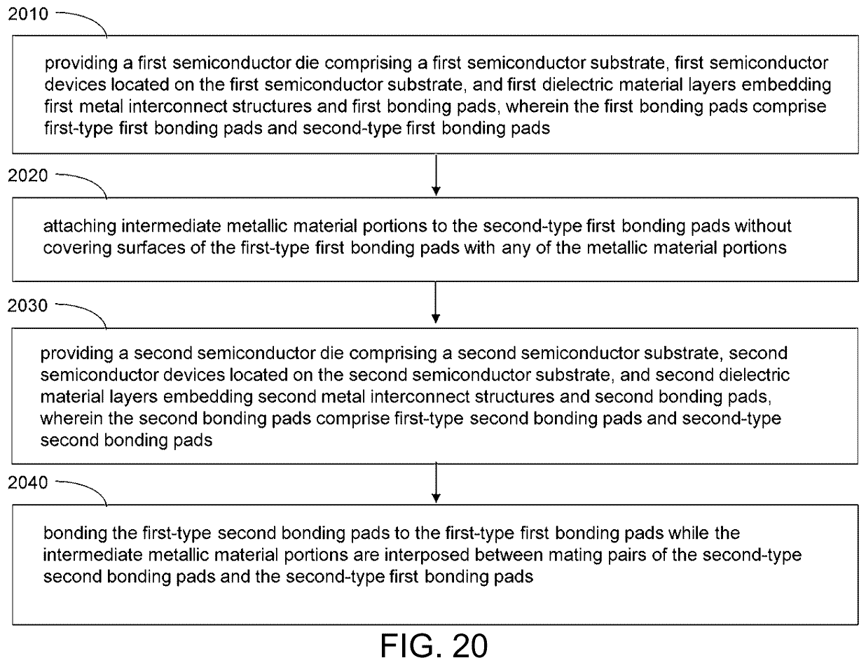

FIG. 20 is a third flowchart illustrating steps for forming a device structure according to an embodiment of the present disclosure.

Referring to step 2010 and FIGS. 10A and 10B, a first semiconductor die 300 is provided, which comprises a first semiconductor substrate 310, first semiconductor devices 120 located on the first semiconductor substrate 310, and first dielectric material layers 350 embedding first metal interconnect structures 340 and first metallic bonding pads 358, wherein the first metallic bonding pads 358 comprise first-type first metallic bonding pads 358A and second-type first metallic bonding pads 358B.

Referring to step 2020 and FIG. 10C, intermediate metallic material portions 389 may be attached to the second-type first metallic bonding pads 358B without covering surfaces of the first-type first metallic bonding pads 358A with any metallic material.

Referring to step 2030 and FIG. 10D, a second semiconductor die 400 is provided, which comprises a second semiconductor substrate 410, second semiconductor devices 420 located on the second semiconductor substrate 410, second dielectric material layers 450 embedding second metal interconnect structures 440, and second metallic bonding pads 488, wherein the second metallic bonding pads 488 comprise first-type second metallic bonding pads 488A and second-type second metallic bonding pads 488B.

Referring to step 2040 and FIGS. 10E and 10F, the first-type second metallic bonding pads 488A may be bonded to the first-type first metallic bonding pads 358A while the intermediate metallic material portions 389 are interposed between mating pairs of the second-type second metallic bonding pads 488B and the second-type first metallic bonding pads 358B.

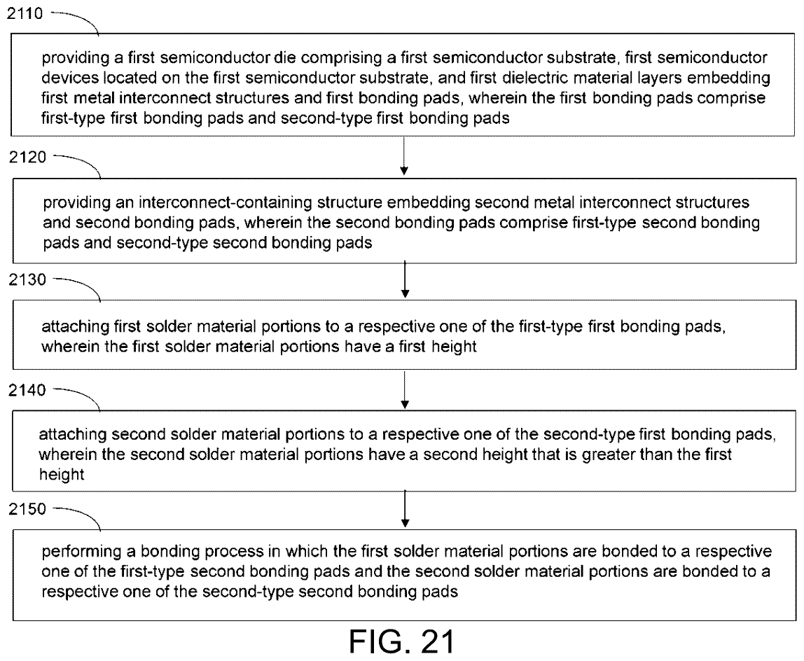

FIG. 21 is a fourth flowchart illustrating steps for forming a device structure according to an embodiment of the present disclosure.

Referring to step 2110 and FIGS. 11A and 12A, a first semiconductor die 300 is provided, which comprises a first semiconductor substrate 310, first semiconductor devices 120 located on the first semiconductor substrate 310, and first dielectric material layers 350 embedding first metal interconnect structures 340 and first metallic bonding pads 368, wherein the first metallic bonding pads 368 comprise first-type first metallic bonding pads 368A and second-type first metallic bonding pads 368B.

Referring to step 2120 and FIGS. 11B and 12A, an interconnect-containing structure (such as a second semiconductor die 400 or an interposer 800) is provided, which embeds second metal interconnect structures (such as the second metal interconnect structures 440 or the redistribution wiring interconnects 840) and comprises second metallic bonding pads (such as second metallic bonding pads 488 or interposer metallic bonding pads 878). The second metallic bonding pads (488 or 878) comprise first-type second metallic bonding pads (488A or 878A) and second-type second metallic bonding pads (488B or 878B).

Referring to step 2130 and FIGS. 11A and 12A, first solder material portions 188A are attached to a respective one of the first-type first metallic bonding pads 368A, wherein the first solder material portions 188A have a first height.

Referring to step 2140 and FIGS. 11A and 12A, second solder material portions 188B are attached to a respective one of the second-type first metallic bonding pads 368B, wherein the second solder material portions 188B have a second height that is greater than the first height.

Referring to step 2150 and FIGS. 11C, 11D, 12B, and 12C, a bonding process is performed in which the first solder material portions 188A are bonded to a respective one of the first-type second metallic bonding pads (488A or 878A) and the second solder material portions 188B are bonded to a respective one of the second-type second metallic bonding pads (488B or 878B).

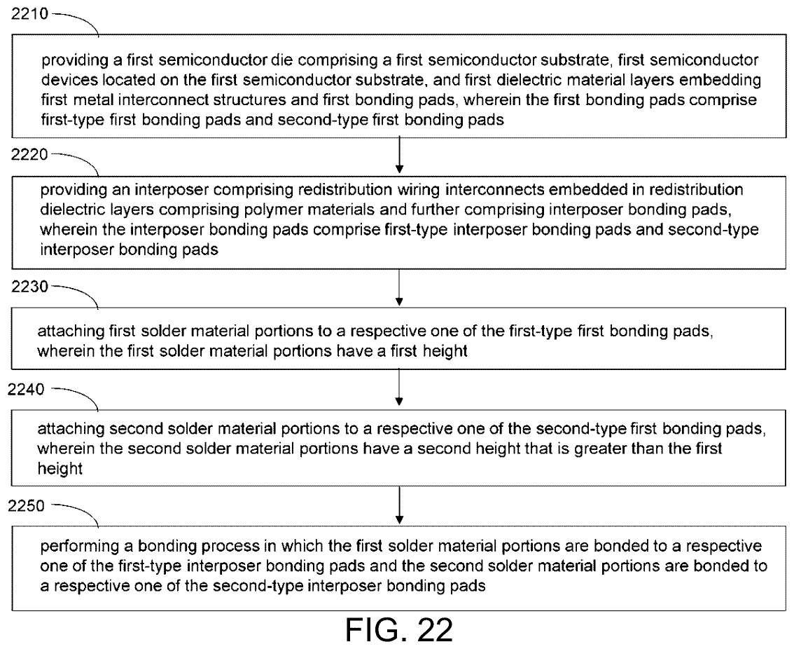

FIG. 22 is a fifth flowchart illustrating steps for forming a device structure according to an embodiment of the present disclosure.

Referring to step 2210 and FIG. 12A, a first semiconductor die 300 is provided, which comprises a first semiconductor substrate 310, first semiconductor devices 120 located on the first semiconductor substrate 310, and first dielectric material layers 350 embedding first metal interconnect structures 340 and first metallic bonding pads 368. The first metallic bonding pads 368 comprise first-type first metallic bonding pads 368A and second-type first metallic bonding pads 368B.

Referring to step 2220 and FIG. 12A, an interposer 800 is provided, which comprises redistribution wiring interconnects 840 embedded in redistribution dielectric layers 850 comprising polymer materials and further comprising interposer metallic bonding pads 878. The interposer metallic bonding pads 878 comprise first-type interposer metallic bonding pads 878A and second-type interposer metallic bonding pads 878B.

Referring to step 2230 and FIG. 12A, first solder material portions 188A are attached to a respective one of the first-type first metallic bonding pads 368A. The first solder material portions 188A have a first height.

Referring to step 2240 and FIG. 12A, second solder material portions 188B are attached to a respective one of the second-type first metallic bonding pads 368B. The second solder material portions 188B have a second height that is greater than the first height.

Referring to step 2250 and FIGS. 12B and 12C, a bonding process is performed, in which the first solder material portions 188A are bonded to a respective one of the first-type interposer metallic bonding pads 878A and the second solder material portions 188B are bonded to a respective one of the second-type interposer metallic bonding pads 878B.

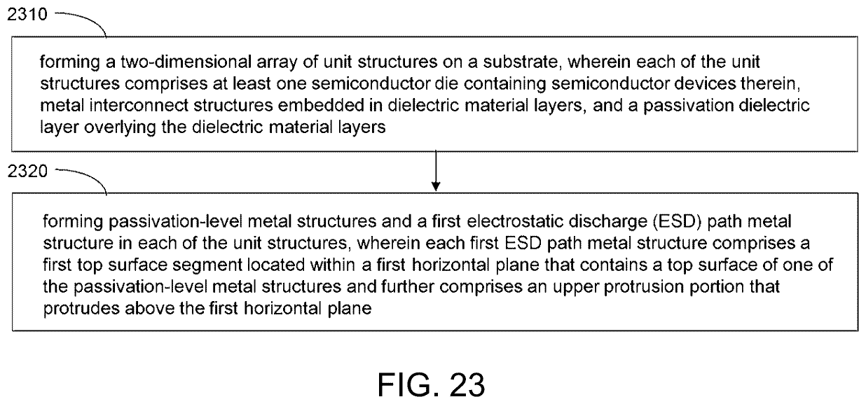

FIG. 23 is a sixth flowchart illustrating steps for forming a device structure according to an embodiment of the present disclosure.

Referring to step 2310 and FIGS. 1, 7A, 7B, 13, and 14A-14G, a two-dimensional array of unit structures may be formed on a substrate (110, 210). Each of the unit structures comprises at least one semiconductor die (700, 720, 300, 400) containing semiconductor devices (120, 320, 420) therein, metal interconnect structures (140, 340, 440) embedded in dielectric material layers (150, 350, 450), and a capping dielectric layer 173 overlying the dielectric material layers (150, 350, 450).

Referring to step 2320 and FIGS. 2A-2F, 3, 6A-6C, 7C, 7D, 8A, 8B, 13, and 14A-14G, passivation-level metal structures 167 and a first electrostatic discharge (ESD) path metal structure 168 may be formed in each of the unit structures. Each first ESD path metal structure 168 comprises a first top surface segment TSS1 located within a first horizontal plane HP1 that contains a top surface of one of the passivation-level metal structures 167 and further comprises an upper protrusion portion 166P that protrudes above the first horizontal plane HP1.

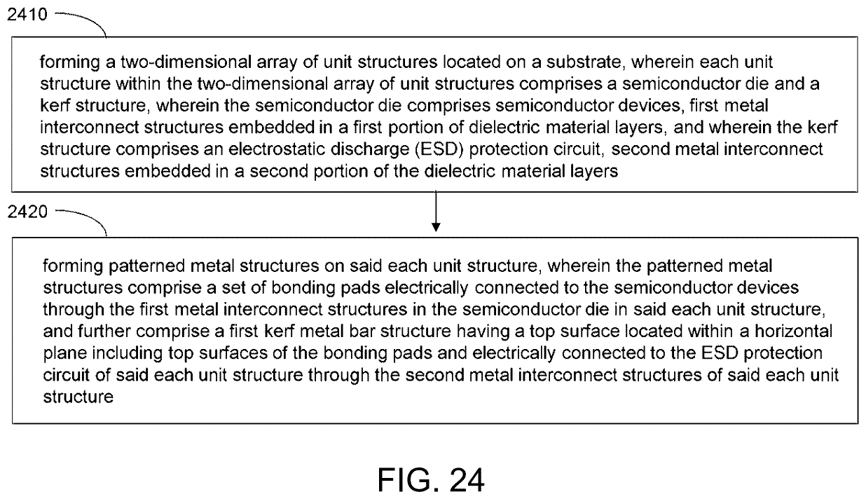

FIG. 24 is a seventh flowchart illustrating steps for forming a device structure according to an embodiment of the present disclosure.

Referring to step 2410 and FIGS. 1, 7A, 7B, 13, 14A-14G, 15A, and 15G-15L, a two-dimensional array of unit structures located on a substrate may be formed. Each unit structure within the two-dimensional array of unit structures comprises a semiconductor die 700 and a kerf structure 701. The semiconductor die 700 comprises semiconductor devices 120, first metal interconnect structures 140 embedded in a first portion of dielectric material layers 150, and wherein the kerf structure 701 comprises an electrostatic discharge (ESD) protection circuit 122, second metal interconnect structures 140′ embedded in a second portion of the dielectric material layers 150.

Referring to step 2420 and FIGS. 2A-2F, 3, 6A-6C, 7C, 7D, 8A, 8B, 13, 14A-14G, 15A, and 15G-15L, patterned metal structures (168, 198) may be formed on said each unit structure. The patterned metal structures (168, 198) comprise a set of metallic bonding pads 178 electrically connected to the semiconductor devices 120 through the first metal interconnect structures 140 in the semiconductor die 700 in said each unit structure, and further comprise a first elongated metal bar structure 198 having a top surface located within a horizontal plane including top surfaces of the metallic bonding pads 178 and electrically connected to the ESD protection circuit 122 of said each unit structure through the second metal interconnect structures 140′ of said each unit structure.

The various embodiments of the present disclosure may be used to provide and utilize leading point of discharge (LPoD) structures at an interconnect level, at a die level, and/or at a wafer level. The various LPoD structures may be formed over a semiconductor wafer (that functions as the semiconductor substrate 110) or over a carrier substrate 210 that supports a reconstituted wafer. The LPoD structures may comprise an upper protrusion portion on an ESD path metal structure, intermediate metallic material portions, solder material portions having a greater height than normal solder material portions that are not provided with ESD protection, or an elongated metal bar structure. The LPoD structures may be used for anisotropic etch process for forming via cavities, bonding processes using solder material portions, bonding processes using metal-to-metal bonding, and/or solder ball attachment processes.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
semiconductor devices located on a semiconductor substrate;
an electrostatic discharge (ESD) path metal structure embedded in a capping dielectric layer, wherein the ESD path metal structure comprises a first top surface segment located within a first horizontal plane and further comprises an upper protrusion portion that protrudes above the first horizontal plane;
a first metallic bonding pad having a planar bottom surface that contacts the first top surface segment; and
a second metallic bonding pad contacting a top surface of the upper protrusion portion.

2. The device structure of claim 1, further comprising:
a first solder material portion contacting the first metallic bonding pad; and
a second solder material portion contacting the second metallic bonding pad.

3. The device of structure of claim 1, wherein the upper protrusion portion has at least one tilted top surfaces each having a tilt angle relative to the first horizontal plane.

4. The device structure of claim 1, further comprising passivation-level metal structures located at a same level as the ESD path metal structure, wherein a top surface of one of the passivation-level metal structures is located within the first horizontal plane, and wherein a first areal metal density at a level of the passivation-level metal structures and the ESD path metal structure within a region including the upper protrusion portion of the ESD path metal structure is less than a second areal metal density at the level of the passivation-level metal structures and the ESD path metal structure within a region of the passivation-level metal structures is by a factor of at least 3.

5. The device structure of claim 4, wherein the upper protrusion portion of the ESD path metal structure has a same material composition as a portion of said one of the passivation-level metal structures that underlies the first horizontal plane.

6. The device structure of claim 1, wherein the upper protrusion portion comprises a planar top surface segment and at least one vertical surface segment having a bottom periphery within the first horizontal plane.

7. The device structure of claim 1, wherein the upper protrusion portion of the ESD path metal structure comprises copper at an atomic percentage of at least 98%.

8. The device structure of claim 1, wherein:
a second horizontal plane including a planar top surface of the capping dielectric layer is located above the first horizontal plane; and
each of the first metallic bonding pad and the second metallic bonding pad comprises a respective planar portion overlying the second horizontal plane and a respective via portion underlying the second horizontal plane and vertically extending through the capping dielectric layer.

9. The device structure of claim 8, wherein a via portion of the first metallic bonding pad has a greater vertical extent than a via portion of the second metallic bonding pad.

10. The device structure of claim 1, further comprising:
an electrostatic discharge (ESD) protection circuit located on the semiconductor substrate; and
metal interconnect structures embedded in dielectric material layers that are located between the semiconductor substrate and the capping dielectric layer,
wherein the ESD path metal structure is electrically connected to the ESD protection circuit through a subset of the metal interconnect structures.

11. A device structure comprising:
a molding compound die frame laterally surrounding a first semiconductor die and a second semiconductor die;
first passivation-level metal structures that overlie the first semiconductor die;
second passivation-level metal structures that overlie the second semiconductor die;
an electrostatic discharge (ESD) path metal structure that overlies the first semiconductor die, the molding compound die frame, and the second semiconductor die, wherein the ESD path metal structure comprises a first top surface segment located within a first horizontal plane that contains a top surface of one of the first passivation-level metal structures and a top surface of one of the second passivation-level metal structures, and further comprises an upper protrusion portion that protrudes above the first horizontal plane;
a first metallic bonding pad having a planar bottom surface that contacts the first top surface segment; and
a second metallic bonding pad contacting a top surface of the upper protrusion portion.

12. The device structure of claim 11, further comprising:
a first solder material portion contacting the first metallic bonding pad; and
a second solder material portion contacting the second metallic bonding pad.

13. The device structure of claim 11, wherein:
the first metallic bonding pad has an areal overlap with the molding compound die frame in a plan view; and
the second metallic bonding pad is located entirely within an area of the first semiconductor die in the plan view.

14. The device structure of claim 11, wherein the upper protrusion portion has an areal overlap with the molding compound die frame in a plan view.

15. The device structure of claim 11, further comprising a capping dielectric layer embedding the first passivation-level metal structures, the second passivation-level metal structures, and the ESD path metal structures, wherein a first areal metal density at a level of the first passivation-level metal structures, the second passivation-level metal structures within a region including the upper protrusion portion of the ESD path metal structure is less than a second areal metal density at the level of the first passivation-level metal structures, the second passivation-level metal structures within a region of the first passivation-level metal structures is by a factor of at least 3.

16. A device structure comprising:
a first semiconductor die comprising a first semiconductor substrate, first semiconductor devices located on the first semiconductor substrate, first dielectric material layers embedding first metal interconnect structures, first metallic bonding pads, wherein the first metallic bonding pads comprise first-type first metallic bonding pads and second-type first metallic bonding pads;
a second semiconductor die comprising a second semiconductor substrate, second semiconductor devices located on the second semiconductor substrate, second dielectric material layers embedding second metal interconnect structures, and second metallic bonding pads, wherein the second metallic bonding pads comprise first-type second metallic bonding pads that are directly bonded to the first-type first metallic bonding pads and second-type second metallic bonding pads that do not contact any of the first metallic bonding pads; and
intermediate metallic material portions, wherein each of the intermediate metallic material portions is in contact with a respective one of the second-type first metallic bonding pads and with a respective one of the second-type second metallic bonding pads.

17. The device structure of claim 16, wherein:
each of the first-type first metallic bonding pads has a first thickness; and
each of the second-type first metallic bonding pads has a second thickness that is less than the first thickness.

18. The device structure of claim 17, wherein each of the second metallic bonding pads has a uniform thickness throughout.

19. The device structure of claim 17, wherein each of the intermediate metallic material portions has a metallic material portion thickness that equals a difference between the first thickness and the second thickness.

20. The device structure of claim 16, wherein each of the intermediate metallic material portions has a respective horizontal surface segment that is located within a horizontal plane including bonding surfaces of the first-type first metallic bonding pads.
